(19) United States
(12) Patent Application Publication
(10) Pub. No.: US 2003/0219680 A1
(43) Pub. Date: Nov. 27, 2003

(54) Radiation-sensitive resin composition

(76) Inventors: Yukio Nishimura, Yokkaichi (JP); Hiroyuki Ishii, Yokkaichi (JP); Isao Nishimura, Yokkaichi (JP); Eiichi Kobayashi, Yokohama (JP)

Correspondence Address: Supervisor, Patent Prosecution Services, PIPER RUDNICK LLP, 1200 Nineteenth Street, N.W., Washington, DC, 20036-2412, US

(21) Appl. No.: 10/428,139

(22) Filed: May 2, 2003

(30) Foreign Application Priority Data
May 9, 2002 (JP) 2002-133816

(51) Int. Cl. G03F 7/038

(52) U.S. Cl. 430/270.1; 430/907

(57) ABSTRACT

A radiation-sensitive resin composition suitable as a chemically-amplified resist is provided. The composition comprised (A) a resin insoluble or scarcely soluble in alkali, but becoming alkali soluble by the action of an acid, and (B) a photoacid generator. The resin comprises a recurring unit of the following formula (I),

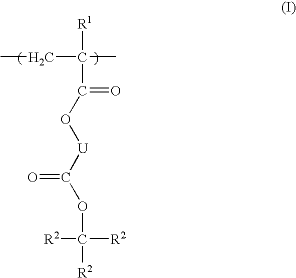

wherein R¹ is typically a hydrogen atom and the —C (R⁵)₃ structure is a 2-methyl-2-tricyclodecanyl group, 2-ethyl-2-tricyclodecanyl group, 2-methyl-2-adamantyl group, 2-ethyl-2-adamantyl group, 1-methylcyclopentyl group, 1-ethylcyclopentyl group, 1-methylcyclohexyl group, or 1-ethylcyclohexyl group.

### BACKGROUND OF THE INVENTION

1. Field of the Invention

The present invention relates to a radiation-sensitive resin composition and, more particularly, to a radiation-sensitive resin composition suitable as a chemically-amplified resist useful for microfabrication utilizing various types of radiations, for example, deep ultraviolet rays such as a KrF excimer laser and an ArF excimer laser, X-rays such as a synchrotron radiation, and charged particle rays such as electron beams.

2. Description of Background Art

In the field of microfabrication represented by the manufacture of integrated circuit devices, lithographic technology enabling microfabrication with a line width of 0.20 μm or less has been demanded in order to increase the degree of integration.

A conventional lithographic process utilizes near ultraviolet rays such as an i-line radiation. However, it is very difficult to perform microfabrication with a line width of sub-quarter micron using near ultraviolet rays.

Therefore, in order to enable microfabrication with a line width of 0.20 μm or less, utilization of radiation with a shorter wavelength has been studied. As radiation with a shorter wavelength, deep ultraviolet rays represented by a line spectrum of a mercury lamp and an excimer laser, X-rays, electron beams, and the like can be given. Of these, a KrF excimer laser (wavelength: 248 nm) and an ArF excimer laser (wavelength: 193 nm) have attracted attention.

As a radiation-sensitive resin composition applicable to the excimer laser radiation, a number of compositions utilizing a chemical amplification effect between a component having an acid-dissociable functional group and a component generating an acid (hereinafter referred to as “photoacid generator”) upon irradiation (hereinafter referred to as “exposure”) have been proposed. Such a composition is hereinafter referred to as a chemically-amplified radiation-sensitive composition.

As the chemically-amplified radiation-sensitive composition, Japanese Patent Publication No. 27660/1990 discloses a composition comprising a polymer containing a t-butyl ester group of carboxylic acid or a t-butylcarbonate group of phenol and a photoacid generator. This composition utilizes the effect of the polymer to release a t-butyl ester group or t-butyl carbonate group in the polymer by the action of an acid generated upon exposure to form an acidic group such as a carboxylic group or a phenolic hydroxyl group, which allows the exposed area on the resist film to be readily soluble in an alkaline developer.

Most of the conventional chemically-amplified radiation-sensitive compositions use a phenol resin as a base resin. Deep ultraviolet rays used as radiations for exposure are absorbed due to an aromatic ring in the resin and cannot sufficiently reach the lower layers of the resist film. Because of this, the dose of the radiation is larger in the upper layers and is smaller in the lower layers of the resist film. This causes a pattern shape to be thinner in the upper portion but to be thicker toward the lower portion, thereby forming a trapezoid shape after development. No sufficient resolution can be obtained from such a resist film. Such a trapezoid resist pattern profile formed after development cannot give a desirable dimensional accuracy in the succeeding steps such as an etching step and an ion implantation step. Moreover, if the shape of the upper part of the resist pattern is not rectangular, the rate of removal of the resist by dry etching is increased, whereby it is difficult to control etching conditions.

The shape of the resist pattern can be improved by increasing the radiation transmittance of the resist film. For example, (meth)acrylate resins represented by polymethylmethacrylate are particularly desirable from the viewpoint of radiation transmittance due to superior transparency to deep ultraviolet rays. Japanese Patent Application Laid-open No. 226461/1992 proposes a chemically-amplified radiation-sensitive composition using a methacrylate resin. However, this composition has insufficient dry etching resistance due to the absence of an aromatic ring, although the composition excels in microfabrication performance. This makes it difficult to perform etching with high accuracy. Therefore, a composition having both transparency to radiation and dry etching resistance cannot be provided.

A method of introducing an alicyclic ring into the resin component in the composition instead of an aromatic ring has been known as a means of improving dry etching resistance without impairing radiation transmittance of the resist made from a chemically-amplified radiation-sensitive composition. A chemically-amplified radiation-sensitive composition using a (meth)acrylate resin having an alicyclic ring is proposed in Japanese Patent Application Laid-open No. 234511/1995, for example.

This composition, however, comprises groups which are comparatively easily dissociated with conventional acids (an acetal functional group such as a tetrahydropyranyl group, for example) and groups which are comparatively difficult to be dissociated with acids (a t-butyl functional group such as a t-butyl ester group, t-butyl carbonate group, for example) as an acid-dissociable functional group as the resin component. The resin component possessing the former acid-dissociable functional group exhibits excellent basic properties as a resist such as superior sensitivity and excellent pattern shape, but has a problem of poor storage stability as a composition, whereas the resin component possessing the latter acid-dissociable functional group exhibits impaired basic properties as a resist, particularly in terms of sensitivity and pattern shape, in spite of excellent storage stability. In addition, inclusion of an alicyclic structure in the resin components of this composition increases hydrophobicity of the resin, resulting in poor adhesion to substrates.

More recently, a chemically amplified radiation sensitive composition using a resin containing a recurring unit derived from a compound in which the carboxyl group of methacrylic acid is protected with a bridged hydrocarbon group having an acid-dissociable ester group, such as a t-butyl group, tetrahydropyran-2-yl group, tetrahydrofuran-2-yl group, 4-methoxytetrahydropyran-4-yl group, 1-ethoxyethoxy group, or 3-oxocyclohexyl group, has been proposed (Japanese Patent Application Laid-open No. 287712/1998). This composition is claimed to exhibit excellent adhesion to substrates, superior transparency to light at a wavelength of 220 nm or less, good etching resistance, and the like. However, the composition is not necessarily satisfactory in transparency to deep ultraviolet rays and in property balance as a resist, including line width stability when the heating temperature after exposure fluctuates.

In view of recent progress in the microfabrication of semiconductor devices, development of a novel resin component exhibiting high transmittance of radiations and having excellent property balance as a resist is crucial for chemically-amplified radiation-sensitive compositions which can be adapted for short wavelength radiations represented by deep ultraviolet rays.

Therefore, an object of the present invention is to provide a radiation-sensitive resin composition having high transmittance of radiations and exhibiting superior basic properties as a resist such as high sensitivity, resolution, pattern shape, dry etching resistance, and line width stability when the heating temperature after exposure fluctuates.

### SUMMARY OF THE INVENTION

The above object is solved in the present invention by a radiation-sensitive resin composition comprising:

(A) a resin insoluble or scarcely soluble in alkali, but becoming alkali soluble by the action of an acid, the resin comprising a recurring unit of the following formula (I),

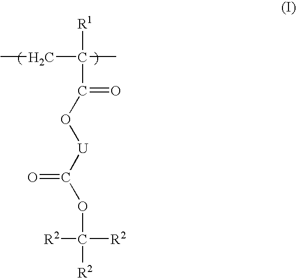

wherein R¹ represents a hydrogen atom, methyl group, a linear or branched hydroxy alkyl group having 1-4 carbon atoms, or a linear or branched fluorinated alkyl group having 1-4 carbon atoms, R² individually represents a monovalent alicyclic hydrocarbon group having 4-20 carbon atoms or a derivative thereof, or a linear or branched alkyl group having 1-4 carbon atoms, provided that at least one R² is a monovalent alicyclic hydrocarbon group having 4-20 carbon atoms or a derivative thereof, or any two of the R² groups form, in combination and together with the carbon atoms to which the two R² groups bond, a divalent alicyclic hydrocarbon group having 4-20 carbon atoms or a derivative thereof, with the remaining R² groups being a linear or branched alkyl group having 1-4 carbon atoms or a monovalent alicyclic hydrocarbon group having 4-20 carbon atoms or a derivative thereof, and U represents a divalent bridged hydrocarbon group having 5-12 carbon atoms, and

(B) a photoacid generator.

In the above composition, R¹ in the formula (I) is preferably a hydrogen atom or a methyl group.

In the above composition, the divalent bridged hydrocarbon group represented by U in the formula (I) is preferably a group derived from bicyclo[2.2.1]heptane, tetracyclo[6.2.1.1^{3,6}.0^{2,7}]dodecane, tricyclo[5.2.1.0^{2,6}]decane, or tricyclo[4.2.1.0^{3,7}]nonane.

In the above composition, the group —C(R²)₃ in the formula (I) is preferably a 1-alkyl substituted cycloalkyl group, 1-alkyl substituted bridged hydrocarbon group, or 1-bridged hydrocarbon substituted alkyl group.

It is still more preferable that group —C(R²)₃ in the formula (I) be a 1-methylcyclopentyl group, 1-ethylcyclopentyl group, 1-methylcyclohexyl group, 1-ethylcyclohexyl group, 2-methyladamantan-2-yl group, 2-ethyladamantan-2-yl group, 2-methylbicyclo[2.2.1]heptan-2-yl group, 2-ethylbicyclo[2.2.1]heptan-2-yl group, or 1-methyl-1-(bicyclo[2.2.1]heptan-2-yl)ethyl group.

In the above composition, the resin (A) preferably comprises a recurring unit of the following formula (I−1),

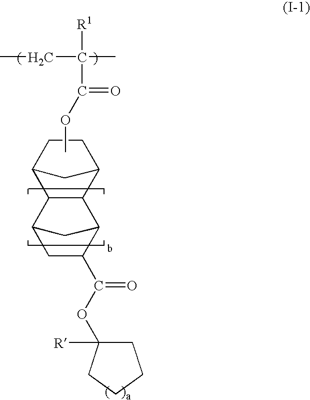

wherein R represents a hydrogen atom or a methyl group, R¹ represents a methyl group or ethyl group, a is 1 or 2, and b is 0 or 1.

In the above composition, the resin (A) preferably comprises a recurring unit of the following formula (III),

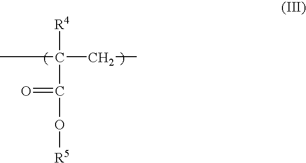

wherein R⁴ represents a hydrogen atom, a methyl group, a linear or branched hydroxyalkyl group having 1-4 carbon atoms, or a linear or branched fluoroalkyl group having 1-4 carbon atoms, and R⁵ represents a hydrogen atom or a monovalent organic group.

The R⁵ group in the formula (III) is preferably a monovalent organic group.

It is still more preferable that the R⁵ group in the formula (III) be a linear or branched alkyl group having 1-6 carbon atoms, a monovalent organic group with an alicyclic structure having 4-20 carbon atoms, a monovalent organic group with a cyclic ether structure, a substituted or unsubstituted monovalent organic group with a lactone skeleton, or a group of the following formulas (3-1) or (3-2),

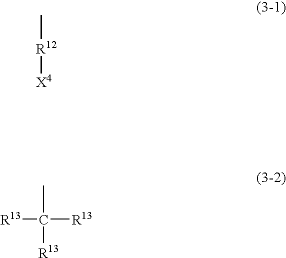

wherein R¹² represents a linear or branched divalent organic group or a divalent organic group having an alicyclic structure, X⁴ represents a hydrogen atom or a monovalent functional group, and R¹³ individually represents a linear or branched alkyl group having 1-4 carbon atoms, an oxoalkyl group having 2-4 carbon atoms, or a monovalent alicyclic hydrocarbon group having 4-20 carbon atoms or a derivative thereof, or any two of R¹³ groups form in combination a divalent alicyclic hydrocarbon group having 4-20 carbon atoms or a derivative thereof, with the remaining R¹³ group being a linear or branched alkyl group having 1-4 carbon atoms, an oxoalkyl group having 2-4 carbon atoms, or a monovalent alicyclic hydrocarbon group having 4-20 carbon atoms or a derivative thereof.

It is particularly preferable in the above composition that the R⁵ group in the formula (III) be a hydrogen atom.

In the above composition, the content of the recurring unit (I) in the resin (A) is preferably 10-70 mol % of the total amount of the recurring units.

In the above composition, the resin (A) preferably has a polystyrene-reduced weight average molecular weight determined by gel permeation chromatography of 2,000 to 200,000.

In the above composition, the acid produced by the acid generator (B) is preferably a compound of any one of the following formulas (BA−1) to (BA−5),

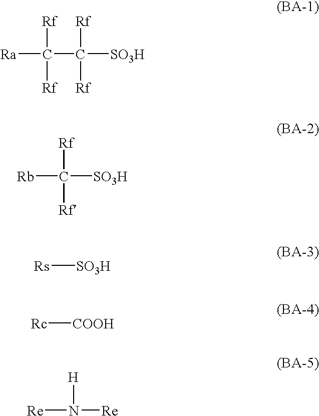

wherein, in the formula (BA−1), Rf individually represents a fluorine atom or trifluoromethyl group, Ra represents a hydrogen atom, a fluorine atom, a linear or branched alkyl group having 1-20 carbon atoms, a linear or branched fluoroalkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms; in the formula (BA−2), Rf represents a fluorine atom or a trifluoromethyl group, Rf′ represents a hydrogen atom, fluorine atom, methyl group, or trifluoromethyl group, and Rb represents a hydrogen atom, a linear or branched alkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms; in the formula (BA−3), Rs represents a linear or branched alkyl group having 1-20 carbon atoms or a substituted or unsubstituted monovalent cyclic hydrocarbon group having 3-20 carbon atoms; in the formula (BA−4), Rc represents a linear or branched alkyl group having 1-20 carbon atoms, a linear or branched fluoroalkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms; in the formula (BA−5), Re represents a Ra—SO₂ group or Ra—CO— group, wherein Ra is the same as defined for the above formula (BA−1); provided that when the acid produced by the acid generator (B) contains a mixture of the acid of the formula (BA−1) and the acid of the formula (BA−5), the Ra groups in the formulas (BA−1) and (BA−5) may be either the same or different.

It is particularly preferable that the compound generating the acids of the above formulas (BA−1) to (BA−5) be an onium salt, sulfoneimide compound, sulfone compound, sulfonate compound, disulfonyldiazomethane compound, disulfonylmethane compound, oxime sulfonate compound, or hydrazine sulfonate compound.

In the above composition, the amount of the photoacid generator (B) is preferably 0.1-20 parts by weight for 100 parts by weight of the resin (A).

It is preferable that the above composition further comprises an acid diffusion controller.

In the above composition, the amount of the acid diffusion controller is 0.001-5 parts by weight for 100 parts by weight of the resin (A).

Other objects, features and advantages of the invention will hereinafter become more readily apparent from the following description.

### BRIEF DESCRIPTION OF THE DRAWINGS

FIG. 1 is a ¹H-NMR spectrum of monomer (i−1−a) prepared in Synthetic Example 1.

FIG. 2 is a ¹³C-NMR spectrum of monomer (i−1−a) prepared in Synthetic Example 1.

### DETAILED DESCRIPTION OF THE INVENTION AND PREFERRED EMBODIMENTS

The present invention is described below in detail. Component (A)

The component (A) of the present invention is a resin comprising a recurring unit of the above formula (I) (hereinafter referred to as “recurring unit (I)”). The resin is insoluble or scarcely soluble in alkali, but becomes alkali soluble by the action of an acid (this resin is hereinafter referred to as “resin (A)”).

The term “alkali insoluble” or “scarcely alkali-soluble” used herein indicates the following properties of a resin: In the case of developing a film using only the resin (A) instead of a resist film under alkaline development conditions employed when forming a resist pattern of the resist film formed from the radiation-sensitive resin composition containing the resin (A), the term “alkali insoluble” or “scarcely alkali-soluble” refers to properties in which 50% or more of the initial thickness of the resist film remains after development.

In the recurring unit (I) in the resin (A), both the monovalent alicyclic hydrocarbon group represented by R² and the divalent alicyclic hydrocarbon group formed by the two R² groups and the carbon atom to which these two groups bond may have a bridged hydrocarbon skeleton. The following formulas (A) to (E) show major bridged hydrocarbon skeletons with carbon atom positional numbers in these bridged hydrocarbon groups, including the bridged hydrocarbon groups represented by U.

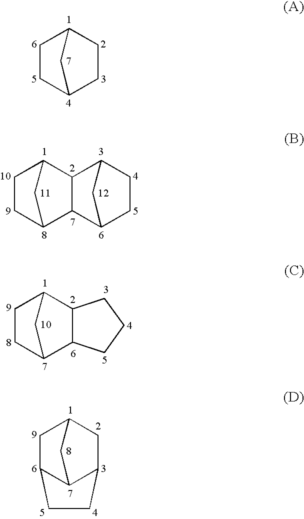

In the above formulas, the formula (A) shows bicyclo[2.2.1]heptane, the formula (B) shows tetracyclo[6.2.1.1^{3,6}.0^{2,7}]dodecane, the formula (C) shows tricyclo[5.2.1.0^{2,6}]decane, and the formula (D) shows tricyclo[4.2.1.0^{3,7}]nonane. In the following description, nomenclature of bridged hydrocarbon skeletons follows the formulas (A) to (D).

As examples of the linear or branched hydroxyalkyl groups having 1-4 carbon atoms represented by R¹ in the formula (I), a hydroxymethyl group, 1-hydroxyethyl group, 2-hydroxyethyl group, 1-hydroxypropyl group, 2-hydroxypropyl group, 3-hydroxypropyl group, 1-hydroxybutyl group, 2-hydroxybutyl group, 3-hydroxybutyl group, and 4-hydroxybutyl group can be given.

As examples of the linear or branched fluoroalkyl group having 1-4 carbon atoms represented by R¹, a monofluoromethyl group, difluoromethyl group, trifluoromethyl group, 1-fluoroethyl group, 1,2-difluoroethyl group, 2,2,2-trifluoroethyl group, 1,1,2,2-tetrafluoroethyl group, pentafluoroethyl group, heptafluoro-n-propyl group, and nonafluoro-n-butyl group can be given.

Preferable groups for R¹ in the formula (I) are a hydrogen atom, methyl group, hydroxymethyl group, trifluoromethyl group, and the like.

The following groups are given as examples of the monovalent alycyclic hydrocarbon group having 4-20 carbon atoms and its derivatives represented by R² in the formula (I): a cycloalkyl group such as a cyclobutyl group, cyclopentyl group, cyclohexyl group, cycloheptyl group, and cyclooctyl group; a bridged hydrocarbon group such as an adamantan-1-yl group, bicyclo[2.2.1]heptan-2-yl group, tetracyclo[6.2.1.1^{3,6}.0^{2,7}]dodecan-4-yl group, and tricyclo[5.2.1.0^{2,6}]decan-8-yl group; a group obtained by substituting one or more hydrogen atoms on these cycloalkyl groups or the bridged hydrocarbon groups by a linear, branched, or cyclic alkyl group having 1-4 carbon atoms such as a methyl group, ethyl group, n-propyl group, i-propyl group, n-butyl group, 2-methylpropyl group, 1-methylpropyl group, or t-butyl group; and derivatives of these alicyclic hydrocarbon groups which may be substituted with alkyl groups obtained by substituting one or more hydrogen atoms therein with a hydroxyl group, carboxyl group, nitro group, cyano group, amino group, and the like.

The following groups can be given as examples of the divalent alicyclic hydrocarbon group having 4-20 carbon atoms formed by any two R² groups together with the carbon atoms to which these two R² groups bond or the derivative thereof: groups derived from a cycloalkane such as cyclobutane, cyclopentane, cyclohexane, cycloheptane, or cyclooctane and groups derived from a bridged hydrocarbon such as adamantane, bicyclo[2.2.1]heptane, tetracyclo[6.2.1.1^{3,6}.0^{2,7}]dodecane, or tricyclo[5.2.1.0^{2,6}]decane; groups obtained by substituting one or more hydrogen atoms on these groups derived from the cycloalkanes or bridged hydrocarbons by a linear, branched, or cyclic alkyl group having 1-4 carbon atoms such as a methyl group, ethyl group, n-propyl group, i-propyl group, n-butyl group, 2-methylpropyl group, 1-methylpropyl group, or t-butyl group; and derivatives of these groups derived from the cycloalkanes or bridged hydrocarbons which may be substituted with alkyl groups obtained by substituting one or more hydrogen atoms therein with a hydroxyl group, carboxyl group, nitro group, cyano group, amino group, and the like.

As examples of the linear or branched alkyl group having 1-4 carbon atoms represented by R², a methyl group, ethyl group, n-propyl group, i-propyl group, n-butyl group, 2-methylpropyl group, 1-methylpropyl group, and t-butyl group can be given.

The following groups are given as examples of the structure represented by -C(R²)₃ group in the formula (I):

1-alkyl-substituted cycloalkyl groups such as a

1-methylcyclopentyl group, 1-ethylcyclopentyl group,

1-methylcyclohexyl group, and 1-ethylcyclohexyl group;

1-alkyl-substituted bridged hydrocarbon groups such as a

2-methyladamantan-2-yl group, 2-ethyladamantane-2-yl group,

2-methylbicyclo[2.2.1]heptan-2-yl group,

2-ethylbicyclo[2.2.1]heptan-2-yl group,

4-methyltetracyclo[6.2.1.1^{3,6}.0^{2,7}]dodecan-4-yl group,

4-ethyltetracyclo[6.2.1.1^{3,6}.0^{2,7}]dodecan-4-yl group,

8-methyltricyclo[5.2.1.0^{2,6}]decan-8-yl group, and

8-ethyltricyclo[5.2.1.0^{2,6}]decan-8-yl) group; and

1-bridged hydrocarbon-substituted alkyl groups such as a

1-methyl-1-(adamantan-1-yl)ethyl group,

1-methyl-1-(bicyclo[2.2.1]heptan-2-yl)ethyl group,

1-methyl-1-(tetracyclotetracyclo[6.2.1.1^{3,6}.0^{2,7}]dodecan-4-yl)ethyl group, and

1-methyl-1-(tricyclotricyclo[5.2.1.0^{2,6}]decan-8-yl)ethyl group.

Among these groups representing the structure corresponding to the —C(R²)₃ group, 1-methylcyclopentyl group, 1-ethylcyclopentyl group, 1-methylcyclohexyl group, 1-ethylcyclohexyl group, 2-methyladamantan-2-yl group, 2-ethyladamantan-2-yl group, 2-methylbicyclo[2.2.1]heptan-2-yl group, 2-ethylbicyclo[2.2.1]heptan-2-yl group, and 1-methyl-1-(bicyclo[2.2.1]heptan-2-yl)ethyl group are preferable, with particularly preferable groups being 1-methylcyclopentyl group, 1-ethylcyclopentyl group, 1-methylcyclohexyl group, and 1-ethylcyclohexyl group.

As examples of the divalent bridged hydrocarbon group having 5-12 carbon atoms represented by U in the formula (I) groups derived from adamantane, bicyclo[2.2.1]heptane, tetracyclo[6.2.1.1^{3,6}.0^{2,7}]dodecane, or tricyclo[5.2.1.0^{2,6}]decane can be given.

As a particularly preferable recurring unit (I) in the present invention, the recurring unit of the following formula (I−1) (hereinafter referred to as “recurring unit (I−1)”), for example, can be given.

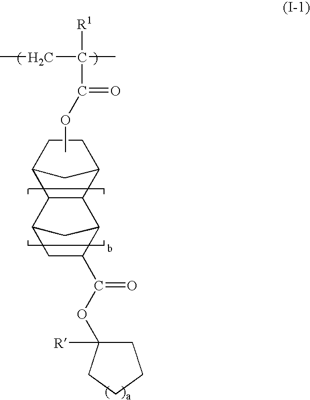

wherein R represents a hydrogen atom or a methyl group, R′ represents a methyl group or ethyl group, a is 1 or 2, and b is 0 or 1.

Monomers from which the recurring unit (I) is derived are represented by the following formula (i) and monomers from which the recurring unit (I−1) is derived are represented by the following formula (i−1).

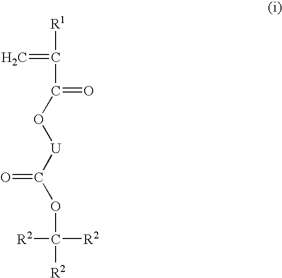

wherein R¹, R², and U are the same as defined for the above formula (I).

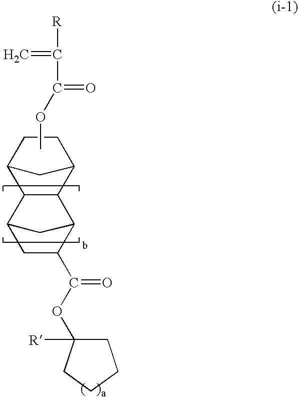

wherein R, R′, a, and b are respectively the same as those defined in the above formula (I−1).

The monomers represented by the formula (i−1) are synthesized by the following methods, for example.

1) bicyclo[2.2.1]hept-2-ene-5-carboxylic acid 1-methylcyclopentyl is reacted with formic acid, a BH₃-tetrahydrofuran complex, and the like to obtain 1-methylcyclopentyl 2-hydroxycarbonyloxybicyclo[2.2.1]-heptan-5-carboxylate or 1-methylcyclopentyl 3-hydroxycarbonyloxy bicyclo[2.2.1]heptan-5-carboxylate.

2) The compound obtained in 1) is hydrolyzed with a base such as sodium carbonate or the like to obtain 1-methylcyclopentyl 2-hydroxybicyclo[2.2.1]hept-2-ene-5-carboxylate or 1-methylcyclopentyl 3-hydroxybicyclo[2.2.1]hept-2-ene-5-carboxylate.

3) The compound obtained in 2) is reacted with an equivalent amount of (meth)acrylic acid chloride in the presence of a base such as sodium hydroxide to dehydrochlorinate, thereby obtaining 1-methylcyclopentyl 2-(meth)acryloyloxybicyclo[2.2.1]hept-2-ene-5-carboxylate of the following formula (i−1−1) or 1-methylcyclopentyl 3-(meth)acryloyloxybicyclo[2.2.1]hept-2-ene-5-carboxylate of the following formula (i−1−2),

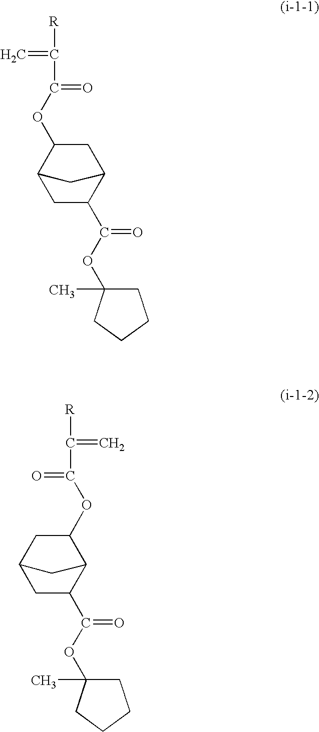

wherein R represents a hydrogen atom or methyl group.

As specific examples of monomers of the formula (i−1) other than monomers represented by the formulas (i−1−1) or (I−1−2), monomers of the following formulas (i−1−3) to (I−1−16) wherein R represents a hydrogen atom or a methyl group, can be given.

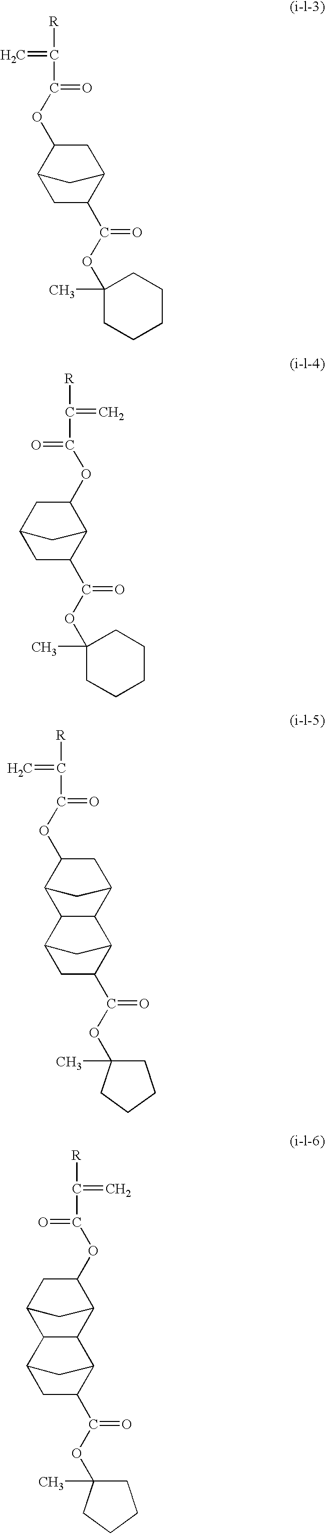

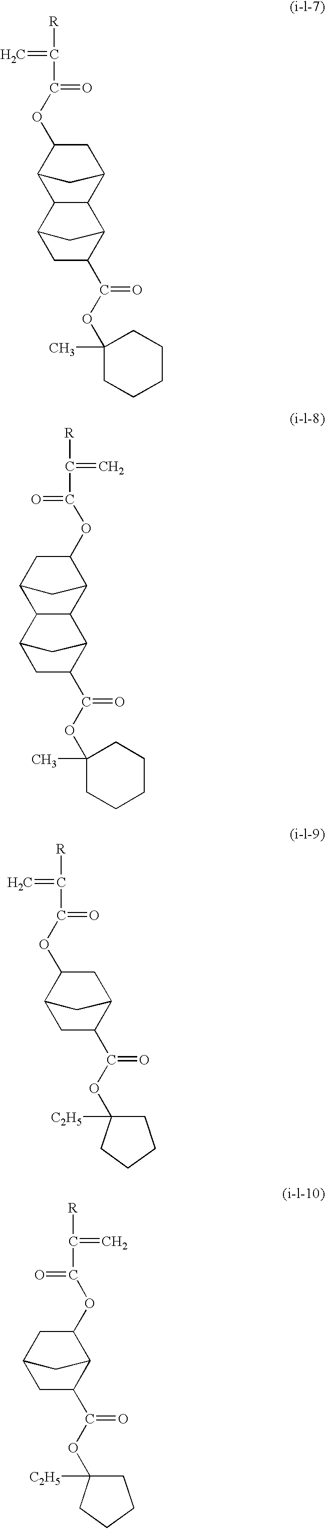

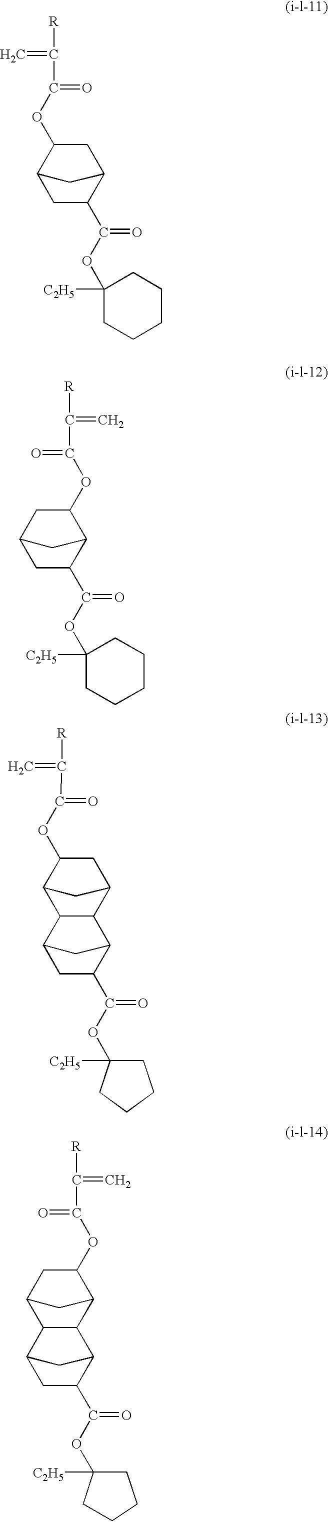

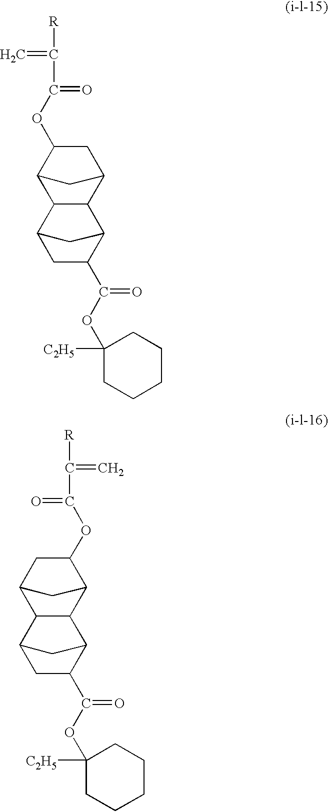

Either one type of recurring unit (I) may be used alone or a combination of two or more types of recurring unit (I) may be used in the resin (A).

In addition, the resin (A) may comprise one or more recurring units other than the recurring unit (I) (hereinafter referred to as “other recurring units”).

As preferable examples of the other recurring units, a recurring unit of the following formula (II) (hereinafter called “recurring unit (II)”) and a recurring unit of the following formula (III) (hereinafter called “recurring unit (III)”) can be given.

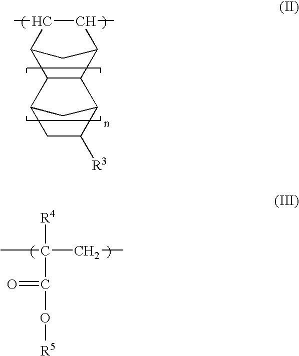

wherein R³ indicates a monovalent group, n is an integer of 0-2, R⁴ represents a hydrogen atom, a methyl group, a linear or branched hydroxyalkyl group having 1-4 carbon atoms, or a linear or branched fluoroalkyl group having 1-4 carbon atoms, and R⁵ represents a hydrogen atom or a monovalent organic group.

As examples of the monovalent group represented by R³ in the formula (II), groups of the following formulas (1-1) to (1-4) can be given.

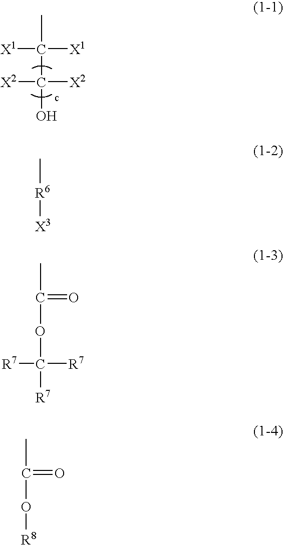

wherein X¹ individually represents a hydrogen atom, a fluorine atom, a linear or branched alkyl group having 1-4 carbon atoms, or a linear or branched fluoroalkyl group having 1-4 carbon atoms, X² individually represents a hydrogen atom, a fluorine atom, a linear or branched alkyl group having 1-4 carbon atoms, or a linear or branched fluoroalkyl group having 1-4 carbon atoms, and c is an integer of 0-5; R⁶ represents a single bond, a linear or branched divalent organic group, or a divalent organic group having an alicyclic structure, and X³ represents a hydrogen atom or a monovalent functional group; R⁷ individually represents a linear or branched alkyl group having 1-4 carbon atoms, an oxoalkyl group having 2-4 carbon atoms, or a monovalent alicyclic hydrocarbon group having 4-20 carbon atoms or a derivative thereof, or any two of R⁷ groups form in combination a divalent alicyclic hydrocarbon group having 4-20 carbon atoms or a derivative thereof, with the remaining R⁷ group being a linear or branched alkyl group having 1-4 carbon atoms, an oxoalkyl group having 2-4 carbon atoms, or a monovalent alicyclic hydrocarbon group having 4-20 carbon atoms or a derivative thereof; and R⁸ represents a linear or branched alkyl group having 1-6 carbon atoms, a monovalent organic group with an alicyclic structure having 4-20 carbon atoms, a monovalent organic group with a cyclic ether structure, or a substituted or unsubstituted monovalent organic group with a lactone skeleton.

As examples of the linear or branched alkyl group having 1-4 carbon atoms represented by X¹ or X² in the formula (1-1), a methyl group, ethyl group, n-propyl group, i-propyl group, n-butyl group, 2-methylpropyl group, 1-methylpropyl group, and t-butyl group can be given.

As examples of the linear or branched fluoroalkyl group having 1-4 carbon atoms represented by X¹ or X² in the formula (1-1), a monofluoromethyl group, difluoromethyl group, trifluoromethyl group, 1-fluoroethyl group, 1,2-difluoroethyl group, 2,2,2-trifluoroethyl group, 1,1,2,2-tetrafluoroethyl group, pentafluoroethyl group, heptafluoro-n-propyl group, and nonafluoro-n-butyl group can be given.

Preferable groups represented by Xor X² in the formula (1-1) are a hydrogen atom, methyl group, fluorine atom, trifluoromethyl group, and the like.

As preferable examples of the group represented by R³in the formula (1-1), a hydroxymethyl group, 2-hydroxyethyl group, 3-hydroxypropyl group, (fluoro)(hydroxy)methyl group, (difluoro) (hydroxy)methyl group, 1,2-difluoro-2-hydroxyethyl group, 1,1,2,2-tetrafluoro-2-hydroxyethyl group, 2-trifluoromethyl-2-hydroxyethyl group, 2,2-di(trifluoromethyl)-2-hydroxyethyl group, and the like can be given.

As examples of the linear or branched divalent organic group represented by R⁶ in the formula (1-2), a methylene group and alkylene groups having 2-12 carbon atoms such as ethylene group, propylene group, trimethylene group, tetramethylene group, 2-methyltrimethylene group, hexamethylene group, octamethylene group, and decamethylene group can be given.

As examples of the divalent organic group having an alicyclic structure represented by R⁶, groups derived from a cycloalkane having 4-20 carbon atoms such as cyclobutane, cyclopentane, cyclohexane, cycloheptane, or cyclooctane and groups derived from a bridged hydrocarbon having 4-20 carbon atoms such as adamantane, bicyclo[2.2.1]heptane, tetracyclo[6.2.1.1^{3,6}.0^{2,7}]dodecane, or tricyclo[5.2.1.0^{2,6}]decane can be given.

As R⁶ in the formula (1-2), a single bond, methylene group, ethylene group, divalent group derived from adamantane, divalent group derived from bicyclo[2.2.1]heptane, and the like are preferable.

As examples of the monovalent functional group represented by X³ in the formula (1-2), a hydroxyl group, carboxyl group, nitro group, cyano group, and amino group can be given.

As X³ in the formula (1-2), a hydrogen atom, hydroxyl group, carboxyl group, cyano group, and the like are preferable.

The following groups can be given as preferable examples of the group shown by the formula (1-2) representing R³ in the general formula (II): a hydrogen atom, hydroxyl group, hydroxymethyl group, 2-hydroxyethyl group, 3-hydroxypropyl group, 3-hydroxyadamantan-1-yl group, 5-hydroxybicyclo[2.2.1]heptan-2-yl group, 6-hydroxybicyclo[2.2.1]heptan-2-yl group, 9-hydroxy tetra cyclo[6.2.1.1^{3,6}.0^{2,7}]dodecan-4-yl group, 10-hydroxytetracyclo[6.2.1.1^{3,6}.0^{2,7}]dodecan-4-yl group, carboxyl group, carboxymethyl group, 2-carboxyethyl group, 3-carboxypropyl group, 3-carboxyadamantan-1-yl group, 5-carboxybicyclo[2.2.1]heptan-2-yl group, 6-carboxybicyclo[2.2.1]heptan-2-yl group, 9-carboxytetracyclo[6.2.1.1^{3,6}.0^{2,7}]dodecan-4-yl group, 10-carboxytetracyclo[6.2.1.1^{3,6}.0^{2,7}]dodecan-4-yl group, cyano group, cyanomethyl group, 2-cyanoethyl group, 3-cyanopropyl group, 3-cyanoadamantan-1-yl group, 5-cyanobicyclo[2.2.1]heptan-2-yl group, 6-cyanobicyclo[2.2.1]heptan-2-yl group, 9-cyanotetracyclo[6.2.1.1^{3,6}.0^{2,7}]dodecan-4-yl group, and 10-cyanotetracyclo[6.2.1.1^{3,6}.0^{2,7}]dodecan-4-yl group.

As examples of the monovalent alicyclic hydrocarbon group having 4-20 carbon atoms or a derivative thereof represented by R⁷ in the formula (1-3) and the divalent alicyclic hydrocarbon group having 4-20 carbon atoms formed by two R⁷ groups and the carbon atom to which the two R⁷ groups bond or a derivative thereof, groups derived from a cycloalkane such as cyclobutane, cyclopentane, cyclohexane, cycloheptane, or cyclooctane or from a bridged hydrocarbon such as adamantane, bicyclo[2.2.1]heptane, tetracyclo[6.2.1.1^{3,6}.0^{2,7}]dodecane, or tricyclo[5.2.1.0^{2,6}]decane; groups in which one or more hydrogen atoms of these groups derived from the cycloalkane or bridged hydrocarbon are replaced with a linear, branched, or cyclic alkyl group having 1-4 carbon atoms such as a methyl group, ethyl group, n-propyl group, i-propyl group, n-butyl group, 2-methylpropyl group, 1-methylpropyl group, and t-butyl group; and groups in which one or more hydrogen atoms of these groups derived from the cycloalkane or bridged hydrocarbon, which may be either substituted or unsubstituted with an alkyl group, are replaced with a hydroxyl group, carboxyl group, nitro group, cyano group, or amino group can be given.

As examples of the linear or branched alkyl group having 1-4 carbon atoms represented by R⁷, a methyl group, ethyl group, n-propyl group, i-propyl group, n-butyl group, 2-methylpropyl group, 1-methylpropyl group, and t-butyl group can be given.

As examples of the oxoalkyl group having 2-4 carbon atoms represented by R⁷, a 1-oxoethyl group, 1-oxopropyl group, and 1-oxo-n-butyl group can be given.

The following groups can be given as preferable examples of the structure corresponding to the group —C(R²)₃ represented by the formula (1-3) in the formula (II):

t-butyl group, 2-methyl-2-butyl group, 2-ethyl-2-butyl group,

3-ethyl-3-butyl group, 1,1-dimethyl-2-oxopropyl group,

1,1-dimethyl-2-oxo-n-butyl group, 1-methylcyclopentyl group,

1-ethylcyclopentyl group, 1-methylcyclohexyl group,

1-ethylcyclohexyl group, 2-methyladamantan-2-yl group,

2-ethyladamantan-2-yl group,

2-methyl-3-hydroxyadamantan-2-yl group,

2-methylbicyclo[2.2.1]heptan-2-yl group,

2-ethylbicyclo[2.2.1]heptan-2-yl group,

4-methyltetracyclo[6.2.1.1^{3,6}.0^{2,7}]dodecan-4-yl group,

4-ethyltetracyclo[6.2.1.1^{3,6}.0^{2,7}]dodecan-4-yl group,

8-methyltricyclo[5.2.1.0^{2,6}]decan-8-yl group,

8-ethyltricyclo[5.2.1.0^{2,6}]decan-8-yl) group,

1-methyl-1-cyclopentylethyl group,

1-methyl-1-(2-hydroxycyclopentyl)ethyl group,

1-methyl-1-(3-hydroxycyclopentyl)ethyl group,

1-methyl-1-cyclohexylethyl group,

1-methyl-1-(3-hydroxycyclohexyl)ethyl group,

1-methyl-1-(4-hydroxycyclohexyl)ethyl group,

1-methyl-1-cycloheptylethyl group,

1-methyl-1-(3-hydroxycycloheptyl)ethyl group,

1-methyl-1-(4-hydroxycycloheptyl)ethyl group,

1-methyl-1-(adamantan-1-yl)ethyl group,

1-methyl-1-(3-hydroxyadamantan-1-yl)ethyl group,

1-methyl-1-(bicyclo[2.2.1]heptan-2-yl)ethyl group,

1-methyl-1-(tetracyclo[6.2.1.1^{3,6}.0^{2,7}]dodecan-4-yl)ethyl

group, 1-methyl-1-(tricyclo[5.2.1.0^{2,6}]decan-8-yl) ethyl group,

1,1-dicyclopentylethyl group, 1,1-dicyclohexylethyl group,

1,1-di(adamantan-1-yl)ethyl group,

1,1-di(bicyclo[2.2.1]heptan-2-yl)ethyl group,

1,1-di(tetracyclo[6.2.1.1^{3,6}.0^{2,7}]dodecan-4-yl)ethyl group,

and 1,1-di(tricyclo[5.2.1.0^{2,6}]decan-8-yl)ethyl group.

As examples of the linear or branched alkyl group having 1-6 carbon atoms represented by R⁸ in the formula (1-4), a methyl group, ethyl group, n-propyl group, i-propyl group, n-butyl group, 2-methylpropyl group, and 1-methylpropyl group can be given.

As examples of the monovalent organic group with an alicyclic structure having 4-20 carbon atoms represented by R⁸, groups derived from a cycloalkane such as cyclobutane, cyclopentane, cyclohexane, cycloheptane, or cyclooctane; groups derived from a bridged hydrocarbon such as adamantane, bicyclo[2.2.1]heptane, tetracyclo[6.2.1.1^{3,6}.0^{2,7}]dodecane, or tricyclo[5.2.1.0^{2,6}]decane; groups in which one or more hydrogen atoms of these groups derived from the cycloalkane or bridged hydrocarbon are replaced with a linear, branched, or cyclic alkyl group having 1-4 carbon atoms such as a methyl group, ethyl group, n-propyl group, i-propyl group, n-butyl group, 2-methylpropyl group, 1-methylpropyl group, and t-butyl group; and groups in which one or more hydrogen atoms of the monovalent groups derived from the cycloalkane or bridged hydrocarbon, which may be either substituted or unsubstituted with an alkyl group, are replaced with a hydroxyl group, carboxyl group, nitro group, cyano group, or amino group can be given.

As examples of the monovalent organic group having a cyclic ether structure represented by R⁸, a tetrahydrofuran-2-yl group, tetrahydropyran-2-yl group, and the like which may be bonded with a linear, branched, or cyclic alkyl group such as a methyl group, ethyl group, n-propyl group, i-propyl group, n-butyl group, 2-methylpropyl group, 1-methylpropyl group, or t-butyl group can be given.

As examples of the substituted or unsubstituted monovalent organic group having a lactone skeleton represented by R⁸, groups shown by the following formulas (2-1) to (2-4) can be given.

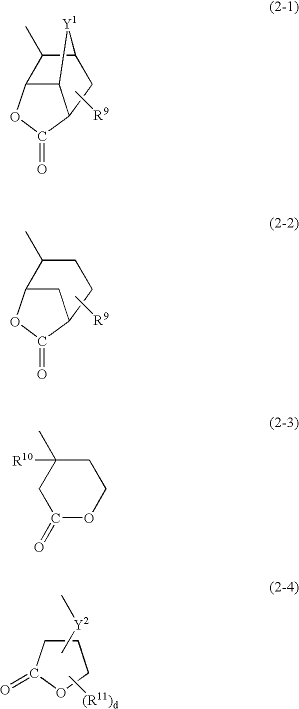

wherein R⁹ individually represents a hydrogen atom, a linear or branched alkyl group having 1-5 carbon atoms, a linear or branched alkoxyl group having 1-5 carbon atoms, or a linear or branched alkoxycarbonyl group having 2-5 carbon atoms, Y¹ represents a methylene group, dimethylmethylene group, oxygen atom, or sulfur atom, R¹⁰ represents a hydrogen atom, linear or branched alkyl group having 1-5 carbon atoms, linear or branched alkoxyl group having 1-5 carbon atoms, or linear or branched alkoxycarbonyl group having 2-5 carbon atoms, R¹ individually represents a hydrogen atom, linear or branched alkyl group having 1-5 carbon atoms, linear or branched alkoxyl group having 1-5 carbon atoms, or linear or branched alkoxycarbonyl group having 2-5 carbon atoms, d is an integer of 0-4, and Y² is a single bond or a methylene group.

As examples of the linear or branched alkyl group having 1-5 carbon atoms represented by R⁹, R¹⁰, or R¹¹ in the formulas (2-1) to (2-4), a methyl group, ethyl group, n-propyl group, i-propyl group, n-butyl group, 1-methylpropyl group, 2-methylpropyl group, t-butyl group, and n-pentyl group can be given.

As examples of the linear or branched alkoxyl group having 1-5 carbon atoms represented by R⁹, R¹⁰, or R¹¹, a methoxy group, ethoxy group, n-propoxy group, i-propoxy group, n-butoxy group, 1-methylpropoxy group, 2-methylpropoxy group, t-butoxy group, and n-pentyloxy group can be given.

As examples of the linear or branched alkoxylcarbonyl group having 2-5 carbon atoms represented by R⁹, R¹⁰, or R¹¹, a methoxycarbonyl group, ethoxycarbonyl group, n-propoxycarbonyl group, i-propoxycarbonyl group, n-butoxycarbonyl group, 1-methylpropoxycarbonyl group, 2-methylpropoxycarbonyl group, and t-butoxycarbonyl group can be given.

The following groups can be given as preferable examples of the R⁸ group in the formula (1-4) which represents the R³ group in the formula (II): linear or branched alkyl groups such as a methyl group, ethyl group, and n-propyl group; cycloalkyl groups such as a cyclopentyl group and cyclohexyl group; groups derived from a bridged hydrocarbon such as an adamantan-1-yl group, bicyclo[2.2.1]heptan-2-yl group, 7,7-dimethylbicyclo[2.2.l]heptan-1-yl group, tetracyclo[6.2.1.1^{3,6}.0^{2,7}]dodecan-4-yl group, and tricyclo[5.2.1.0^{2,6}]decan-8-yl group; an organic group having a cyclic ether structure such as a (tetrahydrofuran-2-yl)methyl group; and organic groups with a lactone skeleton which may be either substituted or unsubstituted such as a 5-oxo-4-oxatricyclo[4.2.1.0^{3,7}]nonan-2-yl group, 9-methoxycarbonyl-5-oxo 4-oxatricyclo[4.2.1.0^{3,7}]nonan-2-yl group, 7-oxo-6-oxabicyclo[3.2.1]octan-4-yl group, 2-methoxycarbonyl 7-oxo-6-oxa-bicyclo[3.2.1]octan-4-yl group, 2-oxotetrahydropyran-4-yl group, 4-methyl-2-oxotetrahydropyran-4-yl group, 4-ethyl-2-oxotetrahydropyran-4-yl group, 4-n-propyl-2-oxotetrahydropyran-4-yl group, 5-oxotetrahydrofuran-3-yl group, 2,2-dimethyl-5-oxotetrahydrofuran-3-yl group, 4,4-dimethyl-5-oxotetrahydrofuran-3-yl group, 2-oxotetrahydrofuran-3-yl group, 4,4-dimethyl-2-oxotetrahydrofuran-3-yl group, 5,5-dimethyl-2-oxotetrahydrofuran-3-yl group, 2-oxotetrahydrofuran-3-yl group, (5-oxotetrahydrofuran-2-yl)methyl group, (3,3-dimethyl-5-oxotetrahydrofuran-2-yl)methyl group, and (4,4-dimethyl-5-oxotetrahydrofuran-2-yl)methyl group.

As examples of the linear or branched hydroxyalkyl groups having 1-4 carbon atoms represented by R⁴ in the formula (III), a hydroxymethyl group, 1-hydroxyethyl group, 2-hydroxyethyl group, 1-hydroxypropyl group, 2-hydroxypropyl group, 3-hydroxypropyl group, 1-hydroxybutyl group, 2-hydroxybutyl group, 3-hydroxybutyl group, and 4-hydroxybutyl group can be given.

As examples of the linear or branched fluoroalkyl group having 1-4 carbon atoms represented by R⁴, a monofluoromethyl group, difluoromethyl group, trifluoromethyl group, 1-fluoroethyl group, 1,2-difluoroethyl group, 2,2,2-trifluoroethyl group, 1,1,2,2-tetrafluoroethyl group, pentafluoroethyl group, heptafluoro-n-propyl group, and nonafluoro-n-butyl group can be given.

Preferable groups for R⁴ in the formula (III) are a hydrogen atom, methyl group, monofluoromethyl group, difluoromethyl group, trifluoromethyl group, hydroxymethyl group, 2-hydroxyethyl group, and the like.

As examples of the monovalent organic group represented by R⁵, a linear or branched alkyl group having 1-6 carbon atoms, a monovalent organic group with a cyclic structure having 4-20 carbon atoms, a monovalent organic group with an ether structure, a substituted or unsubstituted monovalent organic group with a lactone structure, and the groups of the following formulas (3-1) or (3-2) can be given.

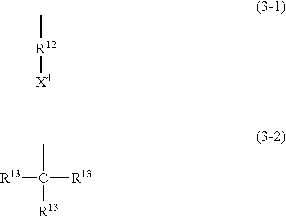

wherein R¹² represents a linear or branched divalent organic group or a divalent organic group having an alicyclic structure, X⁴represents a hydrogen atom or a monovalent functional group, and R¹³ individually represents a linear or branched alkyl group having 1-4 carbon atoms, an oxoalkyl group having 2-4 carbon atoms, or a monovalent alicyclic hydrocarbon group having 4-20 carbon atoms or a derivative thereof, or any two of R¹³ groups form in combination a divalent alicyclic hydrocarbon group having 4-20 carbon atoms or a derivative thereof, with the remaining R¹³ group being a linear or branched alkyl group having 1-4 carbon atoms, an oxoalkyl group having 2-4 carbon atoms, or a monovalent alicyclic hydrocarbon group having 4-20 carbon atoms or a derivative thereof.

Among the monovalent organic group represented by R⁵ in the formula (III), as examples of the linear or branched alkyl group having 1-6 carbon atoms, monovalent organic group with a cyclic structure having 4-20 carbon atoms, monovalent organic group with an ether structure, and substituted or unsubstituted monovalent organic group with a lactone structure, the groups mentioned as examples for the R⁸ group in the above formulas (1-4) can be given.

The following groups can be given as preferable examples of the linear or branched alkyl group having 1-6 carbon atoms, monovalent organic group with an alicyclic structure having 4-20 carbon atoms, monovalent organic group with a cyclic ether structure, and the substituted or unsubstituted monovalent organic group with a lactone skeleton represented by R⁵ in the formula (III):

linear or branched alkyl groups such as a methyl group, ethyl group, and n-propyl group;

cycloalkyl groups such as a cyclopentyl group and cyclohexyl group;

groups derived from a bridged hydrocarbon such as an adamantan-1-yl group, bicyclo[2.2.1]heptan-2-yl group,

7,7-dimethylbicyclo[2.2.1]heptan-1-yl group,

tetracyclo[6.2.1.1^{3,6}.0^{2,7}]dodecan-4 yl group, and

tricyclo[5.2.1.0^{2,6}]decan-8-yl group;

an organic group having a cyclic ether structure such as a (tetrahydrofuran-2-yl)methyl group; and

organic groups with a lactone skeleton which may be either substituted or unsubstituted such as a

5-oxo-4-oxatricyclo[4.2.1.0^{3,7}]nonan-2-yl group,

9-methoxycarbonyl-5-oxo-4-oxatricyclo[4.2.1.0^{3,7}]nonan-2-yl group, 7-oxo-6-oxabicyclo[3.2.1]octan-4-yl group,

2-methoxycarbonyl-7-oxo-6-oxa-bicyclo[3.2.1]octan-4-yl group, 2-oxotetrahydropyran-4-yl group,

4-methyl-2-oxotetrahydropyran-4-yl group,

4-ethyl-2-oxotetrahydropyran-4-yl group,

4-n-propyl-2-oxotetrahydropyran-4-yl group,

5-oxotetrahydrofuran-3-yl group,

2,2-dimethyl-5-oxotetrahydrofuran-3-yl group,

4,4-dimethyl-5-oxotetrahydrofuran-3-yl group,

2-oxotetrahydrofuran-3-yl group,

4,4-dimethyl-2-oxotetrahydrofuran-3-yl group,

5,5-dimethyl-2-oxotetrahydrofuran-3-yl group,

2-oxotetrahydrofuran-3-yl group,

(5-oxotetrahydrofuran-2-yl)methyl group,

(3,3-dimethyl-5-oxotetrahydrofuran-2-yl)methyl group, and

(4,4-dimethyl-5-oxotetrahydrofuran-2-yl)methyl group.

As examples of the linear or branched divalent organic group and the divalent organic group with an alicyclic structure represented by R¹² in the formula (3-1), the same groups as metioned for R⁶ in the above formula (1-2) can be given.

As R¹² in the formula (3-1), a methylene group, ethylene group, divalent group derived from adamantane, divalent group derived from bicyclo[2.2.1]heptane, and the like are preferable.

As examples of the monovalent functional group represented by X⁴ in the formula (3-1), the same monovalent functional groups as those previously given for X³ in the formula (1-2) can be given.

As X⁴ in the formula (3-1), a hydrogen atom, hydroxyl group, carboxyl group, cyano group, and the like are preferable.

The following groups can be given as preferable examples of the group represented by the formula (3-1) which represents the R⁵ group in the formula (III):

a hydroxymethyl group, 2-hydroxyethyl group, 3-hydroxypropyl group, 3-hydroxyadamantan-1-yl group,

5-hydroxybicyclo[2.2.1]heptan-2-yl group,

6-hydroxybicyclo[2.2.1]heptan-2-yl group,

9-hydroxytetracyclo[6.2.1.1^{3,6}.0^{2,7}]dodecan-4-yl group,

10-hydroxytetracyclo[6.2.1.1^{3,6}.0^{2,7}]dodecan-4-yl group,

carboxymethyl group, 2-carboxyethyl group, 3-carboxypropyl group, 3-carboxyadamantan-1-yl group,

5-carboxybicyclo[2.2.1]heptan-2-yl group,

6-carboxybicyclo[2.2.1]heptan-2-yl group,

9-carboxytetracyclo[6.2.1.1^{3,6}.0^{2,7}]dodecan-4-yl group,

10-carboxytetracyclo[6.2.1.1^{3,6}.0^{2,7}]dodecan-4-yl group,

cyanomethyl group, 2-cyanoethyl group, 3-cyanopropyl group,

3-cyanoadamantan-1-yl group,

5-cyanobicyclo[2.2.1]heptan-2-yl group,

6-cyanobicyclo[2.2.1]heptan-2-yl group,

9-cyanotetracyclo[6.2.1.1^{3,6}.0^{2,7}]dodecan-4-yl group, and

10-cyanotetracyclo[6.2.1.1^{3,6}.0^{2,7}]dodecan-4-yl group.

As examples of the linear or branched alkyl group having 1-4 carbon atoms, oxoalkyl group having 2-4 carbon atoms, and monovalent alicyclic hydrocarbon group having 4-20 carbon atoms or its derivative represented by R¹³ in the formula (3-2), and the divalent alicyclic hydrocarbon group having 4-20 carbon atoms formed by bonding of any two of the groups R¹³ or its derivatives, the same groups as mentioned above as examples of R⁷ in the formula (1-3) can be given.

The following groups can be given as preferable examples of the group represented by the formula (3-2) which represents the R⁵ group in the formula (III):

t-butyl group, 2-methyl-2-butyl group, 2-ethyl-2-butyl group,

3-ethyl-3-butyl group, 1,1-dimethyl-2-oxopropyl group,

1,1-dimethyl-2-oxo-n-butyl group, 1-methylcyclopentyl group,

1-ethylcyclopentyl group, 1-methylcyclohexyl group,

1-ethylcyclohexyl group, 2-methyladamantan-2-yl group,

2-ethyladamantan-2-yl group,

2-methyl-3-hydroxyadamantan-2-yl group,

2-methylbicyclo[2.2.1]heptan-2-yl group,

2-ethylbicyclo[2.2.1]heptan-2-yl group,

4-methyltetracyclo[6.2.1.1^{3,6}.0^{2,7}]dodecan-4-yl group,

4-ethyltetracyclo[6.2.1.1^{3,6}.0^{2,7}]dodecan-4-yl group,

8-methyltricyclo[5.2.1.0^{2,6}]decan-8-yl group,

8-ethyltricyclo[5.2.1.0^{2,6}]decan-8-yl) group,

1-methyl-1-cyclopentylethyl group,

1-methyl-1-(2-hydroxycyclopentyl)ethyl group,

1-methyl-1-(3-hydroxycyclopentyl)ethyl group,

1-methyl-1-cyclohexylethyl group,

1-methyl-1-(3-hydroxycyclohexyl)ethyl group,

1-methyl-1-(4-hydroxycyclohexyl)ethyl group,

1-methyl-1-cycloheptylethyl group,

1-methyl-1-(3-hydroxycycloheptyl)ethyl group,

1-methyl-1-(4-hydroxycycloheptyl)ethyl group,

1-methyl-1-(adamantan-1-yl)ethyl group,

1-methyl-1-(3-hydroxyadamantan-1-yl)ethyl group,

1-methyl-1-(bicyclo[2.2.1]heptan-2-yl)ethyl group,

1-methyl-1-(tetracyclo[6.2.1.1^{3,6}.0^{2,7}]dodecan-4-yl)ethyl group, 1-methyl-1-(tricyclo[5.2.1.0^{2,6}]decan-8-yl)ethyl group,

1,1-dicyclopentylethyl group, 1,1-dicyclohexylethyl group,

1,1-di(adamantan-1-yl)ethyl group,

1,1-di(bicyclo[2.2.1]heptan-2-yl)ethyl group,

1,1-di(tetracyclo[6.2.1.1^{3,6}.0^{2,7}]dodecan-4-yl)ethyl group,

and 1,1-di(tricyclo[5.2.1.0^{2,6}]decan-8-yl)ethyl group.

As the group R⁵ in the formula (III), a hydrogen atom is also preferable.

The following compounds can be given as examples of monomers providing a preferable recurring unit (II):

bicyclo[2.2.1]hept-2-ene derivatives such as

5-methylbicyclo[2.2.1]hept-2-ene,

5-ethylbicyclo[2.2.1]hept-2-ene,

5-n-butylbicyclo[2.2.1]hept-2-ene,

5-n-hexylbicyclo[2.2.1]hept-2-ene,

5-n-octylbicyclo[2.2.1]hept-2-ene,

5-n-decylbicyclo[2.2.1]hept-2-ene,

5-hydroxybicyclo[2.2.1]hept-2-ene,

5-hydroxymethylbicyclo[2.2.1]hept-2-ene,

5-(2-hydroxyethyl)bicyclo[2.2.1]hept-2-ene,

5-(3-hydroxypropyl)bicyclo[2.2.1]hept-2-ene,

5-[(fluoro)(hydroxy)methyl]bicyclo[2.2.1]hept-2-ene,

5-[(difluoro)(hydroxy)methyl]bicyclo[2.2.1]hept-2-ene,

5-(1,2-difluoro-2-hydroxyethyl)bicyclo[2.2.1]hept-2-ene,

5-(1,1,2,2-tetrafluoro-2-hydroxyethyl)bicyclo[2.2.1]hept-2-ene,

5-(2-trifluoromethyl-2-hydroxyethyl)bicyclo[2.2.1]hept-2-ene,

5-[2,2-di(trifluoromethyl)-2-hydroxyethyl]bicyclo[2.2.1]-hept-2-ene,

(3-hydroxyadamantan-1-yl)bicyclo[2.2.1]hept-2-ene-⁵-carboxylate,

(5-hydroxybicyclo[2.2.1]hept-2-yl)bicyclo[2.2.1]hept-2-ene-5-carboxylate,

(6-hydroxybicyclo[2.2.1]hept-2-yl)bicyclo[2.2.1]hept-2-ene-5-carboxylate,

(9-hydroxytetracyclo[6.2.1.1^{3,6}.0^{2,7}]dodecan-4-yl)

bicyclo[2.2.1]hept-2-ene-5-carboxylate,

(10-hydroxytetracyclo[6.2.1.1^{3,6}.0^{2,7}]dodecan-4-yl)

bicyclo[2.2.1]hept-2-ene-5-carboxylate,

bicyclo[2.2.1]hept-2-ene-5-carboxylic acid,

bicyclo[2.2.1]hept-2-ene-5-acetic acid,

bicyclo[2.2.1]hept-2-ene-5-propionic acid,

5-cyanobicyclo[2.2.1]hept-2-ene,

5-cyanomethylbicyclo[2.2.1]hept-2-ene,

5-(2-cyanoethyl)bicyclo[2.2.1]hept-2-ene,

5-(3-cyanopropyl)bicyclo[2.2.1]hept-2-ene,

methyl bicyclo[2.2.1]hept-2-ene-5-carboxylate,

ethyl bicyclo[2.2.1]hept-2-ene-5-carboxylate,

n-propyl bicyclo[2.2.1]hept-2-ene-5-carboxylate,

t-butyl bicyclo[2.2.1]hept-2-ene-5-carboxylate,

2-ethyl-2-butyl bicyclo[2.2.1]hept-2-ene-5-carboxylate,

3-ethyl-3-butyl bicyclo[2.2.1]hept-2-ene-5-carboxylate,

cyclopentyl bicyclo[2.2.1]hept-2-ene-5-carboxylate,

cyclohexyl bicyclo[2.2.1]hept-2-ene-5-carboxylate,

(2-methyladamantan-2-yl)bicyclo[2.2.1]hept-2-ene-5-carboxylate,

(2-methyl-3-hydroxyadamantan-2-yl)bicyclo[2.2.1]hept-2-ene-5-carboxylate,

(2-ethyladamantan-2-yl)bicyclo[2.2.1]hept-2-ene-5-carboxylate,

(2-methylbicyclo[2.2.1]heptan-2-yl)bicyclo[2.2.1]hept-2-ene-5-carboxylate,

(2-ethylbicyclo[2.2.1]heptan-2-yl)bicyclo[2.2.1]hept-2-ene-5-carboxylate,

(4-methyltetracyclo[6.2.1.1^{3,6}.0^{2,7}]dodecan-4-yl) bicyclo[2.2.1]hept-2-ene-5-carboxylate,

(4-ethyltetracyclo[6.2.1.1^{3,6}.0^{2,7}]dodecan-4-yl) bicyclo[2.2.1]hept-2-ene-5-carboxylate,

(8-methyltricyclo[5.2.1.0^{2,6}]dodecan-8-yl)bicyclo[2.2.1]-hept-2-ene-5-carboxylate,

(8-ethyltricyclo[5.2.1.0^{2,6}]dodecan-8-yl)bicyclo[2.2.1]-hept-2-ene-5-carboxylate,

1-methylcyclopentyl bicyclo[2.2.1]hept-2-ene-5-carboxylate,

1-ethylcyclopentyl bicyclo[2.2.1]hept-2-ene-5-carboxylate,

1-methylcyclohexyl bicyclo[2.2.1]hept-2-ene-5-carboxylate,

1-ethylcyclohexyl bicyclo[2.2.1]hept-2-ene-5-carboxylate,

(1-methyl-1-cyclopentylethyl)bicyclo[2.2.1]hept-2-ene-5-carboxylate,

(1-methyl-1-cyclohexylethyl)bicyclo[2.2.1]hept-2-ene-5-carboxylate,

[1-methyl-1-(adamantan-1-yl)ethyl]bicyclo[2.2.1]hept-2-ene-5-carboxylate,

[1-methyl-1-(bicyclo[2.2.1]heptan-2-yl)ethyl]bicyclo[2.2.1]hept-2-ene-5-carboxylate,

[1-methyl-1-(tetracyclo[6.2.1.1^{3,6}.0^{2,7}]dodecan-4-yl)ethyl]bicyclo[2.2.1]hept-2-ene-5-carboxylate,

[1-methyl-1-(tricyclo[5.2.1.0^{2,6}]decan-8-yl)ethyl]bicyclo[2.2.1]hept-2-ene-5-carboxylate,

[1-methyl-1-(2-hydroxycyclopentyl)ethyl]bicyclo[2.2.1]hept-2-ene-5-carboxylate,

[1-methyl-1-(3-hydroxycyclopentyl)ethyl]bicyclo[2.2.1]hept-2-ene-5-carboxylate,

[1-methyl-1-(3-hydroxycyclohexyl)ethyl]bicyclo[2.2.1]hept-2-ene-5-carboxylate,

[1-methyl-1-(4-hydroxycyclohexyl)ethyl]bicyclo[2.2.1]hept-2-ene-5-carboxylate,

[1-methyl-1-(3-hydroxycycloheptyl)ethyl]bicyclo[2.2.1]hept-2-ene-5-carboxylate,

[1-methyl-1-(4-hydroxycycloheptyl)ethyl]bicyclo[2.2.1]hept-2-ene-5-carboxylate,

[1-methyl-1-(3-hydroxyadamantan-1-yl)ethyl]bicyclo[2.2.1]hept-2-ene-5-carboxylate,

(1,1-dicyclopentylethyl)bicyclo[2.2.1]hept-2-ene-5-carboxylate,

(1,1-dicyclohexylethyl)bicyclo[2.2.1]hept-2-ene-5-carboxylate,

[1,1-di(adamantan-1-yl)ethyl]bicyclo[2.2.1]hept-2-ene-5-carboxylate,

[1,1-di(bicyclo[2.2.1]hept-2-yl)ethyl]bicyclo[2.2.1]hept-2-ene-5-carboxylate,

[1,1-di(tetracyclo[6.2.1.1^{3,6}.0^{2,7}]dodecan-4-yl)ethyl]bicyclo[2.2.1]hept-2-ene-5-carboxylate,

[1,1-di(tricyclo[5.2.1.0^{2,6}]decan-8-yl)ethyl]bicyclo[2.2.1]-hept-2-ene-5-carboxylate,

(adamantan-1-yl) bicyclo[2.2.1]hept-2-ene-5-carboxylate,

(bicyclo[2.2.1]heptan-2-yl)bicyclo[2.2.1]hept-2-ene-5-carboxylate,

(7,7-dimethylbicyclo[2.2.1]heptan-1-yl)bicyclo[2.2.1]hept-2-ene-5-carboxylate,

(tetracyclo[6.2.1.1^{3,6}.0^{2,7}]dodecan-4-yl)bicyclo[2.2.1]hept-2-ene-5-carboxylate,

(tricyclo[5.2.1.0^{2,6}]dodecan-8-yl)bicyclo[2.2.1]hept-2-ene-5-carboxylate,

[(tetrahydrofuran-2-yl)methyl]bicyclo[2.2.1]hept-2-ene-5-carboxylate,

(1,1-dimethyl-2-oxopropyl)bicyclo[2.2.1]hept-2-ene-5-carboxylate,

(5-oxo-4-oxatricyclo[4.2.1.0^{3,7}]nonan-2-yl) bicyclo[2.2.1]hept-2-ene-5-carboxylate,

(9-methoxycarbonyl-5-oxo-4-oxatricyclo[4.2.1.0^{3,7}]nonan-2-yl) bicyclo[2.2.1]hept-2-ene-5-carboxylate,

(7-oxo-6-oxabicyclo[3.2.1]octan-4-yl) bicyclo[2.2.1]hept-2-ene-5-carboxylate,

(2-methoxycarbonyl-7-oxo-6-oxabicyclo[3.2.1]octan-4-yl) bicyclo[2.2.1]hept-2-ene-5-carboxylate,

(2-oxotetrahydropyran-4-yl)bicyclo[2.2.1]hept-2-ene-5-carboxylate,

(4-methyl-2-oxotetrahydropyran-4-yl)bicyclo[2.2.1]hept-2-ene-5-carboxylate,

(4-ethyl-2-oxotetrahydropyran-4-yl)bicyclo[2.2.1]hept-2-ene-5-carboxylate,

(4-n-propyl-2-oxotetrahydropyran-4-yl)bicyclo[2.2.1]hept-2-ene-5-carboxylate,

(5-oxotetrahydrofuran-3-yl)bicyclo[2.2.1]hept-2-ene-5-carboxylate,

(2,2-dimethyl-5-oxotetrahydrofuran-3-yl)bicyclo[2.2.1]hept-2-ene-5-carboxylate,

(4,4-dimethyl-5-oxotetrahydrofuran-3-yl)bicyclo[2.2.1]hept-2-ene-5-carboxylate,

(2-oxotetrahydrofuran-3-yl)bicyclo[2.2.1]hept-2-ene-5-carboxylate,

(4,4-dimethyl-2-oxotetrahydrofuran-3-yl)bicyclo[2.2.1]hept-2-ene-5-carboxylate,

(5,5-dimethyl-2-oxotetrahydrofuran-3-yl)bicyclo[2.2.1]hept-2-ene-5-carboxylate,

(2-oxotetrahydrofuran-3-yl)bicyclo[2.2.1]hept-2-ene-5-carboxylate,

[(5-oxotetrahydrofuran-2-yl)methyl]bicyclo[2.2.1]hept-2-ene-5-carboxylate,

[(3,3-dimethyl-5-oxotetrahydrofuran-2-yl)methyl]bicyclo-[2.2.1]hept-2-ene-5-carboxylate,

and [(4,4-dimethyl-5-oxotetrahydrofuran-2-yl)methyl]-bicyclo[2.2.1]hept-2-ene-5-carboxylate;

tetracyclo[6.2.1.1^{3,6}.0^{2,7}]dodec-4-ene derivatives such as 9-methyltetracyclo[6.2.1.1^{3,6}.0^{2,7}]dodec-4-ene,

9-ethyltetracyclo[6.2.1.1^{3,6}.0^{2,7}]dodec-4-ene,

9-n-butyltetracyclo[6.2.1.1^{3,6}.0^{2,7}]dodec-4-ene,

9-n-hexyltetracyclo[6.2.1.1^{3,6}.0^{2,7}]dodec-4-ene,

9-n-octyltetracyclo[6.2.1.1^{3,6}.0^{2,7}]dodec-4-ene,

9-n-decyltetracyclo[6.2.1.1^{3,6}.0^{2,7}]dodec-4-ene,

9-hydroxytetracyclo[6.2.1.1^{3,6}.0^{2,7}]dodec-4-ene,

9-hydroxymethyltetracyclo[6.2.1.1^{3,6}.0^{2,7}]dodec-4-ene,

9-(2-hydroxyethyl)tetracyclo[6.2.1.1^{3,6}.0^{2,7}]dodec-4-ene,

9-(3-hydroxypropyl)tetracyclo[6.2.1.1^{3,6}.0^{2,7}]dodec-4-ene,

9-[(fluoro)(hydroxy)methyl]tetracyclo[6.2.1.1^{3,6}.0^{2,7}]dodec-4-ene,

9-[(difluoro)(hydroxy)methyl]tetracyclo[6.2.1.1^{3,6}.0^{2,7}]-dodec-4-ene,

9-(1,2-difluoro-2-hydroxyethyl)tetracyclo[6.2.1.1^{3,6}.0^{2,7}]dodec-4-ene,

9-(1,1,2,2-tetrafluoro-2-hydroxyethyl)tetracyclo-[6.2.1.1^{3,6}.0^{2,7}]dodec-4-ene,

9-(2-trifluoromethyl-2-hydroxyethyl)tetracyclo-[6.2.1.1^{3,6}.0^{2,7}]dodec-4-ene,

9-[2,2-di(trifluoromethyl)-2-hydroxyethyl]tetracyclo-[6.2.1.1^{3,6}.0^{2,7}]dodec-4-ene,

(3-hydroxyadamantan-1-yl)

tetracyclo[6.2.1.1^{3,6}.0^{2,7}]dodec-4-ene-9-carboxylate, (5-hydroxybicyclo[2.2.1]heptan-2-yl)

tetracyclo[6.2.1.1^{3,6}.0^{2,7}]dodec-4-ene-9-carboxylate,

(6-hydroxybicyclo[2.2.1]heptan-2-yl)

tetracyclo[6.2.1.1^{3,6}.0^{2,7}]dodec-4-ene-9-carboxylate,

(9-hydroxytetracyclo[6.2.1.1^{3,6}.0^{2,7}]dodecan-4-yl)

tetracyclo[6.2.1.1^{3,6}.0^{2,7}]dodec-4-ene-9-carboxylate,

tetracyclo[6.2.1.1^{3,6}.0^{2,7}]dodec-4-ene-9-carboxylic acid,

tetracyclo[6.2.1.1^{3,6}.0^{2,7}]dodec-4-ene-9-acetic acid,

tetracyclo[6.2.1.1^{3,6}.0^{2,7}]dodec-4-ene-9-propionic acid,

9-cyanotetracyclo[6.2.1.1^{3,6}.0^{2,7}]dodec-4-ene,

9-cyanomethyltetracyclo[6.2.1.1^{3,6}.0^{2,7}]dodec-4-ene,

9-(2-cyanoethyl)tetracyclo[6.2.1.1^{3,6}.0^{2,7}]dodec-4-ene,

9-(3-cyanopropyl)tetracyclo[6.2.1.1^{3,6}.0^{2,7}]dodec-4-ene,

methyl tetracyclo[6.2.1.1^{3,6}.0^{2,7}]dodec-4-ene-9-carboxylate,

ethyl tetracyclo[6.2.1.1^{3,6}.0^{2,7}]dodec-4-ene-9-carboxylate,

t-butyl tetracyclo[6.2.1.1^{3,6}.0^{2,7}]dodec-4-ene-9-carboxylate,

2-methyl-2-butyl tetracyclo[6.2.1.1^{3,6}.0^{2,7}]dodec-4-ene-9-carboxylate,

2-ethyl-2-butyl tetracyclo[6.2.1.1^{3,6}.0^{2,7}]dodec-4-ene-9-carboxylate,

3-ethyl-3-butyl tetracyclo[6.2.1.1^{3,6}.0^{2,7}]dodec-4-ene-9-carboxylate,

cyclopentyl tetracyclo[6.2.1.1^{3,6}.0^{2,7}]dodec-4-ene-9-carboxylate,

cyclohexyl tetracyclo[6.2.1.1^{3,6}.0^{2,7}]dodec-4-ene-9-carboxylate,

(2-methyladamantan-1-yl)

tetracyclo[6.2.1.1^{3,6}.0^{2,7}]dodec-4-ene-9-carboxylate,

(2-methyl-3-hydroxyadamantan-2-yl)

tetracyclo[6.2.1.1^{3,6}.0^{2,7}]dodec-4-ene-9-carboxylate,

(2-ethyladamantan-1-yl) tetracyclo[6.2.1.1^{3,6}.0^{2,7}]dodec-4-ene-9-carboxylate,

(8-methyltricyclo[5.2.1.0^{2,6}]decan-8-yl)

tetracyclo[6.2.1.1^{3,6}.0^{2,7}]dodec-4-ene-9-carboxylate,

(8-ethyltricyclo[5.2.1.0^{2,6}]decan-8-yl)

tetracyclo[6.2.1.1^{3,6}.0^{2,7}]dodec-4-ene-9-carboxylate,

1-methylcyclopentyl tetracyclo[6.2.1.1^{3,6}0.^{2,7}]dodec-4-ene-9-carboxylate,

1-ethylcyclopentyl tetracyclo[6.2.1.1^{3,6}.0^{2,7}]dodec-4-ene-9-carboxylate,

1-ethylcyclohexyl tetracyclo[6.2.1.1^{3,6}.0^{2,7}]dodec-4-ene-9-carboxylate,

1-ethylcyclohexyl tetracyclo[6.2.1.1^{3,6}.0^{2,7}]dodec-4-ene-9-carboxylate,

(2-methylbicyclo[2.2.1]heptan-2-yl) tetracyclo[6.2.1.1^{3,6}.0^{2,7}]dodec-4-ene-9-carboxylate,

(2-ethylbicyclo[2.2.1]heptan-2-yl) tetracyclo[6.2.1.1^{3,6}.0^{2,7}]dodec-4-ene-9-carboxylate,

(4-methyltetracyclo[6.2.1.1^{3,6}.0^{2,7}]dodecan-4-yl]tetracyclo[6.2.1.1^{3,6}.0^{2,7}]dodec-4-ene-9-carboxylate,

(4-ethyltetracyclo[6.2.1.1^{3,6}.0^{2,7}]dodecan-4-yl]tetracyclo[6.2.1.1^{3,6}.0^{2,7}]dodec-4-ene-9-carboxylate,

(1-methyl-1-cyclopentylethyl) tetracyclo[6.2.1.1^{3,6}.0^{2,7}]dodec-4-ene-9-carboxylate,

(1-methyl-1-cyclohexylethyl) tetracyclo[6.2.1.1^{3,6}.0^{2,7}]dodec-4-ene-9-carboxylate,

[1-methyl-1-(adamantan-1-yl)ethyl]tetracyclo[6.2.1.1^{3,6}.0^{2,7}]dodec-4-ene-9-carboxylate,

[1-methyl-1-(bicyclo[2.2.1]hept-2-yl)ethyl]tetracyclo[6.2.1.1^{3,6}.0^{2,7}]dodec-4-ene-9-carboxylate,

[1-methyl-1-(tetracyclo[6.2.1.1^{3,6}.0^{2,7}]dodecan-4-yl)ethyl]tetracyclo[6.2.1.1^{3,6}.0^{2,7}]dodec-4-ene-9-carboxylate,

[1-methyl-1-(tricyclo[5.2.1.0^{2,6}]decan-8-yl)ethyl]tetracyclo[6.2.1.1^{3,6}.0^{2,7}]dodec-4-ene-9-carboxylate,

[1-methyl-1-(2-hydroxycyclopentyl)ethyl]tetracyclo[6.2.1.1^{3,6}.0^{2,7}]dodec-4-ene-9-carboxylate,

[1-methyl-1-(3-hydroxycyclopentyl)ethyl]tetracyclo[6.2.1.1^{3,6}.0^{2,7}]dodec-4-ene-9-carboxylate,

[1-methyl-1-(3-hydroxycyclohexyl)ethyl]tetracyclo[6.2.1.1^{3,6}.0^{2,7}]dodec-4-ene-9 carboxylate,

[1-methyl-1-(4-hydroxycyclohexyl)ethyl]tetracyclo[6.2.1.1^{3,6}.0^{2,7}]dodec-4-ene-9-carboxylate,

[1-methyl-1-(3-hydroxycycloheptyl)ethyl]tetracyclo[6.2.1.1^{3,6}.0^{2,7}]dodec-4-ene-9-carboxylate,

[1-methyl-1-(4-hydroxycycloheptyl)ethyl]tetracyclo[6.2.1.1^{3,6}0.^{2,7}]dodec-4-ene-9-carboxylate,

[1-methyl-1-(3-hydroxyadamantan-1-yl)ethyl]tetracyclo[6.2.1.1^{3,6}.0^{2,7}]dodec-4-ene-9-carboxylate,

(1,1-dicyclopentylethyl) tetracyclo[6.2.1.1^{3,6}.0^{2,7}]dodec-4-ene-9-carboxylate,

(1,1-dicyclohexylethyl) tetracyclo[6.2.1.1^{3,6}.0^{2,7}]dodec-4-ene-9-carboxylate,

[1,1-di(adamantan-1-yl)ethyl]tetracyclo[6.2.1.1^{3,6}.0^{2,7}]dodec-4-ene-9-carboxylate,

[1,1-di(bicyclo[2.2.1]heptan-2-yl)ethyl]tetracyclo[6.2.1.1^{3,6}.0^{2,7}]dodec-4-ene-9-carboxylate,

[1,1-di(tetracyclo[6.2.1.1^{3,6}.0^{2,7}]dodecan-4-yl)ethyl]tetracyclo[6.2.1.1^{3,6}.0^{2,7}]dodec-4-ene-9-carboxylate,

[1,1-di(tricyclo[5.2.1.0^{2,6}]decan-8-yl)ethyl]tetracyclo[6.2.1.1^{3,6}.0^{2,7}]dodec-4-ene-9-carboxylate,

(adamantan-1-yl) tetracyclo[6.2.1.1^{3,6}.0^{2,7}]dodec-4-ene-9-carboxylate,

(bicyclo[2.2.1]heptan-2-yl) tetracyclo[6.2.1.1^{3,6}.0^{2,7}]dodec-4-ene-9-carboxylate,

(7,7-dimethylbicyclo[2.2.1]heptan-1-yl) tetracyclo[6.2.1.1^{3,6}.0^{2,7}]dodec-4-ene-9-carboxylate,

(tetracyclo[6.2.1.1^{3,6}.0^{2,7}]dodecan-4-yl]tetracyclo[6.2.1.1^{3,6}.0^{2,7}]dodec-4-ene-9-carboxylate,

(tricyclo[5.2.1.0^{2,6}]decan-8-yl) tetracyclo[6.2.1.1^{3,6}.0^{2,7}]dodec-4-ene-9-carboxylate,

[(tetrahydrofuran-2-yl)methyl]tetracyclo[6.2.1.1^{3,6}.0^{2,7}]dodec-4-ene-9-carboxylate,

(1,1-dimethyl-2-oxopropyl) tetracyclo[6.2.1.1^{3,6}.0^{2,7}]dodec-4-ene-9-carboxylate,

(5-oxo-4-oxatricyclo[4.2.1.0^{3,7}]nonan-2-yl) tetracyclo[6.2.1.1^{3,6}.0^{2,7}]dodec-4-ene-9-carboxylate,

(9-methoxycarbonyl-5-oxo-4-oxatricyclo[4.2.1.0^{3,7}]nonan-2-yl)tetracyclo[6.2.1.1^{3,6}.0^{2,7}]dodec-4-ene-9-carboxylate,

(7-oxo-6-oxabicyclo[3.2.1]octan-4-yl) tetracyclo[6.2.1.1^{3,6}.0^{2,7}]dodec-4-ene-9-carboxylate,

(2-methoxycarbonyl-7-oxo-6-oxabicyclo[3.2.1]octan-4-yl) tetracyclo[6.2.1.1^{3,6}.0^{2,7}]dodec-4-ene-9-carboxylate,

(2-oxotetrahydropyran-4-yl) tetracyclo[6.2.1.1^{3,6}.0^{2,7}]dodec-4-ene-9-carboxylate,

(4-methyl-2-oxotetrahydropyran-4-yl) tetracyclo[6.2.1.1^{3,6}.0^{2,7}]dodec-4-ene-9-carboxylate,

(4-ethyl-2-oxotetrahydropyran-4-yl) tetracyclo[6.2.1.1^{3,6}.0^{2,7}]dodec-4-ene-9-carboxylate,

(4-n-propyl-2-oxotetrahydropyran-4-yl) tetracyclo[6.2.1.1^{3,6}.0^{2,7}]dodec-4-ene-9-carboxylate,

(5-oxotetrahydrofuran-3-yl) tetracyclo[6.2.1.1^{3,6}.0^{2,7}]dodec-4-ene-9-carboxylate,

(2,2-dimethyl-5-oxotetrahydrofuran-3-yl) tetracyclo[6.2.1.1^{3,6}.0^{2,7}]dodec-4-ene-9-carboxylate,

(4,4-dimethyl-5-oxotetrahydrofuran-3-yl) tetracyclo[6.2.1.1^{3,6}.0^{2,7}]dodec-4-ene-9-carboxylate,

(2-oxotetrahydrofuran-3-yl) tetracyclo[6.2.1.1^{3,6}.0^{2,7}]dodec-4-ene-9-carboxylate,

(4,4-dimethyl-2-oxotetrahydrofuran-3-yl) tetracyclo[6.2.1.1^{3,6}.0^{2,7}]dodec-4-ene-9-carboxylate,

(5,5-dimethyl-2-oxotetrahydrofuran-3-yl) tetracyclo[6.2.1.1^{3,6}.0^{2,7}]dodec-4-ene-9-carboxylate,

(2-oxotetrahydrofuran-3-yl) tetracyclo[6.2.1.1^{3,6}.0^{2,7}]dodec-4-ene-9-carboxylate,

[(5-oxotetrahydrofuran-2-yl)methyl]tetracyclo[6.2.1.1^{3,6}.0^{2,7}]dodec-4-ene-9-carboxylate,

[(3,3-dimethyl-5-oxotetrahydrofuran-2-yl)methyl]tetracyclo[6.2.1.1^{3,6}.0^{2,7}]dodec-4-ene-9-carboxylate,

and [(4,4-dimethyl-5-oxotetrahydrofuran 2-yl)methyl]tetracyclo[6.2.1.1^{3,6}.0^{2,7}]dodec-4-ene-9-carboxylate.

The following (meth) acrylic acid and their derivatives can be given as examples of monomers providing a preferable recurring unit (III):

hydroxymethyl (meth)acrylate,

2-hydroxyethyl (meth)acrylate,

3-hydroxypropyl (meth)acrylate,

(fluoro)(hydroxy)methyl (meth)acrylate,

(difluoro)(hydroxy)methyl (meth)acrylate,

1,2-difluoro-2-hydroxyethyl (meth)acrylate,

1,1,2,2-tetrafluoro-2-hydroxyethyl (meth)acrylate,

2-trifluoromethyl-2-hydroxyethyl (meth)acrylate,

2,2-di(trifluoromethyl)-2-hdroxyethyl (meth)acrylate,

3-hydroxyadamantan-1-yl (meth)acrylate,

2-methyl-3-hydroxyadamantan-2-yl (meth)acrylate,

5-hydroxybicyclo[2.2.1]heptan-2-yl (meth)acrylate,

6-hydroxybicyclo[2.2.1]heptan-2-yl (meth)acrylate,

9-hydroxytetracyclo[6.2.1.1^{3,6}.0^{2,7}]dodecan-4-yl (meth)acrylate,

(meth)acrylic acid,

carboxymethyl (meth)acrylate,

2-carboxyethyl (meth)acrylate,

3-carboxypropyl (meth)acrylate,

3-carboxyadamantan-1-yl (meth)acrylate,

5-carboxybicyclo[2.2.1]heptan-2-yl (meth)acrylate,

6-carboxybicyclo[2.2.1]heptan-2-yl (meth)acrylate,

9-carboxytetracyclo[6.2.1.1^{3,6}.0^{2,7}]dodecan-4-yl (meth)acrylate,

10-carboxytetracyclo[6.2.1.1^{3,6}.0^{2,7}]dodecan-4-yl (meth)acrylate,

cyanomethyl (meth)acrylate,

2-cyanoethyl (meth)acrylate,

3-cyanopropyl (meth)acrylate,

3-cyanoadamantan-1-yl (meth)acrylate,

5-cyanobicyclo[2.2.1]heptan-2-yl (meth)acrylate,

6-cyanobicyclo[2.2.1]heptan-2-yl (meth)acrylate,

9-cyanotetracyclo[6.2.1.1^{3,6}.0^{2,7}]dodecan-4-yl (meth)acrylate,

10-cyanotetracyclo[6.2.1.1^{3,6}.0^{2,7}]dodecan-4-yl (meth)acrylate,

1-methylcyclopentyl (meth)acrylate,

1-ethylcyclopentyl (meth)acrylate,

1-methylcyclohexyl (meth)acrylate,

1-ethylcyclopentyl (meth)acrylate,

2-methyladamantan-2-yl (meth)acrylate,

2-ethyladamantan-2-yl (meth)acrylate,

2-methylbicyclo[2.2.1]heptan-2-yl (meth)acrylate,

2-ethylbicyclo[2.2.1]heptan-2-yl (meth)acrylate,

4-methyltracyclo[6.2.1.1^{3,6}.0^{2,7}]dodecan-4-yl (meth)acrylate,

4-ethyltracyclo[6.2.1.1^{3,6}.0^{2,7}]dodecan-4-yl (meth)acrylate,

8-methyltricyclo[5.2.1.0^{2,6}]decan-8-yl (meth)acrylate,

8-ethyltricyclo[5.2.1.0^{2,6}]decan-8-yl (meth)acrylate,

1-methyl-1-cyclopentylethyl (meth)acrylate,

1-(2-hydroxycyclopentyl)ethyl (meth)acrylate,

1-methyl-1-(3-hydroxycyclopentyl)ethyl (meth)acrylate,

1-methyl-1-cyclohexylethyl (meth)acrylate,

1-methyl-1-(3-hydroxycyclohexyl)ethyl (meth)acrylate,

1-methyl-1-(4-hydroxycyclohexyl)ethyl (meth)acrylate,

1-methyl-1-(3-hydroxycycloheptyl)ethyl (meth)acrylate,

1-methyl-1-(4-hydroxycycloheptyl)ethyl (meth)acrylate,

1-methyl-1-(adamantan-1-yl)ethyl (meth)acrylate,

1-methyl-1-(3-hydroxyadamantan-1-yl)ethyl (meth)acrylate,

1-methyl-1-(bicyclo[2.2.1]heptan-2-yl)ethyl (meth)acrylate,

1-methyl-1-(tetracyclo[6.2.1.1^{3,6}.0^{2,7}]dodecan-4-yl)ethyl (meth)acrylate,

1-methyl-1-(tricyclo[5.2.1.0^{2,6}]decan-8-yl)ethyl (meth)acrylate,

1,1-dicyclopentylethyl (meth)acrylate,

1,1-dicyclohexylethyl (meth)acrylate,

1,1-di(adamantan-1-yl)ethyl (meth)acrylate,

1,1-di(bicyclo[2.2.1]heptan-2-yl)ethyl (meth)acrylate,

1,1-di(tetracyclo[6.2.1.1^{3,6}.0^{2,7}]dodecan-4-yl)ethyl (meth)acrylate,

1,1-di(tricyclo[5.2.1.0^{2,6}]decan-8-yl)ethyl (meth)acrylate,

methyl (meth)acrylate,

ethyl (meth)acrylate,

n-propyl (meth)acrylate,

t-butyl (meth)acrylate,

2-methyl-2-butyl (meth)acrylate,

2-ethyl-2-butyl (meth)acrylate,

3-ethyl-3-butyl (meth)acrylate,

cyclopentyl (meth)acrylate,

cyclohexyl (meth)acrylate,

adamantan-1-yl (meth)acrylate,

bicyclo[2.2.1]heptan-2-yl (meth)acrylate,

7,7-dimethylbicyclo[2.2.1]heptan-1-yl (meth)acrylate,

tetracyclo[6.2.1.1^{3,6}.0^{2,7}]dodecan-4-yl (meth)acrylate,

tricyclo[5.2.1.0^{2,6}]decan-8-yl (meth)acrylate,

(tetrahydrofuran-2-yl)methyl (meth)acrylate,

1,1-dimethyl-2-oxopropyl (meth)acrylate 5-oxo-4-oxatricyclo[4.2.1.0^{3,7}]nonan-2-yl (meth)acrylate,

9-methoxycarbonyl-5-oxo-4-oxatricyclo[4.2.1.0^{3,7}]nonan-2-yl (meth)acrylate,

7-oxo-6-oxabicyclo[3.2.1]octan-4-yl (meth)acrylate,

2-methoxycarbonyl-7-oxo-6-oxabicyclo[3.2.1]octan-4-yl (meth)acrylate,

2-oxotetrahydropyran-4-yl (meth)acrylate,

4-methyl-2-oxotetrahydropyran-4-yl (meth)acrylate,

4-ethyl-2-oxotetrahydropyran-4-yl (meth)acrylate,

4-propyl-2-oxotetrahydropyran-4-yl (meth)acrylate,

5-oxotetetrahydrofuran-3-yl (meth)acrylate,

2,2-dimethyl-5-oxotetetrahydrofuran-3-yl (meth)acrylate,

4,4-dimethyl-5-oxotetetrahydrofuran-3-yl (meth)acrylate,

2-oxotetetrahydrofuran-3-yl (meth)acrylate,

4,4-dimethyl-2-oxotetetrahydrofuran-3-yl (meth)acrylate,

5,5-dimethyl-2-oxotetetrahydrofuran-3-yl (meth)acrylate,

2-oxotetetrahydrofuran-3-yl (meth)acrylate,

(5-oxotetrahydrofuran-2-yl)methyl (meth)acrylate,

(3,3-dimethyl-5-oxotetetrahydrofuran-2-yl)methyl (meth)acrylate, and

(4,4-dimethyl-5-oxotetetrahydrofuran-2-yl)methyl (meth)acrylate.

The resin (A) may comprise recurring units other than the recurring units (II) and (III).

Examples of monomers which provide the recurring units other than the recurring units (II) and (III) include monofunctional monomers such as vinyl esters such as vinyl acetate, vinyl propionate, and vinyl butyrate; unsaturated nitryl compounds such as (meth)acrylonitrile, α-chloroacrylonitrile, crotonitrile, maleinitrile, fumaronitrile, mesaconitrile, citraconitrile, and itaconitrile; unsaturated amide compounds or unsaturated imide compounds such as (meth)acrylamide, N,N-dimethyl(meth)acrylamide, crotonamide, maleinamide, maleimide, N-phenylmaleimide, N-cyclohexylmaleimide, fumaramide, mesaconamide, citraconamide, and itaconamide; other nitrogen-containing vinyl compounds such as N-vinyl-ε-caprolactam, N-vinylpyrrolidone, vinylpyridine, and vinylimidazole; unsaturated carboxylic acids (anhydrides) such as crotonic acid, maleic acid, maleic anhydride, fumaric acid, itaconic acid, itaconic anhydride, citraconic acid, citraconic anhydride, and mesaconic acid; and polyfunctional monomers such as methylene glycol di(meth)acrylate, ethylene glycol di(meth)acrylate, propylene glycol di(meth)acrylate, 1,6-hexanediol di(meth)acrylate, 2,5-dimethyl-2,5-hexanediol di(meth)acrylate, 1,8-octanediol di(meth)acrylate, 1,9-nonanediol di(meth)acrylate, 1,4-bis(2-hydroxypropyl)benzene di(meth)acrylate, 1,3-bis(2-hydroxypropyl)benzene di(meth)acrylate, 1,2-adamantanediol di(meth)acrylate, 1,3-adamantanediol di(meth)acrylate, 1,4-adamantanediol di(meth)acrylate, and tricyclodecanyldimethylol di(meth)acrylate.

Of these monomers, (meth)acrylamide, N,N-dimethyl (meth)acrylamide, crotonic acid, maleic anhydride, and the like are preferable.

As specific examples of the preferable combinations of the recurring units in the resin (A) of the present invention, the combinations shown in the following (A1) to (A3) can be given.

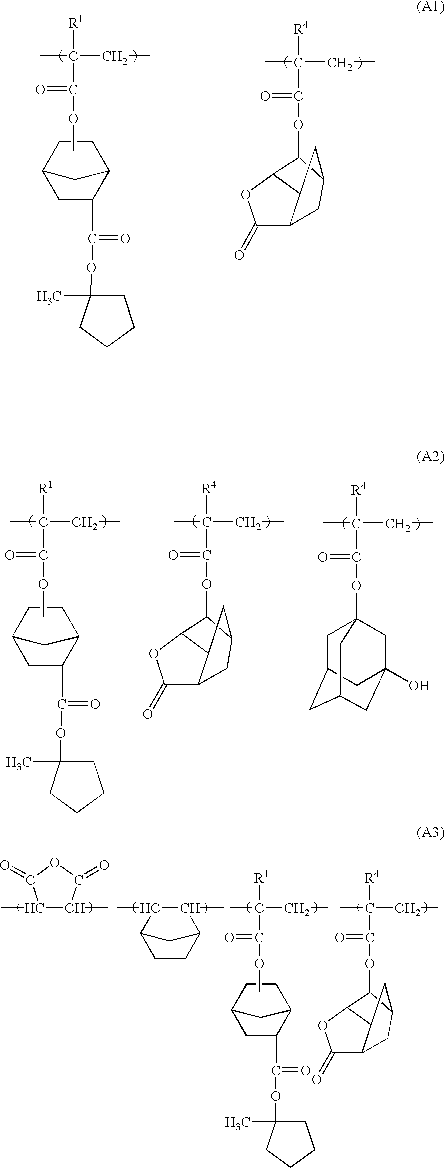

wherein R¹ is the same as defined in the formula (I) and R⁴ is the same as defined in the formula (III).

The amount of the recurring unit (I) in the resin (A) is usually 20 mol % or more, preferably 10 to 70 mol %, still more preferably 10 to 60 mol %, and particularly preferably 20 to 50 mol % of the total amount of the recurring units. If the content of the recurring unit (I) is less than 20 mol %, resolution as a resist tends to decrease.

The amount of the recurring units (II) and (III) is preferably 80 mol % or less of the total amount of the recurring units. In this instance, if the total amount exceeds 80 wt %, resolution as a resist tends to be impaired.

Furthermore, the amount of the recurring units other than the recurring units (II) and (III) is usually 50 mol % or less, and preferably 40 mol % or less of the total amount of the recurring units.

The resin (A) is prepared by polymerizing a mixture of monomers corresponding to each of the above recurring units in an appropriate solvent in the presence of a chain transfer agent, as required, using a radical polymerization initiator such as hydroperoxides, dialkyl peroxides, diacyl peroxides, or azo compounds.

As examples of the solvent which can be used for the polymerization, alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethylbenzene, and cumene; halogenated hydrocarbons such as chlorobutanes, bromohexanes, dichloroethanes, fluorochloroethanes, hexamethylene dibromide, and chlorobenzene; saturated carboxylic acid esters such as ethyl acetate, n-butyl acetate, i-butyl acetate, methyl propionate, and propylene glycol monomethyl ether acetate; alkyllactones such as γ-butyrolactone; ethers such as tetrahydrofuran, dimethoxyethanes, and diethoxyethanes; alkylketones such as 2-butanone, 2-heptanone, and methyl isobutyl ketone; cycloalkylketones such as cyclohexanone; alcohols such as 2-propanol and propylene glycol monomethyl ether; and the like can be given.

The solvent may be used either individually or in combination of two or more.

The polymerization temperature is usually 40-120° C., and preferably 50-100° C. The reaction time is usually 1-48 hours, and preferably 1-24 hours.

It is preferable that the resin (A) of the present invention should contain almost no impurities such as halogens or metals. The content of residual monomers and oligomers should be less than the prescribed amount, for example, the content determined by HPLC should be 0.1 wt % or less. The smaller the amount of such impurities and residual monomers and oligomers, the better are the sensitivity, resolution, process stability, pattern shape, or the like as a resist. In addition, such a small content of impurities and the like decreases changes in the fluctuations in the amount of foreign matters and sensitivity of the composition solution used for forming resist patterns. Thus, a radiation-sensitive resin composition exhibiting stable resist performance can be provided.

The following methods can be given as methods for purifying the resin (A). As a method for removing impurities such as metals, a method of putting metals in the resin solution to be adsorbed using a zeta-potential filter, a method of removing metals as a chelate by washing the resin solution with an acidic aqueous solution such as an aqueous solution of oxalic acid or sulfonic acid, and the like can be given. As the method of reducing the residual monomers and oligomer components to a prescribed level, a method of washing with water, a liquid-liquid extraction method in which the residual monomers and oligomer components are removed by selecting a suitable solvent or appropriately combining suitable solvents, a liquid-phase purification method such as ultrafiltration in which only the low-molecular weight components having a molecular weight less than a specific value are extracted and removed using a suitably selected solvent or combination of two or more solvents, a reprecipitation method in which the residual monomers and the like are removed by adding the resin solution to a poor solvent dropwise, thereby causing the resin to coagulate in the poor solvent, and a solid-phase purification method in which the resin slurry separated by filtration is washed with a poor solvent can be given. A combination of these methods can also be used. The solvents used in the above liquid-phase purification method and the poor solvents used in the solid-phase purification method can be appropriately selected according to the purified resin.

The polystyrene-reduced weight average molecular weight (hereinafter referred to as “Mw”) of the resin (A) determined by gel permeation chromatography (GPC) is usually 1,000-300,000, preferably 2,000-200,000, and still more preferably 3,000-100,000. If Mw of the resin (A) is less than 1,000, heat resistance as a resist tends to decrease. If Mw exceeds 300,000, developability as a resist tends to decrease.

The ratio of Mw to the polystyrene-reduced number average molecular weight (hereinafter referred to as “Mn”) determined by gel permeation chromatography (GPC) (Mw/Mn) of the resin (A) is usually 1-5, and preferably 1-3.

In the present invention, the resin (A) may be used either individually or in combination of two or more.

Component (B)

The component (B) of the present invention is a radiation-sensitive photoacid generator which generates an acid upon exposure to radiation such as visible rays, ultraviolet rays, deep ultraviolet rays, electron beams, and X-rays.

The acid generator (B) causes the acid-dissociable group in the resin (A) to dissociate by the action of an acid generated upon exposure. As a result, exposed areas of the resist film become readily soluble in an alkaline developer, whereby a positive-tone resist pattern is formed.

Compounds shown by the following formulas (BA−1) to (BA−5) are preferable as the acid produced by the acid generator (B).

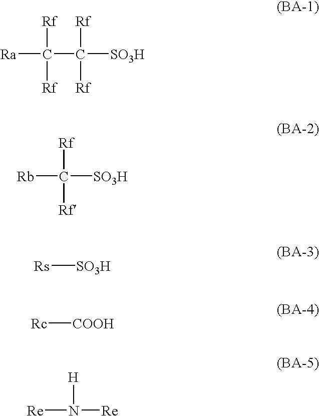

In the formula (BA−1), Rf individually represents a fluorine atom or a trifluoromethyl group and Ra represents a hydrogen atom, a fluorine atom, a linear or branched alkyl group having 1-20 carbon atoms, or a linear or branched fluoroalkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms. In the formula (BA−2), Rf represents a fluorine atom or a trifluoromethyl group, Rf′ represents a hydrogen atom, fluorine atom, methyl group, or trifluoromethyl group, and Rb represents a hydrogen atom, a linear or branched alkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms. In the formula (BA−3), Rs represents a linear or branched alkyl group having 1-20 carbon atoms or a substituted or unsubstituted monovalent cyclic hydrocarbon group having 3-20 carbon atoms. In the formula (BA−4), Rc represents a linear or branched alkyl group having 1-20 carbon atoms, a linear or branched fluoroalkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms. In the formula (BA−5), Re represents a Ra—SO₂— group or Ra—CO— group, wherein Ra is the same as defined for the above formula (B-1). When the acid produced by the acid generator (B) contains a mixture of the acid of the formula (BA−1) and the acid of the formula (BA−5), the Ra groups in the formulas (BA−1) and (BA−5) may be either the same or different.

As examples of the linear or branched alkyl group having 1-20 carbon atoms represented by Ra, Rb, Rs, Rc, or Re in the formulas (BA−1) to (BA−5), a methyl group, ethyl group, n-propyl group, i-propyl group, n-butyl group, 2-methylpropyl group, 1-methylpropyl group, t-butyl group, n-pentyl group and n-hexyl group, n-heptyl group, and n-octyl group can be given.

As examples of the linear or branched fluoroalkyl group having 1-20 carbon atoms represented by Ra, Rc, or Re, a trifluoromethyl group, pentafluoroethyl group, heptafluoro-n-propyl group, heptafluoro-i-propyl group, nonafluoro-n-butyl group, nonafluoro-2-methylpropyl group, nonafluoro-1-methylpropyl group, nonafluoro-t-butyl group, perfluoro-n-pentyl group, perfluoro n-hexyl group, perfluoro-n-heptyl group, and perfluoro-n-octyl group can be given.

As examples of the monovalent cyclic hydrocarbon group having 3-20 carbon atoms represented by Ra, Rb, Rs, Rc, or Re, a phenyl group, 2-naphtyl group, cycloalkyl group, adamantane-1-yl group, bicyclo[2.2.1]heptan-2-yl group, tetracyclo[6.2.1.1^{3,6}.0^{2,7}]dodecan-4-yl group, and 10-camphanyl group can be given.

As examples of the monovalent cyclic fluorohydrocarbon group having 3-20 carbon atoms represented by Ra, Rb, Rc, or Re, groups derived from a phenyl group, 2-naphtyl group, cycloalkyl group, adamantan-1-yl group, bicyclo[2.2.1]heptan-2-yl group, tetracyclo[6.2.1.1^{3,6}.0^{2,7}]dodecan-4-yl group, 10-camphanyl group, or the like by substituting one or more hydrogen atoms with a fluorine atom can be given.

As examples of the acid of the formula (BA−1), the following compounds can be given:

linear or branched fluoroalkyl sulfonic acids such as trifluoromethanesulfonic acid, pentafluoroethanesulfonic

acid, 1,1,2,2-tetrafluoro-n-propanesulfonic acid,

heptafluoro-n-propanesulfonic acid, 1,1,2,2-tetrafluoro-n-butanesulfonic acid, nonafluoro-n-butanesulfonic acid,

1,1,2,2-tetrafluoro-n-octanesulfonic acid,

perfluoro-n-octanesulfonic acid; and acids derived from

1,1,2,2-tetrafluoroethanesulfonic acid,

1-trifluoromethyl-1,2,2-trifluoroethanesulfonic acid,

2-trifluoromethyl-1,1,2-trifluoroethanesulfonic acid,

1,2-di(trifluoromethyl)-1,2-difluoroethanesulfonic acid,

1,1-di(trifluoromethyl)-2,2-difluoroethanesulfonic acid, or

2,2-di(trifluoromethyl)-1,1-difluoroethanesulfonic acid by substituting the hydrogen atom on the 2 position of these acids with a cyclobutyl group, cyclopentyl group, cyclohexyl group,

phenyl group, 4-trifluoromethylphenyl group,

2,3-difluorophenyl group, 2,4-difluorophenyl group,

2,5-difluorophenyl group, 2,6-difluorophenyl group,

3,4-difluorophenyl group, 3,5-difluorophenyl group,

3,6-difluorophenyl group, 2,3,4,5,6-penta-fluorophenyl group,

naphthalen-1-yl group, naphthalen-2-yl group, adamantan-1-yl group, adamantan-2-yl group, 3-hydroxyadamantan-1-yl group,

3-hydroxyadamantan-2-yl group, bicyclo[2.2.1]heptan-2-yl group, 5-hydroxy bicyclo[2.2.1]heptan-2-yl group,

6-hydroxybicyclo[2.2.1]heptan-2-yl group,

7,7-dimethylbicyclo[2.2.1]heptan-2-yl group,

tetracyclo[6.2.1.1^{3,6}.0^{2,7}]dodecan-4-yl group,

9-hydroxytetracyclo[6.2.1.1^{3,6}.0^{2,7}]dodecan-4-yl group, or

10-hydroxytetracyclo[6.2.1.1^{3,6}.0^{2,7}]dodecan-4-yl group.

As examples of the acid of the formula (BA−2), the following compounds can be given: 1-fluoroethanesulfonic acid, 1-fluoro-n-propanesulfonic acid, 1-fluoro-n-butanesulfonic acid, 1-fluoro-n-octanesulfonic acid, 1,1-difluoroethanesulfonic acid, 1,1-difluoro-n-propanesulfonic acid, 1,1-difluoro-n-butanesulfonic acid, 1,1-difluoro-n-octanesulfonic acid, 1-trifluoromethyl-n-propanesulfonic acid, 1-trifluoromethyl-n-butanesulfonic acid, 1-trifluoromethyl-n-octanesulfonic acid, 1,1-di(trifluoromethyl)ethanesulfonic acid, 1,1-di(trifluoromethyl)-n-propanesulfonic acid, 1,1-bis(trifluoromethyl)-n-butanesulfonic acid, and 1,1-di(trifluoromethyl)-n-octanesulfonic acid; and acids derived from monofluoromethanesulfonic acid, difluoromethanesulfonic acid, 1-fluoroethanesulfonic acid, 1,1-difluoroethanesulfonic acid, (trifluoromethyl)methanesulfonic acid, 1-(trifluoromethyl)ethanesulfonic acid, di(trifluoromethyl)methanesulfonic acid, or 1,1-di(trifluoromethyl)ethanesulfonic acid by substituting the hydrogen atom on the 1 position or 2 position of these acids with a cyclobutyl group, cyclopentyl group, cyclohexyl group, phenyl group, 4-trifluoromethylphenyl group, 2,3-difluorophenyl group, 2,4-difluorophenyl group, 2,5-difluorophenyl group, 2,6-difluorophenyl group, 3,4-difluorophenyl group, 3,5-difluorophenyl group, 3,6-difluorophenyl group, 2,3,4,5,6-pentafluorophenyl group, naphthalen-1-yl group, naphthalen-2-yl group, adamantan-1-yl group, adamantan-2-yl group, 3-hydroxyadamantan-1-yl group, 3-hydroxyadamantan-2-yl group, bicyclo[2.2.1]heptan-2-yl group, 5-hydroxy bicyclo[2.2.1]heptan-2-yl group, 6-hydroxybicyclo[2.2.1]heptan-2-yl group, 7,7-dimethylbicyclo[2.2.1]heptan-2-yl group, tetracyclo[6.2.1.1^{3,6}.0^{2,7}]dodecan-4-yl group, 9-hydroxytetracyclo[6.2.1.1^{3,6}.0^{2,7}]dodecan-4-yl group, or 10-hydroxytetracyclo[6.2.1.1^{3,6}.0^{2,7}]dodecan-4-yl group.

As examples of the acid of the formula (BA−3), the following compounds can be given: linear or branched cycloalkyl sulfonic acids such as methanesulfonic acid, ethanesulfonic acid, n-propanesulfonic acid, n-butanesulfonic acid, 2-methylpropanesulfonic acid, 1-methylpropanesulfonic acid, t-butanesulfonic acid, n-pentanesulfonic acid, n-hexanesulfonic acid, n-octanesulfonic acid, cyclopentanesulfonic acid, and cyclohexanesulfonic acid; aromatic sulfonic acids such as benzenesulfonic acid, p-toluenesulfonic acid, benzylsulfonic acid, α-naphthalenesulfonic acid, and β-naphthalenesulfonic acid; and 10-camphorsulfonic acid.

As examples of the acid of the formula (BA−4), the following compounds can be given: monocarboxylic acids such as acetic acid, propyonic acid, butyric acid, isobutyric acid, valeric acid, isovaleric acid, caproic acid, benzoic acid, salicylic acid, phthalic acid, terephthalic acid, α-naphthalenecarboxylic acid, β-naphthalenecarboxylic acid, cyclobutanecarboxylic acid, cyclopentanecarboxylic acid, cyclohexanecarboxylic acid, adamantane-1-carboxylic acid, bicycle [2.2.1]heptan-2-carboxylic acid, adamantane-1-acetic acid, bicyclo[2.2.1]heptane-2-acetic acid, lithocholic acid, deoxycholic acid, chenodeoxycholic acid, and cholic acid; and dicarboxylic acids such as cyclobutane-1,1-dicarboxylic acid, cyclobutane-1,2-dicarboxylic acid, cyclopentane-1,1-dicarboxylic acid, cyclopentane-1,2-dicarboxylic acid, cyclopentane-1,3-dicarboxylic acid, cyclohexane-1,1-dicarboxylic acid, cyclohexane-1,2-dicarboxylic acid, cyclohexane-1,3-dicarboxylic acid, cyclohexane-1,4-dicarboxylic acid, adamantane-1,3-dicarboxylic acid, bicyclo[2.2.1]heptane-2,3-dicarboxylic acid, adamantane-1,3-diacetic acid, and bicyclo[2.2.1]heptane-2,3-diacetic acid.

As examples of the acid of the formula (BA−5), the following compounds can he given:

N,N-bis(trifluoromethanesulfonyl)imidic acid,

N,N-bis(pentafluoroethanesulfonyl)imidic acid,

N,N-bis(1,1,2,2-tetrafluoro-n-propanesulfonyl)imidic acid,

N,N-bis (heptafluoro-n-propanesulfonyl)imidic acid,

N,N-bis(1,1,2,2-tetrafluoro-n-butanesulfonyl)imidic acid,

N,N-bis(nonafluoro-n-butanesulfonyl)imidic acid,

N,N-bis(1,1,2,2-tetrafluoro-n-octanesulfonyl)imidic acid,

N,N-bis(perfluoro-n-octanesulfonyl)imidic acid,

N-trifluoromethanesulfonyl.N-pentafluoroethane-sulfonylimidic acid,

N-trifluoromethanesulfonyl.N-heptafluoro-n-propane-sulfonylimidic acid,

N-trifluoromethanesulfonyl.N-nonafluoro-n-butane-sulfonylimidic acid,

N-pentafluoroethanesulfonyl.N-heptafluoro-n-propane-sulfonylimidic acid,

N-pentafluoroethanesulfonyl.N-nonafluoro-n-butane-sulfonylimidic acid, and

N-heptafluoro-n-propanesulfonyl.N-nonafluoro-n-butane-sulfonylimidic acid.

As the compound generating the acids of the above formulas (BA−1) to (BA−5), onium salts, sulfoneimide compounds, sulfone compounds, sulfonate compounds, disulfonyldiazomethane compounds, disulfonylmethane compounds, oxime sulfonate compounds, hydrazine sulfonate compounds, and the like can be given.

As examples of onium salt compounds, iodonium salts, sulfonium salts (including tetrahydrothiophenium salts), phosphonium salts, diazonium salts, and pyridinium salts can be given.

Preferable examples of onium salt compounds include:

iodonium salts such as diphenyliodonium salt,

di(4-t-butylphenyl)iodonium slat, di(p-tolyl)iodonium salt,

di(3,4-dimethylphenyl)iodonium salt,

4-nitrophenyl.phenyliodonium salt,

di(3-nitrophenyl)iodonium salt,

4-methoxyphenyl.phenyliodonium salt,

di(4-chlorophenyl)iodonium salt,

di(4-trifluoromethylphenyl)iodonium salt,

biphenyleneiodonium salt, di(naphthalen-2-yl)iodonium slat,

and 2-chlorobiphenyleneiodonium salt;

aryl sulfonium salts such as triphenylsulfonium salt,

4-t-butylphenyl.diphenylsulfonium salt,

4-t-butoxyphenyl.diphenylsulfonium salt,

4-hydroxyphenyl.diphenylsulfonium salt,

tri(4-methoxyphenyl)sulfonium salt,

di(4-methoxyphenyl).p-tolylsulfonium salt,

phenyl.biphenylenesulfonium salt,

4-phenylthiophenyl.diphenylsulfonium salt,

and 4,4′-bis(diphenylsulfoniophenyl)sulfide salt;

tri(cyclo)alkylsulfonium salts such as

dicyclohexyl.methylsulfonium salt

dimethyl.cyclohexylsulfonium salt

and tricyclohexylsulfonium salt;

2-oxosulfonium salts such as

cyclohexyl.2-oxocyclohexyl-methylsulfonium salt,

dicyclohexyl.2-oxocyclohexylsulfonium salt,

2-oxocyclohexyldimethylsulfonium salt,

bicyclo[2.2.1]heptan-2-yl.methyl.2-oxocyclohexylsulfonium salt, bicyclo[2.2.1]heptan-2-yl.cyclohexyl.2-oxocyclohexyl-sulfonium salt,

1-[2-(naphthalen-1-yl)-2-oxoethyl]tetrahydrothiophenium salt,

1-[2-(naphthalen-1-yl)-2-oxoethyl]tetrahydrothiophenium salt,

and 1-(2-oxo-n-butyl)tetrahydrothiophenium salt;

naphthalen-1-yl.dialkylsulfonium salts such as

naphthalen-1-yl.dimethylsulfonium salt,

naphthalen-1-yl.diethylsulfonium salt,

4-cyanonaphthalen-1-yl.dimethylsulfbnium salt,

4-cyanonaphthalen-1-yl.diethylsulfonium salt,

4-nitronaphthalen-1-yl.dimethylsulfonium salt,

4-nitronaphthalen-1-yl.diethylsulfonium salt,

4-methylnaphthalen-1-yl.dimethylsulfonium salt,

4-methylnaphthalen-1-yl.diethylsulfonium salt,

4-hydroxynaphthalen-1-yl.dimethylsulfonium salt,

and 4-hydroxynaphthalen-1-yl.diethylsulfonium salt; and

aryl thiophenium salts such as

1-(4-hydroxynaphthalen-1-yl)tetrahydrothiophenium salt,

1-(4-methoxynaphthalen-1-yl)tetrahydrothiophenium salt,

1-(4-ethoxynaphthalen-1-yl)tetrahydrothiophenium salt,

1-(4-n-butoxynaphthalen-1-yl)tetrahydrothiophenium salt,

1-(4-methoxymethoxynaphthalen-1-yl)tetrahydrothiophenium salt,

1-(4-ethoxymethoxynaphthalen-1-yl)tetrahydrothiophenium salt,

1-[4-(1-methoxyethoxy)naphthalen-1-yl]tetrahydrothiophenium salt,

1-[4-(2-methoxyethoxy)naphthalen-1-yl]tetrahydrothiophenium salt,

1-(4-methoxycarbonyloxynaphthalene-1-yl)tetrahydro-thiophenium salt,

1-(4-ethoxycarbonyloxynaphthalene-1-yl)tetrahydro-thiophenium salt,

1-(4-n-propoxycarbonyloxynaphthalene-1-yl)tetrahydro-thiophenium salt,

1-(4-i-propoxycarbonyloxynaphthalene-1-yl)tetrahydro-thiophenium salt,

1-(4-n-butoxycarbonyloxynaphthalene-1-yl)tetrahydro-thiophenium salt,

1-(4-t-butoxycarbonyloxynaphthalene-1-yl)tetrahydro-thiophenium salt,

1-[4-(2-tetrahydrofuranyloxy)naphthalen-1-yl]tetrahydro-thiophenium salt,

1-[4-(2-tetrahydropyranyloxy)naphthalen-1-yl]tetrahydro-thiophenium salt,

1-(4-benzyloxynaphthalen-1-yl)tetrahydrothiophenium salt,

4-(4-n-butoxynaphthalen-1-yl)-4-thioniatricyclo[5.2.1.0^{2,6}]-decane salt,

(4-ethoxynaphthalen-1-yl)4-thioniatricyclo[5.2.1.0^{2,6}]decane salt,

1-[4-(bicyclo[2.2.1]heptan-2-yl)oxynaphthalen-1-yl]-tetrahydrothiophenium salt,

1-(3,5-dimethyl-4-hydroxyphenyl)tetrahydrothiophenium salt,

1-(3,5-dimethyl-4-ethoxyphenyl)tetrahydrothiophenium salt,

and 1-(3,5-dimethyl-4-n-butoxyphenyl)tetrahydrothiophenium salt.

As examples of the sulfonimide compound, compounds of the following formula (B1) can be given:

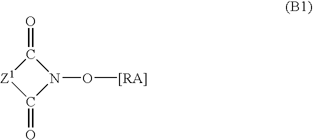

wherein [RA] is a residue of an acid represented by any of the above formulas (BA−1) to (BA−4), generating the acid represented by any of the above formulas (BA−1) to (BA−4) when dissociated, and Z¹ represents a divalent organic group.

The compound of the formula (B1) has a structure consisting of a compound in which the [RA] group in the formula (B1) has been replaced by a hydrogen atom (hereinafter referred to as a “mother nucleus compound (B1)”) and a residue of an acid represented by any of the above formulas (BA−1) to (BA−4), bonded via a sulfonyl group or carbonyl group.

As examples of the mother nucleus compound (B1), N-hydroxysuccinimide, N-hydroxydiphenylmaleimide, N-hydroxybicyclo[2.2.1]hept-5-ene-2,3-dicarboxyimide, N-hydroxy-7-oxabicyclo[2.2.1]hept-5-ene-2,3-dicarboxyimide, N-hydroxybicyclo[2.2.1]heptane-5,6-oxy-2,3-dicarboxyimide, N-hydroxynaphthylimide, and N-hydroxyphthalimide can be given.

As examples of the sulfone compound, β-ketosulfone, β-sulfonylsulfone, and α-diazo compounds of these compounds can be given.

As examples of the sulfonate compound, alkyl sulfonate, haloalkyl sulfonate, aryl sulfonate, and imino sulfonate can be given.

As examples of the disulfonyldiazomethane compound, compounds shown by the following formula (B2) can be given:

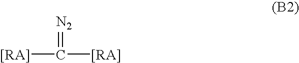

wherein [RA] individually represents the [RA] group defined in the formula (B1).

As examples of the disulfonylmethane compound, compounds shown by the following formula (B3) can be given:

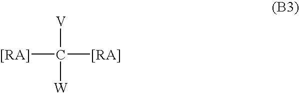

wherein [RA] individually represents the [RA] defined in the formula (B1), at least one of V and W represents an aryl group, or V and W bond to form monocyclic or polycyclic structure having at least one unsaturated bond, or V and W bond to form a group of the following formula:

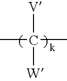

wherein V′ and W′ individually represent a hydrogen atom, halogen atom, an alkyl group, cycloalkyl group, aryl group, or aralkyl group, or V′ and W′ each bonded to the same or different carbon atoms bond to form a monocyclic carbon structure, and k is an integer from 2 to 10.

As examples of the oxime sulfonate compound, compounds of the following formula (B4-1) or (B4-2) can be given:

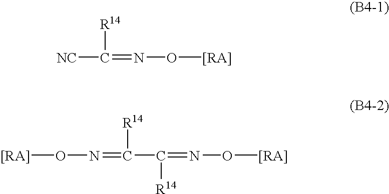

wherein [RA] individually represents the [RA] group defined in the formula (B1) and R¹⁴ individually represents a monovalent organic group.

As specific examples of R¹⁴ in the formulas (B4-1) and (B4-2), a methyl group, ethyl group, n-propyl group, phenyl group, and tosyl group can be given.

As examples of the hydrazine sulfonate compound, bis(benzene)sulfonylhydrazine, bis(p-toluene)sulfonylhydrazine, bis(trifluoromethane)sulfonylhydrazine, bis(nonafluoro-n-butane)sulfonylhydrazine, bis(n-propane)sulfonylhydrazine, benzenesulfonylhydrazine, p-toluenesulfonylhydrazine, trifluoromethanesulfonylhydrazine, nonafluoro-n-butanesulfonylhydrazine, n-propanesulfonylhydrazine, and trifluoromethanesulfonyl.p-toluenesulfonylhydrazine can be given.

The following compounds can be given as specific preferable examples of the acid generator (B):

diphenyliodonium trifluoromethanesulfonate,

diphenyliodonium nonafluoro-n-butanesulfonate,

diphenyliodonium perfluoro-n-octanesulfonate,

diphenyliodonium 2-(bicyclo[2.2.1]heptan-2-yl)-1,1,2,2-tetrafluoroethanesulfonate,

diphenyliodonium 2-(5-hydroxybicyclo[2.2.1]heptan-2-yl)-1,1,2,2-tetrafluoroethanesulfonate,

diphenyliodonium 2-(6-hydroxybicyclo[2.2.1]heptan-2-yl)-1,1,2,2-tetrafluoroethanesulfonate,

diphenyliodonium 2-(tetracyclo[6.2.1.1^{3,6}.0^{2,7}]dodecan-4-yl)-1,1,2,2-tetrafluoroethanesulfonate,

diphenyliodonium 2-(9-hydroxytetracyclo[6.2.1.1^{3,6}.0^{2,7}]-dodecan-4-yl)-1,1,2,2-tetrafluoroethanesulfonate,

diphenyliodonium 2-(10-hydroxytetracyclo[6.2.1.1^{3,6}.0^{2,7}]-dodecan-4-yl)-1,1,2,2-tetrafluoroethanesulfonate,

diphenyliodonium N,N-bis(trifluoromethanesulfonyl)imidate,

diphenyliodonium N,N-bis(pentafluoroethanesulfonyl)imidate, diphenyliodonium

N,N-bis(heptafluoro-n-propanesulfonyl)imidate, diphenyliodonium

N,N-bis(nonafluoro-n-butanesulfonyl)imidate,

diphenyliodonium benzenesulfonate,

diphenyliodonium 4-trifluoromethylbenzenesulfonate,

diphenyliodonium 2,4-difluorobenzenesulfonate,

diphenyliodonium 2,3,4,5,6-pentafluorobenzenesulfonate,

diphenyliodonium 10-camphorsulfonate,

bis(4-t-butylphenyl)iodoniumtrifluoromethane sulfonate,

bis(4-t-butylphenyl)iodonium nonafluoro-n-butanesulfonate,

bis(4-t-butylphenyl)iodonium perfluoro-n-octanesulfonate,

bis(4-t-butylphenyl)iodonium

2-(bicyclo[2.2.1]heptan-2-yl)-1,1,2,2-tetrafluoro-ethanesulfonate,

bis(4-t-butylphenyl)iodonium

2-(5-hydroxybicyclo[2.2.1]heptan-2-yl)-1,1,2,2-tetrafluoro-ethanesulfonate,

bis(4-t-butylphenyl)iodonium

2-(6-hydroxybicyclo[2.2.1]heptan-2-yl)-1,1,2,2-tetrafluoro-ethanesulfonate,

bis(4-t-butylphenyl)iodonium

2-(tetracyclo[6.2.1.1^{3,6}.0^{2,7}]dodecan-4-yl)-1,1,2,2-tetrafluoroethanesulfonate,

bis(4-t-butylphenyl)iodonium

2-(9-hydroxytetracyclo[6.2.1.1^{3,6}.0^{2,7}]dodecan-4-yl)-1,1,2,2-tetrafluoroethanesulfonate,

bis(4-t-butylphenyl)iodonium

2-(10-hydroxytetracyclo[6.2.1.1^{3,6}.0^{2,7}]dodecan-4-yl)-1,1,2,2-tetrafluoroethanesulfonate,

bis(4-t-butylphenyl)iodonium

N,N-bis(trifluoromethanesulfonyl)imidate,

bis(4-t-butylphenyl)iodonium

N,N-bis(pentafluoroethanesulfonyl)imidate,

bis(4-t-butylphenyl)iodonium

N,N-bis(heptafluoro-n-propanesulfonyl)imidate,

bis(4-t-butylphenyl)iodonium

N,N-bis(nonafluoro-n-butanesulfonyl)imidate,

bis(4-t-butylphenyl)iodonium benzenesulfonate,

bis(4-t-butylphenyl)iodonium

4-trifluoromethylbenzenesulfonate,

bis(4-t-butylphenyl)iodonium 2,4-difluorobenzenesulfonate,

bis(4-t-butylphenyl)iodonium

2,3,4,5,6-pentafluorobenzenesulfonate,

bis(4-t-butylphenyl)iodonium 10-camphorsulfonate,

triphenylsulfonium trifluoromethanesulfonate,

triphenylsulfonium nonafluoro-n-butanesulfonate,

triphenylsulfonium perfluoro-n-octanesulfonate,

triphenyliodonium

2-(bicyclo[2.2.1]heptan-2-yl)-1,1,2,2-tetrafluoro-ethanesulfonate,

triphenyliodonium

2-(5-hydroxybicyclo[2.2.1]heptan-2-yl)-1,1,2,2-tetrafluoro-ethanesulfonate,

triphenyliodonium

2-(6-hydroxybicyclo[2.2.1]heptan-2-yl)-1,1,2,2-tetrafluoro-ethanesulfonate,

triphenylsulfonium

2-(tetracyclo[6.2.1.1^{3,6}.0^{2,7}]dodecan-4-yl)-1,1,2,2-tetrafluoroethanesulfonate,

triphenylsulfonium

2-(9-hydroxytetracyclo[6.2.1.1^{3,6}.0^{2,7}]dodecan-4-yl)-1,1,2,2-tetrafluoroethanesulfonate,

triphenyliodonium

2-(10-hydroxytetracyclo[6.2.1.1^{3,6}.0^{2,7}]dodecan-4-yl)-1,1,2,2 -tetrafluoroethanesulfonate,

triphenylsulfonium

N,N-bis(trifluoromethanesulfonyl)imidate,

triphenylsulfonium

N,N-bis(pentafluoroethanesulfonyl)imidate,

triphenylsulfonium

N,N-bis(heptafluoro-n-propanesulfonyl)imidate,

triphenylsulfonium

N,N-bis(nonafluoro-n-butanesulfonyl)imidate,

triphenylsulfonium benzenesulfonate,

triphenylsulfonium 4-trifluoromethylbenzenesulfonate,

triphenylsulfonium 2,4-difluorobenzenesulfonate,

tiphenylsulfonium 2,3,4,5,6-pentafluorobenzenesulfonate,

triphenylsulfonium 10-camphorsulfonate,

bicyclo[2.2.1]heptan-2-yl.cyclohexyl.2-oxocyclohexyl-sulfonium trifluoromethanesulfonate,

bicyclo[2.2.1]heptan-2-yl.cyclohexyl.2-oxocyclohexyl-sulfonium nonafluoro-n-butanesulfonate,

bicyclo[2.2.1]heptan-2-yl.cyclohexyl.2-oxocyclohexyl-sulfonium perfluoro-n-octanesulfonate,

bicyclo[2.2.1]heptan-2-yl.cyclohexyl.2-oxocyclohexyl-sulfonium 2-(bicyclo[2.2.1]heptan-2-yl)-1,1,2,2-tetrafluoroethane-sulfonate,

bicyclo[2.2.1]heptan-2-yl.cyclohexyl.2-oxocyclohexyl-sulfonium 2-(5-hydroxybicyclo[2.2.1]hept-2-yl)-1,1,2,2-tetrafluoro-ethanesulfonate,

bicyclo[2.2.1]heptan-2-yl.cyclohexyl.2-oxocyclohexyl-sulfonium 2-(6-hydroxybicyclo[2.2.1]hept-2-yl)-1,1,2,2-tetrafluoro-ethanesulfonate,

bicyclo[2.2.1]heptan-2-yl.cyclohexyl.2-oxocyclohexyl-sulfonium 2-(tetracyclo [6.2.1.1^{3,6}.0^{2,7}]dodecan-4-yl)-1,1,2,2-tetrafluoroethane-sulfonate,

bicyclo[2.2.1]heptan-2-yl.cyclohexyl.2-oxocyclohexyl-sulfonium 2-(9-hydroxytetracyclo[6.2.1.1^{3,6}.0^{2,7}]-dodecan-4-yl)-1,1,2,2-tetrafluoroethanesulfonate,

bicyclo[2.2.1]heptan-2-yl.cyclohexyl.2-oxocyclohexyl-sulfonium 2-(10-hydroxytetracyclo[6.2.1.1^{3,6}.0^{2,7}]-dodecan-4-yl)-1,1,2,2-tetrafluoroethanesulfonate,

bicyclo[2.2.1]heptan-2-yl.cyclohexyl.2-oxocyclohexyl-sulfonium N,N-bis(trifluoromethanesulfonyl)imidate,

bicyclo[2.2.1]heptan-2-yl.cyclohexyl.2-oxocyclohexyl-sulfonium N,N-bis(pentafluoroethanesulfonyl)imidate,

bicyclo[2.2.1]heptan-2-yl.cyclohexyl.2-oxocyclohexyl-sulfonium N,N-bis(heptafluoro-n-propanesulfonyl)imidate,

bicyclo[2.2.1]heptan-2-yl.cyclohexyl.2-oxocyclohexyl-sulfonium N,N-bis(nonafluoro-n-butanesulfonyl)imidate,

bicyclo[2.2.1]heptan-2-yl.cyclohexyl.2-oxocyclohexyl-sulfonium benzenesulfonate,

bicyclo[2.2.1]heptan-2-yl.cyclohexyl.2-oxocyclohexyl-sulfonium 4-trifluoromethylbenzenesulfonate,

bicyclo[2.2.1]heptan-2-yl.cyclohexyl.2-oxocyclohexyl-sulfonium 2,4-difluorobenzenesulfonate,

bicyclo[2.2.1]heptan-2-yl.cyclohexyl.2-oxocyclohexyl-sulfonium 2,3,4,5,6-pentafluorobenzenesulfonate,

bicyclo[2.2.1]heptan-2-yl.cyclohexyl.2-oxocyclohexyl-sulfonium 10-camphorsulfonate,

1-[2-(naphthalen-1-yl)-2-oxoethyl]tetrahydrothiophenium trifluoromethanesulfonate,

1-[2-(naphthalen-1-yl)-2-oxoethyl]tetrahydrothiophenium nonafluoro-n-butanesulfonate,

1-[2-(naphthalen-1-yl)-2-oxoethyl]tetrahydrothiophenium perfluoro-n-octanesulfonate,

1-[2-(naphthalen-1-yl)-2-oxoethyl]tetrahydrothiophenium

2-(bicyclo[2.2.1]heptan-2-yl)-1,1,2,2-tetrafluoroethane-sulfonate,

1-[2-(naphthalen-1-yl)-2-oxoethyl]tetrahydrothiophenium

2-(5-hydroxybicyclo[2.2.1]heptan-2-yl)-1,1,2,2-tetrafluoro-ethanesulfonate,

1-[2-(naphthalen-1-yl)-2-oxoethyl]tetrahydrothiophenium

2-(6-hydroxybicyclo[2.2.1]heptan-2-yl)-1,1,2,2-tetrafluoro-ethanesulfonate,

1-[2-(naphthalen-1-yl)-2-oxoethyl]tetrahydrothiophenium

2-(tetracyclo[6.2.1.1^{3,6}.0^{2,7}]dodecan-4-yl)-1,1,2,2-tetrafluoroethanesulfonate,

1-[2-(naphthalen-1-yl)-2-oxoethyl]tetrahydrothiophenium

2-(9-hydroxytetracyclo[6.2.1.1^{3,6}.0^{2,7}]dodecan-4-yl)-1,1,2,2-tetrafluoroethanesulfonate,

1-[2-(naphthalen-1-yl)-2-oxoethyl]tetrahydrothiophenium

2-(10-hydroxytetracyclo[6.2.1.1^{3,6}.0^{2,7}]dodecan-4-yl)-1,1,2,2-tetrafluoroethanesulfonate,

1-[2-(naphthalen-1-yl)-2-oxoethyl]tetrahydrothiophenium N,N-bis(trifluoromethanesulfonyl)imidate,

1-[2-(naphthalen-1-yl)-2-oxoethyl]tetrahydrothiophenium N,N-bis(pentafluoroethanesulfonyl)imidate,

1-[2-(naphthalen-1-yl)-2-oxoethyl]tetrahydrothiophenium N,N-bis(heptafluoro-n-propanesulfonyl)imidate,

1-[2-(naphthalen-1-yl)-2-oxoethyl]tetrahydrothiophenium N,N-bis(nonafluoro-n-butanesulfonyl)imidate,

1-[2-(naphthalen-1-yl)-2-oxoethyl]tetrahydrothiophenium benzenesulfonate,

1-[2-(naphthalen-1-yl)-2-oxoethyl]tetrahydrothiophenium 4-trifluoromethylbenzenesulfonate,

1-[2-(naphthalen-1-yl)-2-oxoethyl]tetrahydrothiophenium 2,4-difluorobenzenesulfonate,

1-[2-(naphthalen-1-yl)-2-oxoethyl]tetrahydrothiophenium 2,3,4,5,6-pentafluorobenzenesulfonate,

1-[2-(naphthalen-1-yl)-2-oxoethyl]tetrahydrothiophenium 10-camphorsulfonate,

1-(4-hydroxynaphthalen-1-yl)tetrahydrothiophenium trifluoromethanesulfonate,

1-(4-hydroxynaphthalen-1-yl)tetrahydrothiophenium perfluoro-n-octanesulfonate,

1-(4-hydroxynaphthalen-1-yl)tetrahydrothiophenium

2-(bicyclo[2.2.1]heptan-2-yl)-1,1,2,2-tetrafluoroethane-sulfonate,

1-(4-hydroxynaphthalen-1-yl)tetrahydrothiophenium

2-(5-hydroxybicyclo[2.2.1]heptan-2-yl)-1,1,2,2-tetrafluoro-ethanesulfonate,

1-(4-hydroxynaphthalen-1-yl)tetrahydrothiophenium

2-(6-hydroxybicyclo[2.2.1]heptan-2-yl)-1,1,2,2-tetrafluoro-ethanesulfonate,

1-(4-hydroxynaphthalen-1-yl)tetrahydrothiophenium

2-(tetracyclo[6.2.1.1^{3,6}.0^{2,7}]dodecan-4-yl)-1,1,2,2-tetrafluoroethanesulfonate,

1-(4-hydroxynaphthalen-1-yl)tetrahydrothiophenium

2-(9-hydroxytetracyclo[6.2.1.1^{3,6}.0^{2,7}]dodecan-4-yl)-1,1,2,2-tetrafluoroethanesulfonate,

1-(4-hydroxynaphthalen-1-yl)tetrahydrothiophenium

2-(10-hydroxytetracyclo[6.2.1.1^{3,6}.0^{2,7}]dodecan-4-yl)-1,1,2,2-tetrafluoroethanesulfonate,

1-(4-hydroxynaphthalen-1-yl)tetrahydrothiophenium N,N-bis(trifluoromethanesulfonyl)imidate,

1-(4-hydroxynaphthalen-1-yl)tetrahydrothiophenium N,N-bis(pentafluoroethanesulfonyl)imidate,

1-(4-hydroxynaphthalen-1-yl)tetrahydrothiophenium N,N-bis(heptafluoro-n-propanesulfonyl)imidate,

1-(4-hydroxynaphthalen-1-yl)tetrahydrothiophenium N,N-bis(nonafluoro-n-butanesulfonyl)imidate,

1-(4-hydroxynaphthalen-1-yl)tetrahydrothiophenium benzenesulfonate,

diphenyliodonium 4-trifluoromethylbenzenesulfonate,

1-(4-hydroxynaphthalen-1-yl)tetrahydrothiophenium 2,4-difluorobenzenesulfonate,

1-(4-hydroxynaphthalen-1-yl)tetrahydrothiophenium 2,3,4,5,6-pentafluorobenzenesulfonate,

1-(4-hydroxynaphthalen-1-yl)tetrahydrothiophenium 10-camphorsulfonate,

1-(4-n-butoxynaphthalen-1-yl)tetrahydrothiophenium trifluoromethanesulfonate,

1-(4-n-butoxynaphthalen-1-yl)tetrahydrothiophenium nonafluoro-n-butanesulfonate,

1-(4-n-butoxynaphthalen-1-yl)tetrahydrothiophenium perfluoro-n-octanesulfonate,

1-(4-n-butoxynaphthalen-1-yl)tetrahydrothiophenium

2-(bicyclo[2.2.1]heptan-2-yl)-1,1,2,2-tetrafluoroethane-sulfonate,

1-(4-n-butoxynaphthalen-1-yl)tetrahydrothiophenium

2-(5-hydroxybicyclo[2.2.1]heptan-2-yl)-1,1,2,2-tetrafluoro-ethanesulfonate,

1-(4-n-butoxynaphthalen-1-yl)tetrahydrothiophenium

2-(6-hydroxybicyclo[2.2.1]heptan-2-yl)-1,1,2,2-tetrafluoro-ethanesulfonate,

1-(4-n-butoxynaphthalen-1-yl)tetrahydrothiophenium

2-(tetracyclo[6.2.1.1^{3,6}.0^{2,7}]dodecan-4-yl)-1,1,2,2-tetrafluoroethanesulfonate,

1-(4-n-butoxynaphthalen-1-yl)tetrahydrothiophenium

2-(9-hydroxytetracyclo[6.2.1.1^{3,6}.0^{2,7}]dodecan-4-yl)-1,1,2,2-tetrafluoroethanesulfonate,

1-(4-n-butoxynaphthalen-1-yl)tetrahydrothiophenium

2-(10-hydroxytetracyclo[6.2.1.1^{3,6}.0^{2,7}]dodecan-4-yl)-1,1,2,2-tetrafluoroethanesulfonate,

1-(4-n-butoxynaphthalen-1-yl)tetrahydrothiophenium N,N-bis(trifluoromethanesulfonyl)imidate,

1-(4-n-butoxynaphthalen-1-yl)tetrahydrothiophenium N,N-bis(pentafluoroethanesulfonyl)imidate,

1-(4-n-butoxynaphthalen-1-yl)tetrahydrothiophenium N,N-bis(heptafluoro-n-propanesulfonyl)imidate,

1-(4-n-butoxynaphthalen-1-yl)tetrahydrothiophenium N,N-bis(nonafluoro-n-butanesulfonyl)imidate,

1-(4-n-butoxynaphthalen-1-yl)tetrahydrothiophenium benzenesulfonate,

1-(4-n-butoxynaphthalen-1-yl)tetrahydrothiophenium 4-trifluoromethylbenzenesulfonate,

1-(4-n-butoxynaphthalen-1-yl)tetrahydrothiophenium 2,4-difluorobenzenesulfonate,

1-(4-n-butoxynaphthalen-1-yl)tetrahydrothiophenium 2,3,4,5,6-pentafluorobenzenesulfonate,

1-(4-n-butoxynaphtlalen-1-yl)tetrahydrothiophenium 10-camphorsulfonate,

(4-n-butoxynaphthalen-1-yl)-4-thioniatricyclo[5.2.1.0^{2,6}]-decane trifluoromethanesulfonate,

(4-n-butoxynaphthalen-1-yl)-4-thioniatricyclo[5.2.1.0^{2,6}]-decane nonafluoro-n-butanesulfonate,

(4-n-butoxynaphthalen-1-yl)-4-thioniatricyclo[5.2.1.0^{2,6}]-decane perfluoro-n-octanesulfonate,

(4-n-butoxynaphthalen-1-yl)-4-thioniatricyclo[5.2.1.0^{2,6}]-decane

2-(bicyclo[2.2.1]heptan-2-yl)-1,1,2,2-tetrafluoroethane-sulfonate,

(4-n-butoxynaphthalen-1-yl)-4-thioniatricyclo[5.2.1.0^{2,6}]-decane

2-(5-hydroxybicyclo[2.2.1]hept-2-yl)-1,1,2,2-tetrafluoro-ethanesulfonate,

(4-n-butoxynaphthalen-1-yl)-4-thioniatricyclo[5.2.1.0^{2,6}]-decane

2-(6-hydroxybicyclo[2.2.1]hept-2-yl)-1,1,2,2-tetrafluoro-ethanesulfonate,

(4-n-butoxynaphthalen-1-yl)-4-thioniatricyclo[5.2.1.0^{2,6}]-decane

2-(tetracyclo[6.2.1.1^{3,6}.0^{2,7}]dodecan-4-yl)-1,1,2,2-tetrafluoroethanesulfonate,

(4-n-butoxynaphthalen-1-yl)-4-thioniatricyclo[5.2.1.0^{2,6}]-decane

2-(9-hydroxytetracyclo[6.2.1.1^{3,6}.0^{2,7}]dodecan-4-yl)-1,1,2,2-tetrafluoroethanesulfonate,

(4-n-butoxynaphthalen-1-yl)-4-thioniatricyclo[5.2.1.0^{2,6}]-decane

2-(10-hydroxytetracyclo[6.2.1.1^{3,6}.0^{2,7}]dodecan-4-yl)-1,1,2,2-tetrafluoroethanesulfonate,

(4-n-butoxynaphthalen-1-yl)-4-thioniatricyclo[5.2.1.0^{2,6}]-decane N,N-bis(trifluoromethanesulfonyl)imidate,

(4-n-butoxynaphthalen-1-yl)-4-thioniatricyclo[5.2.1.0^{2,6}]-decane N,N-bis(pentafluoroethanesulfonyl)imidate,

(4-n-butoxynaphthalen-1-yl)-4-thioniatricyclo[5.2.1.0^{2,6}]-decane N,N-bis(heptafluoro-n-propanesulfonyl)imidate,

(4-n-butoxynaphthalen-1-yl)-4-thioniatricyclo[5.2.1.0^{2,6}]-decane N,N-bis(nonafluoro-n-butanesulfonyl)imidate,

(4-n-butoxynaphthalen-1-yl)-4-thioniatricyclo[5.2.1.0^{2,6}]-decane benzenesulfonate,

(4-n-butoxynaphthalen-1-yl)-4-thioniatricyclo[5.2.1.0^{2,6}]-decane 4-trifluoromethylbenzenesulfonate,

(4-n-butoxynaphthalen-1-yl)-4-thioniatricyclo[5.2.1.0^{2,6}]-decane 2,4-difluorobenzenesulfonate,

(4-n-butoxynaphthalen-1-yl)-4-thioniatricyclo[5.2.1.0^{2,6}]-decane 2,3,4,5,6-pentafluorobenzenesulfonate,

(4-n-butoxynaphthalen-1-yl)-4-thioniatricyclo[5.2.1.0^{2,6}]-decane 10-camphorsulfonate,

1-(3,5-dimethyl-4-hydroxyphenyl)tetrahydrothiophenium trifluoromethanesulfonate,

1-(3,5-dimethyl-4-hydroxyphenyl)tetrahydrothiophenium nonafluoro-n-butanesulfonate,

1-(3,5-dimethyl-4-hydroxyphenyl)tetrahydrothiophenium perfluoro-n-octanesulfonate,

1-(3,5-dimethyl-4-hydroxyphenyl)tetrahydrothiophenium

2-(bicyclo[2.2.1]heptan-2-yl)-1,1,2,2-tetrafluoroethane-sulfonate,

1-(3,5-dimethyl-4-hydroxyphenyl)tetrahydrothiophenium

2-(5-hydroxybicyclo[2.2.1]hept-2-yl)-1,1,2,2-tetrafluoro-ethanesulfonate,

1-(3,5-dimethyl-4-hydroxyphenyl)tetrahydrothiophenium

2-(6-hydroxybicyclo[2.2.1]hept-2-yl)-1,1,2,2-tetrafluoro-ethanesulfonate,

1-(3,5-dimethyl-4-hydroxyphenyl)tetrahydrothiophenium

2-(tetracyclo[6.2.1.1^{3,6}.0^{2,7}]dodecan-4-yl)-1,1,2,2-tetrafluoroethanesulfonate,

1-(3,5-dimethyl-4-hydroxyphenyl)tetrahydrothiophenium

2-(9-hydroxytetracyclo[6.2.1.1^{3,6}.0^{2,7}]dodecan-4-yl)-1,1,2,2-tetrafluoroethanesulfonate,

1-(3,5-dimethyl-4-hydroxyphenyl)tetrahydrothiophenium

2-(10-hydroxytetracyclo[6.2.1.1^{3,6}.0^{2,7}]dodecan-4-yl)-1,1,2,2-tetrafluoroethanesulfonate,

1-(3,5-dimethyl-4-hydroxyphenyl)tetrahydrothiophenium N,N-bis(trifluoromethanesulfonyl)imidate,

1-(3,5-dimethyl-4-hydroxyphenyl)tetrahydrothiophenium N,N-bis(pentafluoroethanesulfonyl)imidate,

1-(3,5-dimethyl-4-hydroxyphenyl)tetrahydrothiophenium N,N-bis(heptafluoro-n-propanesulfonyl)imidate,

1-(3,5-dimethyl-4-hydroxyphenyl)tetrahydrothiophenium N,N-bis(nonafluoro-n-butanesulfonyl)imidate,

1-(3,5-dimethyl-4-hydroxyphenyl)tetrahydrothiophenium benzenesulfonate,

1-(3,5-dimethyl-4-hydroxyphenyl)tetrahydrothiophenium 4-trifluoromethylbenzenesulfonate,

1-(3,5-dimethyl-4-hydroxyphenyl)tetrahydrothiophenium 2,4-difluorobenzenesulfonate,

1-(3,5-dimethyl-4-hydroxyphenyl)tetrahydrothiophenium 2,3,4,5, 6-pentafluorobenzenesulfonate,

1-(3,5-dimethyl-4-hydroxyphenyl) tetrahydrothiophenium 10-camphorsulfonate,

1-(3,5-dimethyl-4-butoxyphenyl)tetrahydrothiophenium trifluoromethanesulfonate,

1-(3,5-dimethyl-4-butoxyphenyl)tetrahydrothiophenium nonafluoro-n-butanesulfonate,

1-(3,5-dimethyl-4-butoxyphenyl)tetrahydrothiophenium perfluoro-n-octanesulfonate,

1-(3,5-dimethyl-4-butoxyphenyl)tetrahydrothiophenium

2-(bicyclo[2.2.1]heptan-2-yl)-1,1,2,2-tetrafluoroethane-sulfonate,

1-(3,5-dimethyl-4-butoxyphenyl)tetrahydrothiophenium

2-(5-hydroxybicyclo[2.2.1]heptan-2-yl)-1,1,2,2-tetrafluoro-ethanesulfonate,

1-(3,5-dimethyl-4-butoxyphenyl)tetrahydrothiophenium

2-(6-hydroxybicyclo[2.2.1]heptan-2-yl)-1,1,2,2-tetrafluoroethanesulfonate,

1-(3,5-dimethyl-4-butoxyphenyl)tetrahydrothiophenium

2-(tetracyclo[6.2.1.1^{3,6}.0^{2,7}]dodecan-4-yl)-1,1,2,2-tetrafluoroethanesulfonate,

1-(3,5-dimethyl-4-butoxyphenyl)tetrahydrothiophenium

2-(9-hydroxytetracyclo[6.2.1.1^{3,6}.0^{2,7}]dodecan-4-yl)-1,1,2,2-tetrafluoroethanesulfonate,

1-(3,5-dimethyl-4-butoxyphenyl)tetrahydrothiophenium

2-(10-hydroxytetracyclo[6.2.1.1^{3,6}.0^{2,7}]dodecan-4-yl)-1,1,2,2-tetrafluoroethanesulfonate,

1-(3,5-dimethyl-4-butoxyphenyl)tetrahydrothiophenium N,N-bis(trifluoromethanesulfonyl)imidate,

1-(3,5-dimethyl-4-butoxyphenyl)tetrahydrothiophenium N,N-bis(pentafluoroethanesulfonyl)imidate,

1-(3,5-dimethyl-4-butoxyphenyl)tetrahydrothiophenium N,N-bis(heptafluoro-n-propanesulfonyl)imidate,

1-(3,5-dimethyl-4-butoxyphenyl)tetrahydrothiophenium N,N-bis(nonafluoro-n-butanesulfonyl)imidate,

1-(3,5-dimethyl-4-butoxyphenyl)tetrahydrothiophenium benzenesulfonate,

1-(3,5-dimethyl-4-butoxyphenyl)tetrahydrothiophenium 4-trifluoromethylbenzenesuifonate,

1-(3,5-dimethyl-4-butoxyphenyl)tetrahydrothiophenium 2,4-difluorobenzenesulfonate,

1-(3,5-dimethyl-4-butoxyphenyl)tetrahydrothiophenium 2,3,4,5,6-pentafluorobenzenesulfonate,

1-(3,5-dimethyl-4-butoxyphenyl)tetrahydrothiophenium 10-camphorsulfonate,

N-(trifluoromethanesulfonyloxy)succinimide,

N-(nonafluoro-n-butanesulfonyloxy)succinimide,

N-(perfluoro-n-octanesulfonyloxy)succinimide,

N-[2-(bicyclo[2.2.1]heptan-2-yl)-1,1,2,2-tetrafluoroethane-sulfonyloxy]succinimide,

N-[2-(5-hydroxybicyclo[2.2.1]heptan-2-yl)-1,1,2,2-tetrafluoroethanesulfonyloxy]succinimide,

N-[2-(6-hydroxybicyclo[2.2.1]heptan-2-yl)-1,1,2,2-tetrafiuoroethanesulfonyloxy]succinimide,

N-[2-(tetracyclo[6.2.1.1^{3,6}.0^{2,7}]dodecan-4-yl)-1,1,2,2-tetrafluoroethanesulfonyloxy]succinimide,

N-[2-(9-hydroxytetracyclo[6.2.1.1^{3,6}.0^{2,7}]dodecan-4-yl)-1,1,2,2-tetrafluoroethanesulfonyloxy]succinimide,

N-[2-(10-hydroxytetracyclo[6.2.1.1^{3,6}.0^{2,7}]dodecan-4-yl)-1,1,2,2-tetrafluoroethanesulfonyloxy]succinimide,

N-(benzenesulfonyloxy)succinimide,

N-(4-trifluoromethylbenzenesulfonyloxy)succinimide,

N-(2,4-difluorobenzenesulfonyloxy)succinimide,

N-(2,3,4,5,6-pentafluorobenzenesulfonyloxy)succinimide,

N-(10-camphorsulfonyloxy)succinimide,

N-(trifluoromethanesulfonyloxy)bicyclo[2.2.1]hept-5-ene-2,3-dicarboxyimide,

N-(nonafluoro-n-butanesulfonyloxy)bicyclo[2.2.1]hept-5-ene-2,3-dicarboxyimide,

N-(perfluoro-n-octanesulfonyloxy)bicyclo[2.2.1]hept-5-ene-2,3-dicarboxyimide,

N-[2-(bicyclo[2.2.1]heptan-2-yl)-1,1,2,2-tetrafluoroethane-sulfonyloxy]bicyclo[2.2.1]hept-5-ene-2,3-dicarboxyimide,

N-[2-(5-hydroxybicyclo[2.2.1]heptan-2-yl)-1,1,2,2-tetrafluoroethanesulfonyloxy]bicyclo[2.2.1]hept-5-ene-2,3-dicarboxyimide,

N-[2-(6-hydroxybicyclo[2.2.1]heptan-2-yl)-1,1,2,2-tetrafluoroethanesulfonyloxy]bicyclo[2.2.1]hept-5-ene-2,3-dicarboxyimide,

N-[2-(tetracyclo[6.2.1.1^{3,6}.0^{2,7}]dodecan-4-yl)-1,1,2,2-tetrafluoroethanesulfonyloxy]bicyclo[2.2.1]hept-5-ene-2,3-dicarboxyimide,

N-[2-(9-hydroxytetracyclo[6.2.1.1^{3,6}.0^{2,7}]dodecan-4-yl)-1,1,2,2-tetrafluoroethanesulfonyloxy]bicyclo[2.2.1]hept-5-ene-2,3-dicarboxyimide,

N-(benzenesulfonyloxy)bicyclo[2.2.1]hept-5-ene-2,3-dicarboxyimide,

N-(4-trifluoromethylbenzenesulfonyloxy)bicyclo[2.2.1]hept-5-ene-2,3-dicarboxyimide,

N-(2,4-difluorobenzenesulfonyloxy)bicyclo[2.2.1]hept-5-ene-2,3-dicarboxyimide,

N-(2,3,4,5,6-pentafluorobenzenesulfonyloxy)bicyclo[2.2.1]-hept-5-ene-2,3-dicarboxyimide,

N-(10-camphorsulfonyloxy)bicyclo[2.2.1]hept-5-ene-2,3-dicarboxyimide,

N-(trifluoromethanesulfonyloxy)-7-oxabicyclo[2.2.1]hept-5-ene-2,3-dicarboxyimide,

N-(nonafluoro-n-butanesulfonyloxy)-7-oxabicyclo[2.2.1]hept-5-ene-2,3-dicarboxyimide,

N-(perfluoro-n-octanesulfonyloxy)-7-oxabicyclo[2.2.1]hept-5-ene-2,3-dicarboxyimide,

N-[2-(bicyclo[2.2.1]heptan-2-yl)-1,1,2,2-tetrafluoroethane-sulfonyloxy]-7-oxabicyclo[2.2.1]hept-5-ene-2,3-dicarboxyimide,

N-[2-(5-hydroxybicyclo[2.2.1]hept-2-yl)-1,1,2,2-tetrafluoroethanesulfonyloxyl]-7-oxabicyclo[2.2.1]hept-5-ene-2,3-dicarboxyimide,

N-[2-(6-hydroxybicyclo[2.2.1]hept-2-yl)-1,1,2,2-tetrafluoroethanesulfonyloxy]-7-oxabicyclo[2.2.1]hept-5-ene-2,3-dicarboxyimide,

N-[2-(tetracyclo[6.2.1.1^{3,6}.0^{2,7}]dodecan-4-yl)-1,1,2,2-tetrafluoroethanesulfonyloxy]-7-oxabicyclo[2.2.1]hept-5-ene-2,3-dicarboxyimide,

N-[2-(9-hydroxytetracyclo[6.2.1.1^{3,6}.0^{2,7}]dodecan-4-yl)-1,1,2,2-tetrafluoroethanesulfonyloxy]-7-oxabicyclo[2.2.1]-hept-5-ene-2,3-dicarboxyimide,

N-[2-(10-hydroxytetracyclo[6.2.1.1^{3,6}.0^{2,7}]dodecan-4-yl)-1,1,2,2-tetrafluoroethanesulfonyloxy]-7-oxabicyclo[2.2.1]-hept-5-ene-2,3-dicarboxyimide,

N-(benzenesulfonyloxy)-7-oxabicyclo[2.2.1]hept-5-ene-2,3-dicarboxyimide,

N-(4-trifluoromethylbenzenesulfonyloxy)-7-oxabicyclo-[2.2.1]hept-5-ene-2,3-dicarboxyimide,

N-(2,4-difluorobenzenesulfonyloxy)-7-oxabicyclo[2.2.1]hept-5-ene-2,3-dicarboxyimide,

N-(2,3,4,5,6-pentafluorobenzenesulfonyloxy)-7-oxabicyclo-[2.2.1]hept-5-ene-2,3-dicarboxyimide,

and N-(10-camphorsulfonyloxy)-7-oxabicyclo[2.2.1]hept-5-ene-2,3-dicarboxyimide.

Of these acid generators (B), the following compounds are particularly preferable:

diphenyliodonium trifluoromethanesulfonate,

diphenyliodonium nonafluoro-n-butanesulfonate,

diphenyliodonium perfluoro-n-octanesulfonate,

diphenyliodonium 2-(bicyclo[2.2.1]heptan-2-yl)-1,1,2,2-tetrafluoroethanesulfonate,

diphenyliodonium 2-(tetracyclo[6.2.1.1^{3,6}.0^{2,7}]dodecan-4-yl)-1,1,2,2-tetrafluoroethanesulfonate,

diphenyliodonium

N,N-bis(nonafluoro-n-butanesulfonyl)imidate,

diphenyliodonium 10-camphorsulfonate,

bis(4-t-butylphenyl)iodonium trifluoromethanesulfonate,

bis(4-t-butylphenyl)iodonium nonafluoro-n-butanesulfonate,

bis(4-t-butylphenyl)iodonium perfluoro-n-octanesulfonate,

bis(4-t-butylphenyl)iodonium

2-(bicyclo[2.2.1]heptan-2-yl)-1,1,2,2-tetrafluoroethane-sulfonate, bis(4-t-butylphenyl)iodonium

2-(tetracyclo[6.2.1.1^{3,6}.0^{2,7}]dodecan-4-yl)-1,1,2,2-tetrafluoroethanesulfonate, bis(4-t-butylphenyl)iodonium

N,N-bis(nonafluoro-n-butanesulfonyl)imidate,

bis(4-t-butylphenyl)iodonium 10-camphorsulfonate,

triphenylsulfonium trifluoromethanesulfonate,

triphenylsulfonium nonafluoro-n-butanesulfonate,

triphenylsulfonium perfluoro-n-octanesulfonate,

triphenyliodonium 2-(bicyclo[2.2.1]heptan-2-yl)-1,1,2,2-tetrafluoroethanesulfonate,

triphenyliodonium 2-(tetracyclo[6.2.1.1^{3,6}.0^{2,7}]-dodecan-4-yl)-1,1,2,2-tetrafluoroethanesulfonate,

triphenylsulfonium

N,N-bis(nonafluoro-n-butanesulfonyl)imidate,

triphenylsulfonium 10-camphorsulfonate,

1-(4-n-butoxynaphthalen-1-yl)tetrahydrothiophenium trifluoromethanesulfonate,

1-(4-n-butoxynaphthalen-1-yl)tetrahydrothiophenium nonafluoro-n-butanesulfonate,

1-(4-n-butoxynaphthalen-1-yl)tetrahydrothiophenium perfluoro-n-octanesulfonate,

1-(4-n-butoxynaphthalen-1-yl)tetrahydrothiophenium 2-(bicyclo[2.2.1]heptan-2-yl)-1,1,2,2-tetrafluoro-ethanesulfonate,

1-(4-n-butoxynaphthalen-1-yl)tetrahydrothiophenium 2-(tetracyclo[6.2.1.1^{3,6}.0^{2,7}]dodecan-4-yl)-1,1,2,2-tetrafluoroethanesulfonate,

1-(4-n-butoxynaphthalen-1-yl)tetrahydrothiophenium N,N-bis(nonafluoro-n-butanesulfonyl)imidate,

1-(4-n-butoxynaphthalen-1-yl)tetrahydrothiophenium 10-camphorsulfonate,

1-(3,5-dimethyl-4-hydroxyphenyl)tetrahydrothiophenium trifluoromethanesulfonate,

1-(3,5-dimethyl-4-hydroxyphenyl)tetrahydrothiophenium nonafluoro-n-butanesulfonate,

1-(3,5-dimethyl-4-hydroxyphenyl)tetrahydrothiophenium perfluoro-n-octanesulfonate,

1-(3,5-dimethyl-4-hydroxyphenyl)tetrahydrothiophenium 2-(bicyclo[2.2.1]heptan-2-yl)-1,1,2,2-tetrafluoro-ethanesulfonate,

1-(3,5-dimethyl-4-hydroxyphenyl)tetrahydrothiophenium

2-(tetracyclo[6.2.1.1^{3,6}.0^{2,7}]dodecan-4-yl)-1,1,2,2-tetrafluoroethanesulfonate,

1-(3,5-dimethyl-4-hydroxyphenyl)tetrahydrothiophenium N,N-bis(nonafluoro-n-butanesulfonyl)imidate,

1-(3,5-dimethyl-4-hydroxyphenyl)tetrahydrothiophenium 10-camphorsulfonate,

N-(trifluoroinethanesulfonyloxy)succinimide,

N-(nonafluoro-n-butanesulfonyloxy)succinimide,

N-(perfluoro-n-octanesulfonyloxy)succinimide,

N-[2-(bicyclo[2.2.1]heptan-2-yl)-1,1,2,2-tetrafluoro-ethanesulfonyloxy]succinimide,

N-[2-(tetracyclo[6.2.1.1^{3,6}.0^{2,7}]dodecan-4-yl)-1,1,2,2-tetrafluoroethanesulfonyloxy]succinimide,

N-(10-camphorsulfonyloxy)succinimide,

N-(trifluoromethanesulfonyloxy)bicyclo[2.2.1]hept-5-ene-2,3-dicarboxyimide,

N-(nonafluoro-n-butanesulfonyloxy)bicyclo[2.2.1]hept-5-ene-2,3-dicarboxyimide,

N-(perfluoro-n-octanesulfonyloxy)bicyclo[2.2.1]hept-5-ene-2,3-dicarboxyimide,

N-[2-(bicyclo[2.2.1]heptan-2-yl)-1,1,2,2-tetrafluoroethane-sulfonyloxy]bicyclo[2.2.1]hept-5-ene-2,3-dicarboxyimide,

N-[2-(tetracyclo[6.2.1.1^{3,6}.0^{2,7}]dodecan-4-yl)-1,1,2,2-tetrafluoroethanesulfonyloxy]bicyclo[2.2.1]hept-5-ene-2,3-dicarboxyimide,

N-(10-camphorsulfonyloxy)bicyclo[2.2.1]hept-5-ene-2,3-dicarboxyimide, and the like.

In the present invention, the acid generator (B) may be used either individually or in combination of two or more. The amount of the acid generator (B) to be used in the present invention is preferably 0.1-20 parts by weight, and more preferably 0.1-7 parts by weight for 100 parts by weight of the resin (A) from the viewpoint of ensuring sensitivity and developability as a resist. If the amount of the acid generator (B) is less than 0.1 part by weight, sensitivity and developability of the resulting resist tend to decreased. If the amount exceeds 10 parts by weight, it may be difficult to obtain a rectangular resist pattern due to a decrease in transparency to radiation.

Additives

An acid diffusion controller is preferably added to the radiation-sensitive resin composition of the present invention. The acid diffusion controller controls diffusion of an acid generated from the acid generator (B) upon exposure in the resist film and prevents unfavorable chemical reactions in the unexposed region.

The addition of such an acid diffusion controller improves storage stability of the resulting radiation-sensitive resin composition and resolution as a resist. Moreover, the addition of the acid diffusion controller prevents the line width of the resist pattern from changing due to changes in the post-exposure delay (PED) between exposure and development, whereby a composition with remarkably superior process stability can be obtained.

As the acid diffusion controller, nitrogen-containing organic compounds of which the basicity does not change due to exposure or heat treatment during formation of a resist pattern are preferable.

As examples of such nitrogen-containing organic compounds, a compound of the following formula (C) (hereinafter called “acid diffusion controller (C)”) can be given.

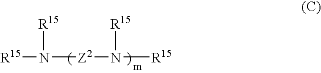

wherein R¹⁵ individually represents a hydrogen atom, a linear, branched, or cyclic alkyl group, aryl group, or aralkyl group which are either substituted or unsubstituted with a functional group such as a hydroxyl group, Z² is a divalent organic group, and m is an integer of 0-2.

In the acid diffusion controller (C), the compound having m=0 is defined as a nitrogen-containing compound (α) and the compound having m=1 or 2 is defined as a nitrogen-containing compound (β) Polyamino compounds and polymers having three or more nitrogen atoms are collectively referred to as “nitrogen-containing compound (γ)”).

As examples of nitrogen-containing organic compounds other than the acid diffusion controller (C), quaternary ammonium hydroxide compounds, amide group-containing compounds, urea compounds, and nitrogen-containing heterocyclic compounds can be given.

Examples of the nitrogen-containing compounds (α) include mono(cyclo)alkylamines such as n-hexylamine, n-heptylamine, n-octylamine, n-nonylamine, n-decylamine, and cyclohexylamine; di (cyclo) alkylamines such as di-n-butylamine, di-n-pentylamine, di-n-hexylamine, di-n-heptylamine, di-n-octylamine, di-n-nonylamine, di-n-decylamine, cyclohexylmethylamine, and dicyclohexylamine; tri(cyclo)alkylamines such as triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, cyclohexyldimethylamine, dicyclohexylmethylamine, and tricyclohexylamine; and aromatic amines such as aniline, N-methylaniline, N,N-dimethylaniline, 2-methylaniline, 3-methylaniline, 4-methylaniline, 4-nitroaniline, 2,6-dimethylaniline, 2,6-diisopropyl aniline, diphenylamine, triphenylamine, and naphthylamine.

Examples of the nitrogen-containing compound (β) include ethylenediamine, N,N,N′,N′-tetramethylethylenediamine, N,N,N′,N′-tetrakis(2-hydroxypropyl)ethylenediamine, tetramethylenediamine, 1,3-bis[1-(4-aminophenyl)-1-methylethyl]benzenetetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4′-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

Examples of the nitrogen-containing compounds (γ) include polyethyleneimine, polyallylamine, and a polymer of 2-dimethylaminoethylacrylamide.

As examples of the quaternary ammonium hydroxide compound, tetramethylammonium hydroxide, tetraethylammonium hydroxide, tetra-n-propylammonium hydroxide, and tetra-n-butylammonium hydroxide can be given.

As examples of the amide group-containing compound, N-t-butoxycarbonyl group-containing amino compounds such as N-t-butoxycarbonyl di-n-octylamine, N-t-butoxycarbonyl di-n-nonylamine, N-t-butoxycarbonyl di-n-decylamine, N-t-butoxycarbonyl dicyclohexylamine, N-t-butoxycarbonyl-1-adamantylamine, N-t-butoxycarbonyl-N-methyl-1-adamantylamine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonylbenzimidazole, N-t-butoxycarbonyl-2-methylbenzimidazole, and N-t-butoxycarbonyl-2-phenylbenzimidazole; formamide, N-methylformamide, N,N-dimethylformamide, acetamide, N-methylacetamide, N,N-dimethylacetamide, propionamide, benzamide, pyrrolidone, and N-methylpyrrolidone can be given.

As examples of the urea compound, urea, methylurea, 1,1-dimethylurea, 1, 3-dimethylurea, 1,1,3,3-tetramethylurea, 1,3-diphenylurea, and tri-n-butylthiourea can be given. Examples of the nitrogen-containing heterocyclic compounds include: imidazoles such as imidazole, 4-methylimidazole, 1-benzyl-2-methylimidazole, 4-methyl-2-phenylimidazole, benzimidazole, and 2-phenylbenzimidazole; pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, and acridine; piperazines such as piperazine, 1-(2-hydroxyethyl)piperazine; and pyrazine, pyrazole, pyridazine, quinoxaline, purine, pyrrolidine, piperidine, 3-piperidino-1,2-propanediol, morpholine, 4-methylmorpholine, 1,4-dimethylpiperazine, and 1,4-diazabicyclo[2.2.2]octane.

These acid diffusion controllers may be used either individually or in combinations of two or more.

The amount of acid diffusion controller to be added is usually 5 parts by weight or less, preferably 10 parts by weight or less, and still more preferably 5 parts by weight or less for 100 parts by weight of the resin (A). If the amount of the acid diffusion controller exceeds 15 parts by weight, sensitivity of the resulting resist and developability of the exposed region may be decreased. If the amount of the acid diffusion controller is less than 0.001 part by weight, the pattern shape or dimensional accuracy of the resulting resist may be decreased depending on the process conditions.

An additive which can further improve dry etching resistance, pattern shape, adhesion to substrate, and the like may be added to the radiation-sensitive resin composition of the present invention. Such an additive may be a compound possessing an acid-dissociable group.

Examples of such an additive include:

adamantane derivatives such as t-butyl

adamantane-1-carboxylate, t-butoxycarbonylmethyl

adamantane-1-carboxylate,α-butyrolactone

adamantane-1-carboxylate, di-t-butyl adamantane-1,3-dicarboxylate, t-butyl adamantane-1-acetate, t-butoxycarbonylmethyl adamantane-1-acetate, di-t-butyl adamantane-1,3-diacetate, and

2,5-dimethyl-2,5-di(adamantan-1-ylcarbonyloxy)hexane; deoxycholates such as t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, and mevalonolactone deoxycholate; lithocholates such as t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate; and

alkyl carboxylate such as dimethyl adipate, diethyl adipate, dipropyl adipate, di-n-butyl adipate, and di-t-butyl adipate.

These additives may be used either individually or in combinations of two or more. The amount of these additives to be added is usually 50 parts by weight or less, and preferably 30 parts by weight or less for 100 parts by weight of the resin (A). If the amount of the additives exceeds 50 parts by weight, heat resistance as a resist tends to decrease.

A surfactant which improves applicability, developability, and the like may be added to the radiation-sensitive resin composition of the present invention.

As examples of surfactants, nonionic surfactants such as polyoxyethylene laurylether, polyoxyethylene stearyl ether, polyoxyethylene oleyl ether, polyoxyethylene n-octyl phenyl ether, polyoxyethylene n-nonyl phenyl ether, polyethylene glycol dilaurate, and polyethylene glycol distearate; commercially available products such as KP341 (manufactured by Shin-Etsu Chemical Co., Ltd.), Polyflow No. 75, No. 95 (manufactured by Kyoeisha Chemical Co., Ltd.), FTOP EF301, EF303, EF352 (manufactured by Tohkem Products Corp.), MEGAFAC F171, F173 (manufactured by Dainippon Ink and Chemicals, Inc.), Fluorad FC430, FC431 (manufactured by Sumitomo 3M, Ltd.), Asahi Guard AG710, Surflon S-382, SC-101, SC-102, SC-103, SC-104, SC-105, SC-106 (manufactured by Asahi Glass Co., Ltd.); and the like can be given.

The surfactants may be used either individually or in combination of two or more.

The amount of the surfactant to be added is usually 2 parts by weight or less for 100 parts by weight of the resin (A) and the acid generator (B) in total.

A photosensitizer which improves sensitivity and the like may be added to the radiation-sensitive resin composition of the present invention.

As examples of photosensitizers, carbazoles, benzophenones, rose bengals, anthracenes, and phenols can be given.

These sensitizers may be used either individually or in combinations of two or more. The amount of the photosensitizer to be added is preferably 50 parts by weight or less for 100 parts by weight of the resin (A).

As examples of other additives, halation inhibitors, adhesion promoters, storage stabilizers, anti-foaming agents, and the like can be given.

Preparation of Composition Solution

The radiation-sensitive resin composition of the present invention is made into a composition solution by dissolving the composition in a solvent so that the total solid content is usually 3-50 wt %, and preferably 5-25 wt %, and filtering the solution using a filter with a pore diameter of about 0.2 μm, for example.

As examples of solvents used for preparation of the composition solution, linear or branched ketones such as 2-butanone, 2-pentanone, 3-methyl-2-butanone, 2-hexanone, 4-methyl-2-pentanone, 3-methyl-2-pentanone, 3,3-dimethyl-2-butanone, 2-heptanone, and 2-octanone; cyclic ketones such as cyclopentanone, 3-methylcyclopentanone, cyclohexanone, 2-methylcyclohexanone, 2,6-dimethylcyclohexanone, and isophorone; propylene glycol monoalkyl ether acetates such as propylene glycol monomethyl ether acetate, propylene glycol monoethyl ether acetate, propylene glycol mono-n-propyl ether acetate, propylene glycol mono-i-propyl ether acetate, propylene glycol mono-n-butyl ether acetate, propylene glycol mono-i-butyl ether acetate, propylene glycol mono-sec-butyl ether acetate, and propylene glycol mono-t-butyl ether acetate; alkyl 2-hydroxypropionates such as methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and t-butyl 2-hydroxypropionate; alkyl 3-alkoxypropionates such as methyl 3-methoxypropionate, ethyl 3-methoxypropionate, methyl 3-ethoxypropionate, and ethyl 3-ethoxypropionate; as well as other solvents such as n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol monomethyl ether, propylene glycol monoethyl ether, propylene glycol mono-n-propyl ether, toluene, xylene, ethyl 2-hydroxy-2-methylpropionate, ethyl ethoxyacetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetate, ethyl acetoacetate, methyl pyruvate, ethyl pyruvate, N-methyl pyrrolidone, N,N-dimethylformamide, N,N-dimethylacetamide, benzyl ethyl ether, di-n-hexyl ether, diethylene glycol monomethyl ether, diethylene glycol monoethyl ether, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, and propylene carbonate can be given.

The solvent may be used either individually or in combination of two or more. Use of a linear or branched ketone, cyclic ketone, propylene glycol monoalkyl ether acetate, alkyl 2-hydroxypropionate, alkyl 3-alkoxypropionate, γ-butyrolactone, or the like is preferable.

Formation of Resist Pattern

The radiation-sensitive resin composition of the present invention is particularly useful as a chemically-amplified resist.

In the chemically-amplified resist, an acid-dissociable group in the resin (A) dissociates by the action of an acid generated from the acid generator (B) upon exposure, thereby producing a carboxyl group. As a result, solubility of the exposed part of the resist in an alkaline developer increases, whereby the exposed part is dissolved in the alkaline developer and removed to obtain a positive-tone resist pattern.

A resist pattern is formed from the radiation-sensitive resin composition of the present invention by applying the composition solution to, for example, substrates such as a silicon wafer and a wafer coated with aluminum using an appropriate application method such as rotational coating, cast coating, roll coating, or spray coating to form a resist film. The resist film is then optionally pre-baked (hereinafter called “PB”) and exposed to form a predetermined resist pattern.

As the radiation, ultraviolet rays, deep ultraviolet rays such as KrF excimer laser (wavelength: 248 nm), ArF excimer laser (wavelength: 193 nm), F₂ excimer laser (wavelength: 157 nm), and EUV (extreme ultraviolet rays, wavelength: 13 nm, etc.), charged particle rays such as electron beams, X-rays such as synchrotron radiation, or the like may be appropriately used. Of these, deep ultraviolet rays and electron beams are preferable.

The exposure conditions such as the light exposure are appropriately determined depending on the composition of the radiation-sensitive resin composition, types of additives, and the like.

It is preferable to perform post exposure bake (hereinafter called “PEB”) in order to stably form a highly-accurate minute pattern. PEB ensures smooth dissociation of the acid-dissociable group in the resin (A) The heating temperature for the PEB is usually 30-200° C., and preferably 50-170° C., although the heating conditions are changed depending on the composition of the radiation-sensitive resin composition.

In order to bring out maximum potentiality of the radiation-sensitive resin composition of the present invention, an organic or inorganic anti-reflection film may be formed on a substrate as disclosed in Japanese Patent Publication No.1994-12452, for example. Moreover, a protection film may be formed on the resist film as disclosed in Japanese Patent Application Laid-open No. 1993-188598 or the like in order to prevent the effects of basic impurities and the like in an environmental atmosphere. These techniques may be employed in combination.

The exposed resist film is then developed to form a specific resist pattern.

As examples of a developer used for development, alkaline aqueous solutions prepared by dissolving at least one of alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, and 1,5-diazabicyclo-[4.3.0]-5-nonene are preferable.

The concentration of the alkaline aqueous solution is usually 10 wt % or less. If the concentration of the alkaline aqueous solution exceeds 10 wt %, an unexposed part may be dissolved in the developer.

Organic solvents may be added to the developer containing an alkaline aqueous solution.

As examples of organic solvents, linear, branched, or cyclic ketones such as acetone, methyl ethyl ketone, methyl i-butyl ketone, cyclopentanone, cyclohexanone, 3-methylcyclopentanone, and 2,6-dimethylcyclohexanone; alcohols such as methylalcohol, ethylalcohol, n-propylalcohol, i-propylalcohol, n-butylalcohol, t-butylalcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol, acetonylacetone, and dimethylformamide can be given.

These organic solvents may be used either individually or in combination of two or more.

The amount of the organic solvent to be used is preferably 100 vol % or less of the alkaline aqueous solution. The amount of the organic solvent exceeding 100 vol % may decrease developability, giving rise to a larger undeveloped portion in the exposed area.

In addition, surfactants or the like may be added to the developer containing the alkaline aqueous solution in an appropriate amount.

After development using the alkaline aqueous solution developer, the resist film is generally washed with water and dried.

### EXAMPLES

The present invention is described below in more detail by examples. However, these examples should not be construed as limiting the present invention. In the examples, “part” refers to “part by weight” unless otherwise indicated.

Measurement and evaluation in the examples and comparative examples were carried out according to the following procedures.

Mw:

Mw was measured by gel permeation chromatography (GPC) using GPC columns (manufactured by Tosoh Corp., G2000HXL×2, G3000HXL×1, G4000HXL×1) under the following conditions. Flow rate: 1.0 ml/minute, eluate: tetrahydrofuran, column temperature: 40° C., standard reference material: monodispersed polystyrene

Radiation Transmittance:

A composition solution was applied to a quartz plate by spin coating and post-baked on a hot plate at 130° C. for 60 seconds to obtain a resist film with a thickness of 0.34 μm. The radiation transmittance of the resist film was calculated from the absorbance at a wavelength of 193 nm and was employed as a standard for transparency in the deep UV ray region.

Sensitivity:

A composition solution was applied to a silicon wafer with a 820 Å thickness ARC25 film (manufactured by Brewer Science Corp.) coated on the surface by spin coating and post-baked on a hot plate under the conditions shown in Table 2 to obtain a resist coating with a thickness of 0.34 μm. The coating was exposed to ArF excimer laser through a mask pattern using an ArF excimer laser exposure apparatus (manufactured by Nikon Corp., lens numerical aperture: 0.55). After performing PEB under the conditions shown in Table 2, the resist film was developed at 25° C. for 60 seconds in a 2.38 wt % tetramethylammonium hydroxide aqueous solution, washed with water, and dried to form a positive-tone resist pattern. An optimum dose capable of forming a 0.16 μm line-and-space pattern (1L1S) with a 1:1 line width was taken as sensitivity.

Resolution:

Minimum dimensions of the resist pattern resolved at the optimum dose were taken as the resolution.

Dry-etching Resistance:

A composition solution was applied to a silicon wafer by spin coating and dried to form a resist film with a thickness of 0.5 μm. Then, the resist film was dry-etched using a Pinnacle 8000 (manufactured by PMT Co.) and with CF₄ as an etching gas at a flow rate of 75 sccm and an output of 2,500 W under a gas pressure of 2.5 mTorr to measure the etching rate. The relative etching rate was calculated using the ratio of the found value to the etching rate of the film formed from the resin used in Comparative Example 1. The smaller the etching rate, the better the dry-etching resistance.

Pattern Shape:

The dimension of the bottom (L_{b}) and top (Lₐ) of a square cross-section of a line-and-space pattern (1L1S) with a line width of 0.16 μm was measured by a scanning electron microscope.

The pattern configuration was judged as “Good” when 0.85≦Lₐ/L_{b}≦1 was satisfied and the pattern did not have a skirt-like extension, and as “Tapered” when 0.85>Lₐ/L_{b}.

PEB Temperature Stability:

If the PEB temperature is intentionally raised or lowered by 5° C. from the optimum exposure dose required for developing a line-and-space pattern (1L1S) with a line width of 0.16 μm, not only the line width fluctuates, but also resolution is impaired. The fluctuation value (Unit: nm/° C.) per unit temperature of the resulting line width was calculated. The value was taken as PEB temperature stability. Generally, the lower the value, the better the performance of the resist in actual device fabrication. In the case where the value was less than 5 nm/° C., developability was judged as “Good” and otherwise as “Bad”.

### Synthesis Example 1

10 g of 1-methylcyclopentylbicyclo[2.2.1]hept-2-ene-5-carboxylate was dissolved in 40 ml of dry tetrahydrofuran. After cooling the solution to 0° C., the atmosphere in the reaction vessel was replaced with nitrogen. After dropwise addition of 25 ml of 1 mol tetrahydrofuran solution of BH₃-tetrahydrofuran complex, the mixture was stirred for one hour at 0° C. and then for a further one hour at room temperature. After cooling the reaction mixture to 0° C., 2.0 ml of water was added dropwise. Then, 4.4 ml of a 3 mol sodium hydroxide aqueous solution and 3.0 ml of 30% hydrogen peroxide solution were added dropwise while maintaining the reaction temperature at 20° C. or below. After stirring for 1.5 hours at room temperature, the water layer was saturated with sodium chloride and the organic layer was diluted with 400 ml of diethyl ether. The ether layer was washed with saturated brine and then with water, and dried over magnesium sulfate. Diethyl ether was evaporated to obtain 9.2 g of 1-methylcyclopentyl 2-hydroxybicyclo[2.2.1]hept-2-ene-5-carboxylate or 1-methylcyclopentyl 3-hydroxybicyclo[2.2.1]hept-2-ene-5-carboxylate.

Then, 9.2 g of the 1-methylcyclopentyl 2-hydroxybicyclo[2.2.1]hept-2-ene-5-carboxylate or 1-methylcyclopentyl 3-hydroxybicyclo[2.2.1]hept-2-ene-5-carboxylate and 3.81 g of pyridine were dissolved in 40 g of dry tetrahydrofuran. After cooling the solution to 0° C., a solution of 4.36 g of acryloyl chloride in 5 ml of dry tetrahydrofuran was added dropwise. The mixture was stirred for one hour and allowed to react overnight at room temperature. Deposited pyridine hydrochloride was removed by filtration. The filtrate was diluted with dietheryl 100 ml of ether and washed with 0.5 N oxalic acid aqueous solution, saturated brine, 3 wt % sodium carbonate aqueous solution, and again saturated brine. The ether layer was dried over magnesium sulfate, then the ether layer was removed by distillation under reduced pressure. The residue was distilled in a thin membrane distillatoror to obtain 7.9 g of a compound as a viscous liquid.

The compound was confirmed to be 1-methylcyclopentyl 2-acryloyloxybicyclo[2.2.1]hept-2-ene-5-carboxylate or 1-methylcyclopentyl 3-acryloyloxybicyclo[2.2.1]hept-2-ene-5-carboxylate by

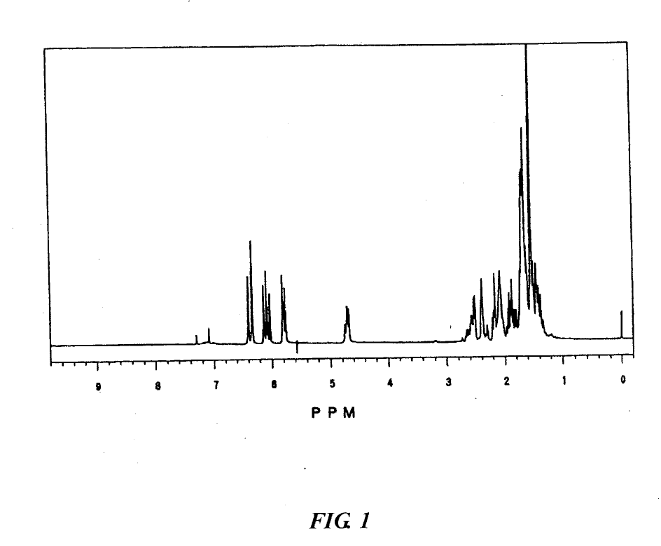

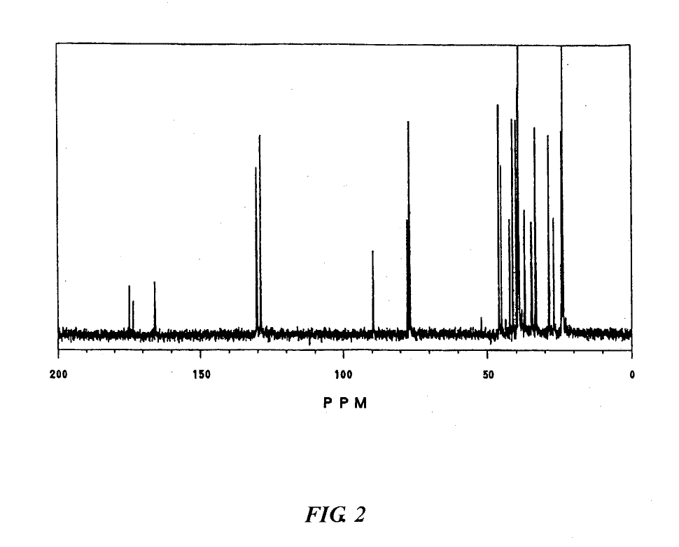

¹H-NMR analysis and ¹³C-NMR analysis. ¹H-NMR spectrum and ¹³C-NMR spectrum of this compound are respectively shown in FIG. 1 and FIG. 2. This compound is indicated as “monomer (I−1−a)”.

### Synthesis Example 2

A monomer solution was prepared by dissolving 53.01 g (45 mol %) of the monomer (i−1−a) and 46.99 g (55 mol % ) of a compound of the following formula (iii−1) (hereinafter referred to as “monomer (iii−1)”) in 200 g of 2-butanone, and further adding 3.54 g of dimethylazobisisobutyrate.

A 1,000 ml three-necked flask containing 100 g of 2-butanone was purged with nitrogen for 30 minutes and heated to 80° C. while stirring. Then, the above monomer solution was added to the flask using a dripping funnel at a rate of 10 ml/5 min. The polymerization was carried out for five hours after initiation of dripping. After the polymerization, the reaction solution was cooled with water to 30° C. or lower and poured into 2,000 g of methanol. White precipitate produced was collected by filtration. The white powder was washed with 400 g of methanol twice, collected by filtration, and dried at 50° C. for 17 hours to obtain 73 g of a white resin powder (yield: 73 wt %).

This resin was a copolymer with a Mw of 8,900 in which the ratio of the recurring units derived from the monomer (i−1−a) and monomer (iii−1) was 42.3:57.7 (mol % ). This resin is referred to as a “resin (A−1)”.

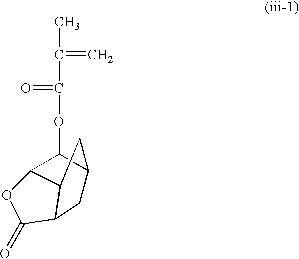

### Synthesis Example 3

A monomer solution was prepared by dissolving 57.20 g (50 mol % ) of the monomer (i−1−a), 20.74 g (25 mol % ) of monomer (iii−1), and 22.06 g (25 mol % ) of a compound of the following formula (iii−2) (hereinafter referred to as “monomer (iii−2)”) in 200 g of 2-butanone, and further adding 3.44 g of dimethylazobisisobutyrate.

A 1,000 ml three-necked flask containing 100 g of 2-butanone was purged with nitrogen for 30 minutes and heated to 80° C. while stirring. Then, the above monomer solution was added to the flask using a dripping funnel at a rate of 10 ml/5 min. The polymerization was carried out for five hours after initiation of dripping. After the polymerization, the reaction solution was cooled with water to 30° C. or lower and poured into 2,000 g of methanol. White precipitate produced was collected by filtration. The white powder was washed with 400 g of methanol twice, collected by filtration, and dried at 50° C. for 17 hours to obtain 71 g of a white resin powder (yield: 71 wt %).

This resin was a copolymer with a Mw of 9,300 in which the ratio of the recurring units derived from the monomer (i−1−a), monomer (iii−1), and monomer (iii−2) was 44:2:30.1:25.7 (mol %). This resin is referred to as a “resin (A-2)”.

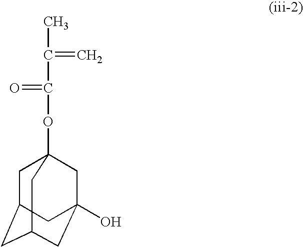

### Synthesis Example 4

A monomer solution was prepared by dissolving 6.83 g (15 mol % ) of bicyclo[2.2.1]hept-2-ene, 7.12 g (15 mol % ) of maleic anhydride, 56.60 g (40 mol % ) of the monomer (i−1−a), and 29.45 g (30 mol % ) of a compound of the following formula (iii−3) (hereinafter referred to as “monomer (iii−3)”) in 200 g of 2-butanone, and further adding 8.19 g of dimethylazobisisobutyrate.

A 1,000 ml three-necked flask containing 100 g of 2-butanone was purged with nitrogen for 30 minutes and heated to 80° C. while stirring. Then, the above monomer solution was added dropwise to the flask using a dripping funnel at a rate of 10 ml/5 min. The polymerization was carried out for five hours after initiation of dripping. After the polymerization, the reaction solution was cooled with water to 30° C. or lower and poured into 2,000 g of methanol. White precipitate produced was collected by filtration. The white powder was washed with 400 g of methanol twice, collected by filtration, and dried at 50° C. for 17 hours to obtain 77 g of a white resin powder (yield: 77 wt %)

This resin was a copolymer with a Mw of 6,200 in which the ratio of the recurring units derived from bicyclo[2.2.1]hept-2-ene, maleic anhydride, monomer (i−1−a), and monomer (iii−3) was 15.2:15.8:39.3:29.7 (mol % ). This resin is referred to as a “resin (A−3)”.

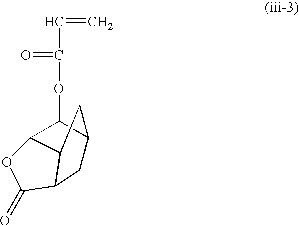

### Synthesis Example 5

A monomer solution was prepared by dissolving 50.55 g (50 mol % ) of 2-methyladamantan-2-yl methacrylate, 25.49 g (25 mol % ) of monomer (iii−2), and 23.97 g (25 mol % ) of monomer (iii−1) in 200 g of 2-butanone, and further adding 3.97 g of dimethylazobisisobutyrate.

A 1,000 ml three-necked flask containing 100 g of 2-butanone was purged with nitrogen for 30 minutes and heated to 80° C. while stirring. Then, the above monomer solution was added dropwise to the flask using a dripping funnel at a rate of 10 ml/5 min. The polymerization was carried out for five hours after initiation of dripping. After the polymerization, the polymer solution was cooled with water to 30° C. or lower and poured into 2,000 g of methanol. White precipitate produced was collected by filtration. The white powder was washed with 400 g of methanol twice, collected by filtration, and dried at 50° C. for 17 hours to obtain 74 g of a white resin powder (yield: 74 wt %).

This resin was a copolymer with a Mw of 9,800 in which the ratio of the recurring units derived from 2-methyladamantan-2-yl methacrylate, the monomer (iii-2), and monomer (iii-1) was 45.2:25.6:29.2 (mol %). This resin is referred to as a “resin (a-1)”.

### Examples 1-3 and Comparative Example 1

Composition solutions consisting of components shown in Table 1 were evaluated. The evaluation results are shown in Table 3.

Components other than the resins (A-1) to (A-3) and the resin (a-1) shown in Table 1 are as follows.

Acid Generator (B)

B-1: 1-(4-n-butoxynaphthalen-1-yl)tetrahydrothiophenium nonafluoro-n-butanesulfonate

Acid Diffusion Controller (C)

C-1: 2-phenylbenzimidazole

Solvent (E)

E-1: propylene glycol monomethyl ether acetate

TABLE 1
Unit in parenthesis (part by weight)

| | | Acid | Acid diffusion | |
|---|---|---|---|---|
| | Resin | generator (B) | controller | Solvent |
| Example 1 | A-1 (100) | B-1 (5) | C-1 (0.3) | E-1 (600) |
| Example 2 | A-2 (100) | B-1 (5) | C-1 (0.3) | E-1 (600) |
| Example 3 | A-3 (100) | B-2 (5) | C-1 (0.3) | E-1 (600) |
| Comparative | a-1 (100) | B-1 (5) | C-1 (0.3) | E-1 (600) |
| Example 1 | | | | |

TABLE 2

| | Resist film | | PB | | PEB | |
|---|---|---|---|---|---|---|
| | thickness | Sub- | Temp. | Time | Temp. | Time |
| | (μm) | strate | (° C.) | (sec) | (° C.) | (sec) |
| Example 1 | 0.34 | ARC25 | 130 | 90 | 130 | 90 |
| Example 2 | 0.34 | ARC25 | 130 | 90 | 130 | 90 |
| Example 3 | 0.34 | ARC25 | 130 | 90 | 130 | 90 |
| Comparative | 0.34 | ARC25 | 130 | 90 | 130 | 90 |
| Example 1 | | | | | | |

TABLE 3

| | Radiation | Sensi- | Reso- | Dry | Pattern | PEB |
|---|---|---|---|---|---|---|
| | transmittance | tivity | lution | etching | configu- | temp. |
| | (193 nm, %) | (J/m²) | (μm) | resistance | ration | stability |
| Example 1 | 71 | 229 | 0.13 | 0.9 | Good | Good |
| Example 2 | 73 | 223 | 0.13 | 0.9 | Good | Good |
| Example 3 | 70 | 228 | 0.13 | 0.9 | Good | Good |
| Com- | 70 | 204 | 0.13 | 0.9 | Bad | Bad |
| parative | | | | | | |
| Example 1 | | | | | | |

The radiation-sensitive resin composition of the present invention exhibits high transparency and excellent resolution when used as a chemically-amplified resist responsive to active radiation such as deep ultraviolet rays represented by a KrF excimer laser (wavelength: 248 nm) and ArF excimer laser (wavelength: 193 nm). The resin composition excels in sensitivity, a pattern shape including a skirt configuration, and dry etching resistance, exhibits only small fluctuation of pattern configuration after dry-etching, particularly shows least variation in the line width due to PEB temperature fluctuation, and exhibits excellent adhesion to substrates. The resin composition is can be suitably used for fabrication of integrated circuit devices which are expected to be more and more miniaturized.

What is claimed is:

1. A radiation-sensitive resin composition comprising:
(A) a resin insoluble or scarcely soluble in alkali, but becoming alkali soluble by the action of an acid, the resin comprising a recurring unit of the following formula (I), 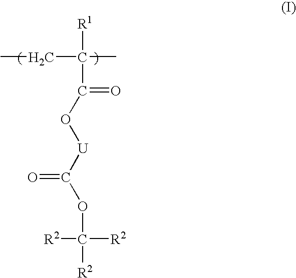
wherein R¹ represents a hydrogen atom, methyl group, a linear or branched hydroxy alkyl group having 1-4 carbon atoms, or a linear or branched fluorinated alkyl group having 1-4 carbon atoms, R² individually represents a monovalent alicyclic hydrocarbon group having 4-20 carbon atoms or a derivative thereof, or a linear or branched alkyl group having 1-4 carbon atoms, provided that at least one R² is a monovalent alicyclic hydrocarbon group having 4-20 carbon atoms or a derivative thereof, or any two of the R² groups form, in combination and together with the carbon atoms to which the two R² groups bond, a divalent alicyclic hydrocarbon group having 4-20 carbon atoms or a derivative thereof, with the remaining R² groups being a linear or branched alkyl group having 1-4 carbon atoms or a monovalent alicyclic hydrocarbon group having 4-20 carbon atoms or a derivative thereof, and U represents a divalent bridged hydrocarbon group having 5-12 carbon atoms, and
(B) a photoacid generator.

2. The composition according to claim 1, wherein R¹ in the formula (I) is a hydrogen atom or a methyl group.

3. The composition according to claim 1, wherein the divalent bridged hydrocarbon group represented by U in the formula (I) is a group derived from bicyclo[2.2.1]heptane, tetracyclo[6.2.1.1^{3,6}.0^{2,7}]dodecane, tricyclo[5.2.1.0^{2,6}]decane, or tricyclo[4.2.1.0^{3,7}]nonane.

4. The composition according to claim 1, wherein the group —C(R²)₃ in the formula (I) is a 1-alkyl substituted cycloalkyl group, 1-alkyl substituted bridged hydrocarbon group, or 1-bridged hydrocarbon substituted alkyl group.

5. The composition according to claim 1, wherein the group —C(R²)₃ in the formula (I) is a 1-methylcyclopentyl group, 1-ethylcyclopentyl group, 1-methylcyclohexyl group, 1-ethylcyclohexyl group, 2-methyladamantan-2-yl group, 2-ethyladamantan-2-yl group, 2-methylbicyclo[2.2.1]heptan-2-yl group, 2-ethylbicyclo[2.2.1]heptan-2-yl group, or 1-methyl-1-(bicyclo[2.2.1]heptan-2-yl)ethyl group.

6. The composition according to claim 1, wherein the resin (A) comprises a recurring unit of the following formula (I-1), 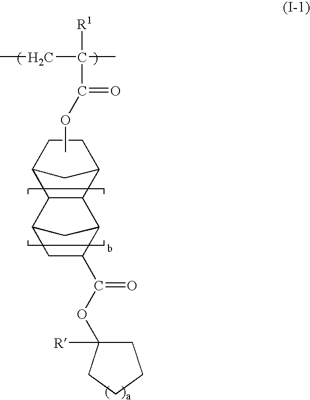
wherein R represents a hydrogen atom or a methyl group, R′ represents a methyl group or ethyl group, a is 1 or 2, and b is 0 or 1.

7. The composition according to claim 1, wherein the resin (A) comprises a recurring unit of the following formula (III), 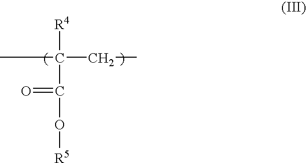
wherein R⁴ represents a hydrogen atom, a methyl group, a linear or branched hydroxyalkyl group having 1-4 carbon atoms, or a linear or branched fluoroalkyl group having 1-4 carbon atoms, and R⁵ represents a hydrogen atom or a monovalent organic group.

8. The composition according to claim 7, wherein the R⁵ group in the formula (III) is a monovalent organic group.

9. The composition according to claim 7, wherein the R⁵ group in the formula (III) is a linear or branched alkyl group having 1-6 carbon atoms, a monovalent organic group with an alicyclic structure having 4-20 carbon atoms, a monovalent organic group with a cyclic ether structure, a substituted or unsubstituted monovalent organic group with a lactone skeleton, or a group of the following formulas (3-1) or (3-2), 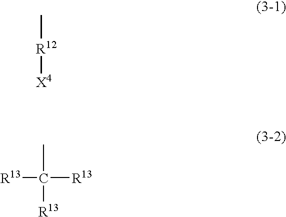
wherein R¹² represents a linear or branched divalent organic group or a divalent organic group having an alicyclic structure, X⁴ represents a hydrogen atom or a monovalent functional group, and R¹³ individually represents a linear or branched alkyl group having 1-4 carbon atoms, an oxoalkyl group having 2-4 carbon atoms, or a monovalent alicyclic hydrocarbon group having 4-20 carbon atoms or a derivative thereof, or any two of R¹³ groups form in combination a divalent alicyclic hydrocarbon group having 4-20 carbon atoms or a derivative thereof, with the remaining R¹³ group being a linear or branched alkyl group having 1-4 carbon atoms, an oxoalkyl group having 2-4 carbon atoms, or a monovalent alicyclic hydrocarbon group having 4-20 carbon atoms or a derivative thereof.

10. The composition according to claim 7, wherein the R⁵ group in the formula (III) is a hydrogen atom.

11. The composition according to claim 1, wherein the content of the recurring unit (I) in the resin (A) is 10-70 mol % of the total amount of the recurring units.

12. The composition according to claim 1, wherein the resin (A) has a polystyrene-reduced weight average molecular weight determined by gel permeation chromatography of 2,000 to 200,000.

13. The composition according to claim 1, wherein the acid produced by the acid generator (B) is a compound of any one of the following formulas (BA-1) to (BA-5), 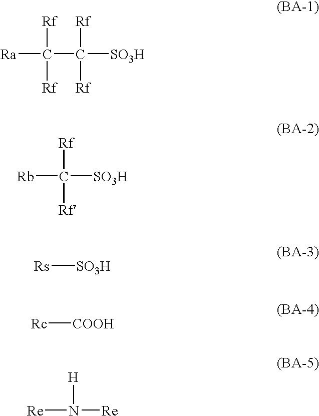
wherein, in the formula (BA-1), Rf individually represents a fluorine atom or trifluoromethyl group, Ra represents a hydrogen atom, a fluorine atom, a linear or branched alkyl group having 1-20 carbon atoms, a linear or branched fluoroalkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms; in the formula (BA-2), Rf represents a fluorine atom or a trifluoromethyl group, Rf′ represents a hydrogen atom, fluorine atom, methyl group, or trifluoromethyl group, and Rb represents a hydrogen atom, a linear or branched alkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms; in the formula (BA-3), Rs represents a linear or branched alkyl group having 1-20 carbon atoms or a substituted or unsubstituted monovalent cyclic hydrocarbon group having 3-20 carbon atoms; in the formula (BA-4), Rc represents a linear or branched alkyl group having 1-20 carbon atoms, a linear or branched fluoroalkyl group having 1-20 carbon atoms, a substituted or unsubstituted monovalent cyclic hydrocarbon group having 3-20 carbon atoms, or a substituted or unsubstituted monovalent cyclic fluoro-hydrocarbon group having 3-20 carbon atoms; in the formula (BA-5), Re represents a Ra—SO₂ group or Ra—CO— group, wherein Ra is the same as defined for the above formula (BA-1); provided that when the acid produced by the acid generator (B) contains a mixture of the acid of the formula (BA-1) and the acid of the formula (BA-5), the Ra groups in the formulas (BA-1) and (BA-5) may be either the same or different.

14. The composition according to claim 13, wherein the compound generating the acids of the above formulas (BA-1) to (BA-5) is an onium salt, sulfoneimide compound, sulfone compound, sulfonate compound, disulfonyldiazomethane compound, disulfonylmethane compound, oxime sulfonate compound, or hydrazine sulfonate compound.

15. The composition according to claim 1, wherein the amount of the photoacid generator (B) is 0.1-20 parts by weight for 100 parts by weight of the resin (A).

16. The composition according to claim 1, further comprising an acid diffusion controller.

17. The composition according to claim 16, wherein the amount of the acid diffusion controller is 0.001-5 parts by weight for 100 parts by weight of the resin (A).
